(19) United States
(12) Patent Application Publication
(10) Pub. No.: US 2026/0313882 A1
(43) Pub. Date: Oct. 8, 2026

(54) SEMICONDUCTOR DEVICE INCLUDING CAPACITORS, WORD LINE PADS AND WORD LINE CONTACTS

(71) Applicant: Samsung Electronics Co., Ltd., Suwon-si (KR)

(72) Inventor: Jeon Il Lee, Suwon-si (KR)

(73) Assignee: Samsung Electronics Co., Ltd., Suwon-si (KR)

(21) Appl. No.: 19/571,425

(22) Filed: Mar. 18, 2026

(30) Foreign Application Priority Data
Apr. 3, 2025 (KR) 10-2025-0043261

(51) Int. Cl. H10B 12/00; H10B 80/00; H10D 80/30; H10W 90/00

(52) U.S. Cl. CPC H10B 12/488; H10B 12/482; H10B 12/485; H10B 12/50; H10B 80/00; H10D 80/30; H10W 90/792

(57) ABSTRACT

A semiconductor device includes a substrate, a plurality of semiconductor patterns on the substrate, spaced apart, a bit line connected to one side surfaces of the plurality of semiconductor patterns, a plurality of capacitors respectively connected to the other side surfaces of the plurality of semiconductor patterns, a plurality of word lines respectively crossing the plurality of semiconductor patterns, a plurality of word line pads overlapping the plurality of capacitors, and a plurality of word line contacts connected to at least some of the plurality of word line pads, the plurality of word line contacts being spaced apart, and the plurality of word line contacts having different lengths.

### CROSS-REFERENCE TO RELATED APPLICATIONS

This present application claims priority to and the benefit under 35 U.S.C. § 119(a)-(d) of Korean Patent Application No. 10-2025-0043261 filed with the Korean Patent Office on Apr. 3, 2025, the entire disclosure of which is incorporated herein by reference.

### FIELD

The present disclosure relates to a semiconductor device and more particularly to a semiconductor device including capacitors, word line pads and word line contacts.

### BACKGROUND

There is a need for technologies to increase the integration density of semiconductor devices. In two-dimensional semiconductor devices, the integration density is mainly determined by the area occupied by a unit memory cell, and such integration density may be affected by the level of fine pattern formation technology.

However, since fine pattern formation technologies require expensive equipment, the integration density of two-dimensional semiconductor devices remains limited despite continuous improvements. Accordingly, three-dimensional semiconductor memory devices including memory cells arranged in three-dimensions have been proposed.

### SUMMARY

In embodiments, a semiconductor device comprises a substrate, a plurality of semiconductor patterns on the substrate, spaced apart in a direction substantially perpendicular to an upper surface of the substrate, a bit line connected to one side surfaces of the plurality of semiconductor patterns along a first direction and extending in a direction substantially perpendicular to the upper surface of the substrate, a plurality of capacitors respectively connected to other side surfaces of the plurality of semiconductor patterns along the first direction, a plurality of word lines respectively crossing the plurality of semiconductor patterns and extending in a second direction intersecting the first direction, a plurality of word line pads overlapping the plurality of capacitors in the second direction, and a plurality of word line contacts extending in a direction substantially perpendicular to the upper surface of the substrate, wherein at least some of the plurality of word line pads are respectively connected to the plurality of word line contacts, wherein the plurality of word line contacts are spaced apart in the first direction, and wherein the plurality of word line contacts have different lengths along the direction substantially perpendicular to the upper surface of the substrate.

In embodiments, a semiconductor device comprises a substrate, a plurality of semiconductor patterns on the substrate, spaced apart in a direction substantially perpendicular to an upper surface of the substrate, a bit line connected to one side surfaces of the plurality of semiconductor patterns along a first direction and extending in a direction substantially perpendicular to the upper surface of the substrate, a plurality of capacitors respectively connected to other side surfaces of the plurality of semiconductor patterns along the first direction, a plurality of word lines respectively crossing of the plurality of semiconductor patterns and extending in a second direction intersecting the first direction, a plurality of word line pads overlapping the plurality of capacitors in the second direction, and a plurality of word line contacts extending in a direction substantially perpendicular to the upper surface of the substrate, wherein at least some of the plurality of word line pads are respectively connected to the plurality of word line contacts, wherein the plurality of word line contacts are spaced apart in the first direction, and wherein the plurality of word line contacts are connected to upper surfaces of word line pads located in different layers.

In embodiments, a semiconductor device comprises a substrate, a plurality of semiconductor patterns on the substrate, spaced apart in a direction substantially parallel to an upper surface of the substrate and in a direction substantially perpendicular to the upper surface of the substrate; a plurality of bit lines spaced apart in the direction substantially parallel to the upper surface of the substrate, each of the plurality of bit lines being connected to one side surfaces of the plurality of semiconductor patterns spaced apart in the direction substantially perpendicular to the upper surface of the substrate along a first direction, and extending in the direction substantially perpendicular to the upper surface of the substrate, a plurality of capacitors respectively connected to the other side surfaces of the plurality of semiconductor patterns along the first direction, a plurality of word lines spaced apart in the direction substantially perpendicular to the upper surface of the substrate and in the first direction, each of the plurality of word lines crossing the plurality of semiconductor patterns spaced apart in a second direction intersecting the first direction, and extending in the second direction, a plurality of word line pads overlapping the plurality of capacitors in the second direction, each of the plurality of word line pads connecting between two word lines among the plurality of word lines that are adjacent in the first direction with the capacitor interposed therebetween, and a plurality of word line contacts extending in the direction substantially perpendicular to the upper surface of the substrate and spaced apart in the first direction on each of the plurality of word line pads, wherein the plurality of word line contacts are connected to upper surfaces of word line pads located in different layers.

### BRIEF DESCRIPTION OF THE DRAWINGS

FIG. 1 is a plan view showing a semiconductor device according to embodiments.

FIG. 2 is a perspective view showing an enlarged view of the R1 region of FIG. 1.

FIG. 3 is a cross-sectional view taken along line A-A′ of FIG. 1.

FIG. 4 is a cross-sectional view taken along lines B-B′, C-C′, and D-D′ of FIG. 1.

FIG. 5 is a plan view showing an enlarged view of the R2 region of FIG. 1.

FIG. 6 is a cross-sectional view taken along line E-E′ of FIG. 5.

FIG. 7 is a cross-sectional view taken along line F-F′ of FIG. 5.

FIG. 8 is a cross-sectional view taken along line G-G′ of FIG. 5.

FIG. 9 is a cross-sectional view taken along lines B-B′, C-C′, and D-D′ of FIG. 1.

FIG. 10 is a cross-sectional view taken along lines B-B′, C-C′, and D-D′ of FIG. 1.

FIG. 11 is a cross-sectional view taken along lines B-B′, C-C′, and D-D′ of FIG. 1.

FIG. 12 is a plan view showing a semiconductor device according to embodiments.

FIG. 13 is a cross-sectional view taken along line H-H′ of FIG. 12.

FIG. 14 is a cross-sectional view taken along line I-l′ of FIG. 12.

FIG. 15 is a cross-sectional view taken along lines J-J′, K-K′, and L-L′ of FIG. 12.

FIG. 16 is a cross-sectional view taken along lines J-J′, K-K′, and L-L′ of FIG. 12.

FIG. 17 is a cross-sectional view taken along lines J-J′, K-K′, and L-L′ of FIG. 12.

FIG. 18 is a cross-sectional view taken along lines J-J′, K-K′, and L-L′ of FIG. 12.

FIG. 19 is a cross-sectional view taken along lines J-J′, K-K′, and L-L′ of FIG. 12.

FIGS. 20, 23, 25, 28, 31, 33, and 36 are plan views illustrating a portion of a method for manufacturing a semiconductor device according to embodiments.

FIGS. 21, 22, 24, 26, 27, 29, 30, 32, 34, 35, 37, 38, and 39 are cross-sectional views illustrating a portion of a method for manufacturing a semiconductor device according to embodiments.

FIGS. 40 to 48 are cross-sectional views illustrating a portion of a method for manufacturing a semiconductor device according to embodiments.

### DETAILED DESCRIPTION

Hereinafter, various embodiments of the present disclosure will be described in detail with reference to the attached drawings so that a person having ordinary skill in the art to which the present disclosure pertains may easily implement the disclosure. The present disclosure may be embodied in many different forms and is not limited to the embodiments described herein.

In order to clearly explain the present disclosure, parts irrelevant to the description are omitted, and the same reference numerals are used for identical or similar components throughout the specification.

In addition, the size and thickness of each component shown in the drawing are arbitrarily shown for convenience of explanation, so the present disclosure is not necessarily limited to what is shown. To clearly represent the various layers and areas in the drawing, the thickness is enlarged and shown. And in the drawing, for convenience of explanation, the thickness of some layers and areas is exaggerated.

Also, when we say that a part, such as a layer, membrane, region, or plate, is “above” or “on” another part, this includes not only cases where it is “directly on” the other part, but also cases where there are other parts in between. Conversely, when we say that a part is “directly on” another part, we mean that there is no other part in between. Also, being “above” or “on” a reference part means being located above or below the reference part, and does not necessarily mean being located “above” or “on” the opposite direction of gravity.

Additionally, throughout the specification, whenever a part is said to “include” a component, this does not mean that it excludes other components, but rather that it may include other components, unless otherwise specifically stated.

Additionally, throughout the specification, when we say “in a plan view”, we mean when the target portion is viewed from above, and when we say “in cross-sectional view”, we mean when the target portion is viewed from the side in a cross-section cut vertically.

As used herein, the term “substantially perpendicular” generally refers to an orientation of two elements that are at or near a right angle (90°) with respect to each other, and can include deviations from exactly 90° within manufacturing tolerances, as would be understood by one of ordinary skill in the art.

As used herein, the term “substantially perpendicular” generally refers to an orientation of two elements that are at or near a right angle (90°) with respect to each other, and can include deviations from exactly 90° within manufacturing tolerances, as would be understood by one of ordinary skill in the art.

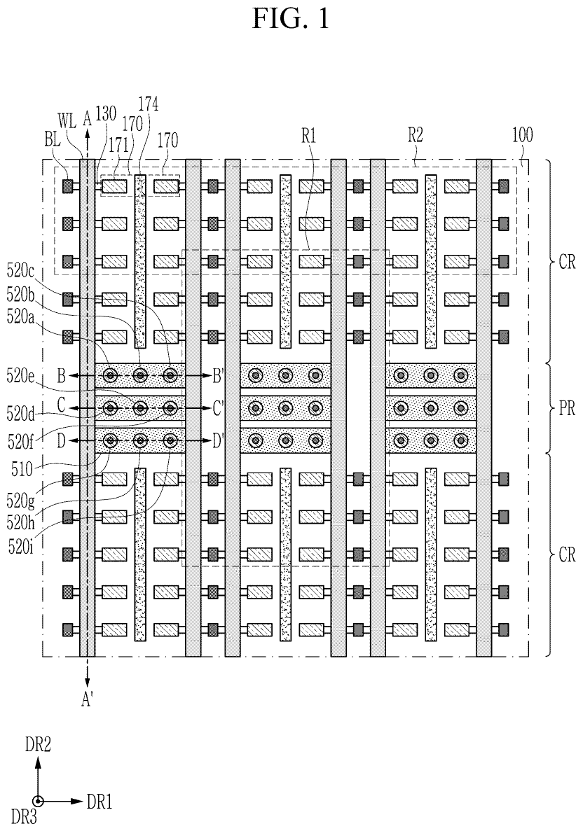

Hereinafter, a semiconductor device according to embodiments will be described with reference to FIGS. 1 to 8.

The embodiments provide a semiconductor device that reduces the area occupied by a plurality of word line pads and minimizes any increase in the area, even when the number of stacked memory cell layers increases.

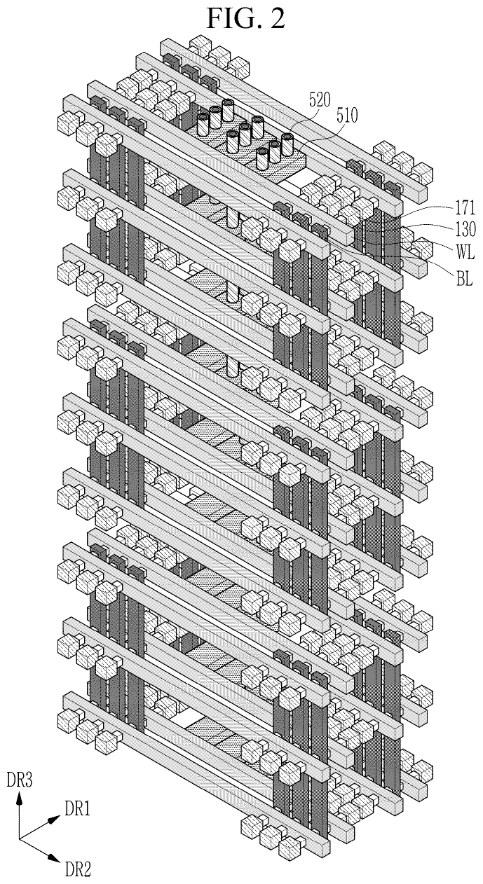

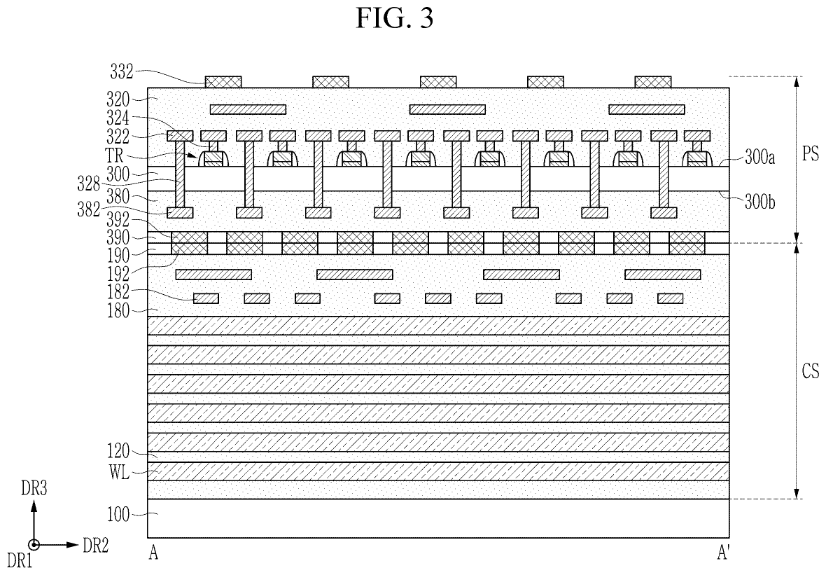

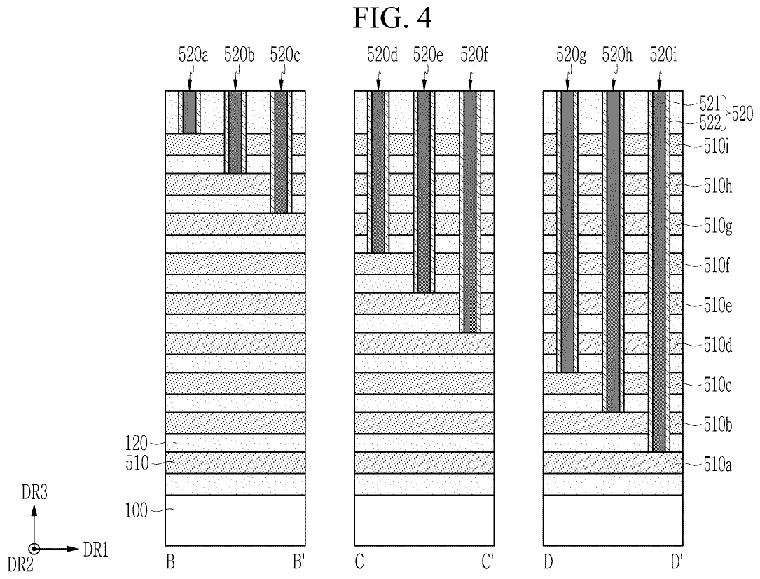

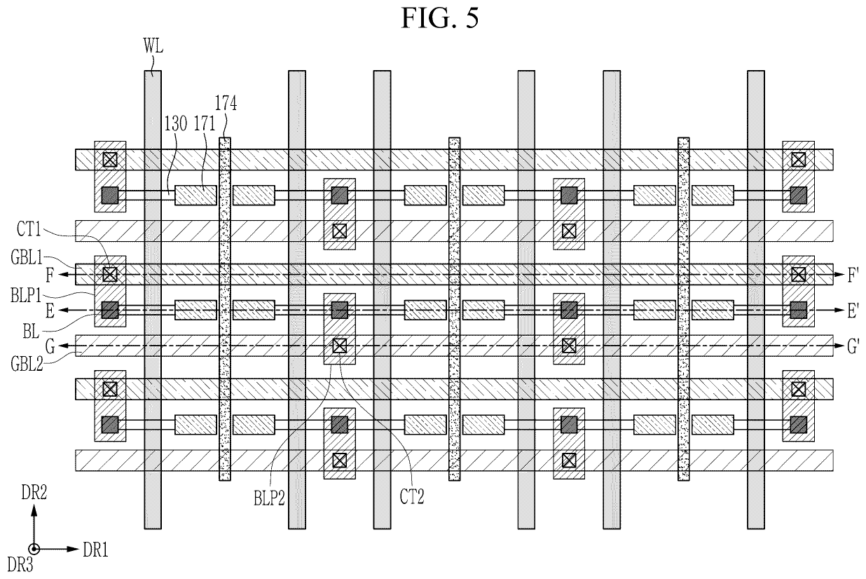

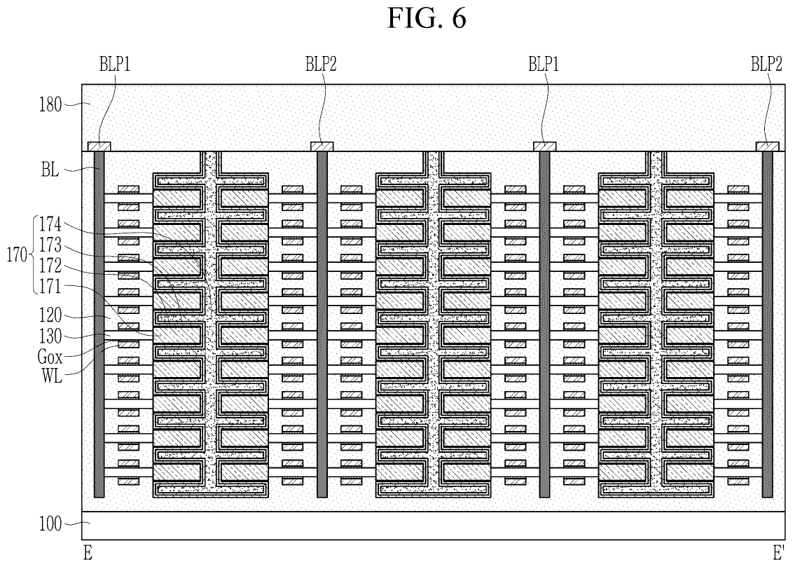

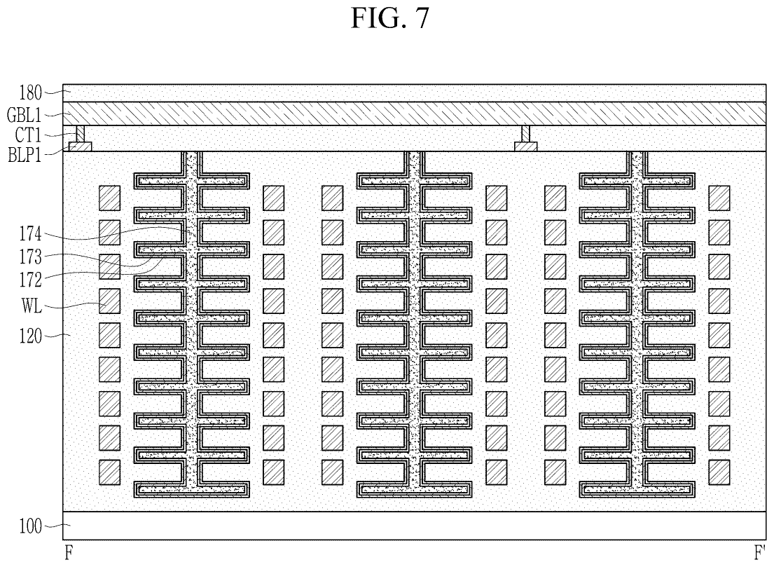

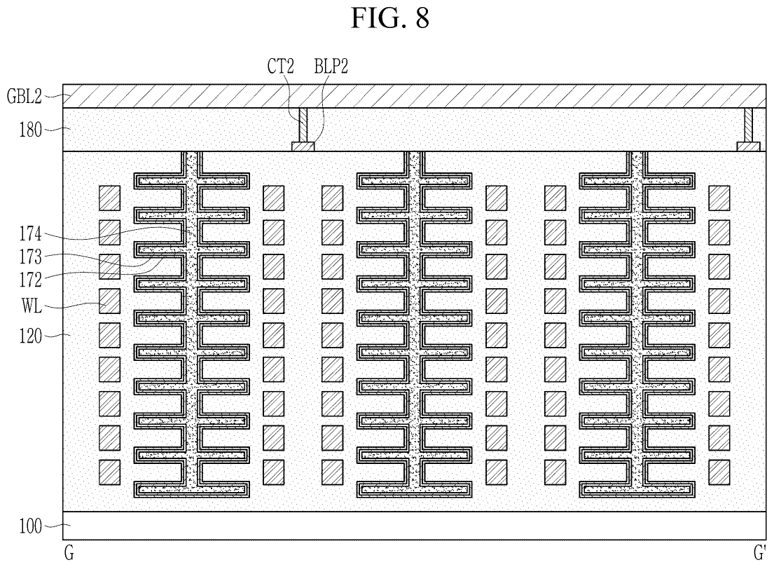

FIG. 1 is a plan view showing a semiconductor device according to embodiments. In FIG. 1, a substrate 100, a semiconductor pattern 130, a bit line BL, a capacitor 170, a word line WL, a word line pad 510, and a word line contact 520 of the semiconductor device are depicted, and the remaining components are omitted. In FIG. 1, only a first capacitor electrode 171 and a plate electrode 174 of the capacitor 170 are illustrated, and the remaining components of the capacitor 170 are omitted. FIG. 2 is a perspective view showing an enlarged view of the R1 region of FIG. 1. For convenience, the substrate 100 and plate electrode 174 are further omitted in FIG. 2. FIG. 3 is a cross-sectional view taken along line A-A′ of FIG. 1. FIG. 4 is a cross-sectional view taken along lines B-B′, C-C′, and D-D′ of FIG. 1. FIG. 5 is a plan view showing an enlarged view of the R2 region of FIG. 1. FIG. 6 is a cross-sectional view taken along line E-E′ of FIG. 5. FIG. 7 is a cross-sectional view taken along line F-F′ of FIG. 5. FIG. 8 is a cross-sectional view taken along line G-G′ of FIG. 5.

As illustrated in FIGS. 1 to 8, a semiconductor device according to embodiments includes a substrate 100, a plurality of semiconductor patterns 130 arranged on the substrate 100 and spaced apart in a direction perpendicular to an upper surface of the substrate 100, a bit line BL connected to one side surfaces of the plurality of semiconductor patterns 130 along a first direction DR1 and extending in a direction perpendicular to the upper surface of the substrate 100, a plurality of capacitors 170 respectively connected to the other side surfaces of the plurality of semiconductor patterns 130 along the first direction DR1, a plurality of word lines WL respectively crossing the plurality of semiconductor patterns 130 and extending in a second direction DR2 intersecting the first direction DR1, a plurality of word line pads 510 overlapping the plurality of capacitors 170 in the second direction DR2, and a plurality of word line contacts 520 extending in a direction perpendicular to the upper surface of the substrate 100. The first direction DR1 and the second direction DR2 may be directions parallel to the upper surface of the substrate 100.

The substrate 100 may include a semiconductor material. For example, the substrate 100 may include a group IV semiconductor, a group III-V compound semiconductor, a group II-VI compound semiconductor, etc. For example, the substrate 100 may include a semiconductor such as Si, Ge, or a compound semiconductor such as SiGe, SiC, GaAs, InAs, or InP. For example, the substrate 100 may be a single crystal epitaxial layer grown on a single crystal silicon substrate. However, the material of the substrate 100 is not limited to this and may be changed in various ways.

The substrate 100 may include a cell region CR and a pad region PR. The cell region CR and the pad region PR may be arranged along the second direction DR2 in which the word line WL extends. The substrate 100 may include a plurality of cell regions CR spaced apart from one another in the second direction DR2. The pad region PR may be located between cell regions CR adjacent in the second direction DR2. A plurality of memory cells may be positioned on the cell region CR of the substrate 100. Each of the plurality of memory cells may include the semiconductor pattern 130, the bit line BL, the capacitor 170, and the word line WL. The semiconductor pattern 130, the bit line BL, the capacitor 170, and the word line WL may be located on the cell region CR of the substrate 100. The word line pad 510 and the word line contact 520 may be located on the pad region PR of the substrate 100. The word line WL may be positioned to extend into the pad region PR. The word line WL may be positioned to extend in the second direction DR2 across the plurality of cell regions CR spaced apart from one another in the second direction DR2 and the pad region PR between the plurality of cell regions CR.

A plurality of semiconductor patterns 130 may be positioned on the cell region CR of the substrate 100. The plurality of semiconductor patterns 130 may be arranged and spaced apart in a third direction DR3 perpendicular to the upper surface of the substrate 100. The plurality of semiconductor patterns 130 may be arranged and spaced apart in the first direction DR1 parallel to the upper surface of the substrate 100. Two capacitors 170 may be located between two semiconductor patterns 130 adjacent in the first direction DR1. Additionally, one bit line BL may be located between two semiconductor patterns 130 adjacent in the first direction DR1. Two capacitors 170 and one bit line BL may be alternately arranged along the first direction DR1. Two semiconductor patterns 130 adjacent to one another in the first direction DR1 may have a symmetrical structure based on two capacitors 170 respectively connected thereto. The other two semiconductor patterns 130 adjacent in the first direction DR1 may have a symmetrical structure based on one bit line BL connected thereto. The plurality of semiconductor patterns 130 may be arranged and spaced apart in the second direction DR2 intersecting the first direction DR1. For example, the second direction DR2 may be a direction orthogonal to the first direction DR1.

The semiconductor pattern 130 may extend in the first direction DR1. The semiconductor pattern 130 may have a bar shape extending in the first direction DR1. One side surface of the semiconductor pattern 130 along the first direction DR1 may be connected to the bit line BL. For example, the semiconductor pattern 130 may be in contact with the bit line BL, but is not limited thereto. Another layer may be positioned between the semiconductor pattern 130 and the bit line BL. The other side surface along the first direction DR1 of the semiconductor pattern 130 may be connected to the capacitor 170.

The semiconductor pattern 130 may include a semiconductor material. For example, the semiconductor pattern 130 may include silicon, germanium, or silicon-germanium. For example, the semiconductor pattern 130 may include single crystal silicon or polycrystalline silicon. However, the examples are not limited thereto.

The bit line BL is connected to one side surfaces of a plurality of semiconductor patterns 130 spaced apart and arranged in the third direction DR3 and may extend in the third direction DR3. A semiconductor device according to embodiments may include a plurality of bit lines BL spaced apart and arranged in the first direction DR1. Each of the plurality of bit lines BL spaced apart and arranged in the first direction DR1 may be connected between two semiconductor patterns 130 adjacent in the first direction DR1. That is, two semiconductor patterns 130 may be connected to one bit line BL. However, not all bit lines BL may be connected to two semiconductor patterns 130. For example, among the plurality of bit lines BL spaced apart and arranged in the first direction DR1, each bit line BL located at both ends may be connected to one semiconductor pattern 130. The plurality of bit lines BL may be arranged spaced apart in the second direction DR2. The plurality of bit lines BL spaced apart and arranged in the second direction DR2 may be respectively connected to the plurality of semiconductor patterns 130 spaced apart and arranged in the second direction DR2.

The bit line BL may include a conductive material. For example, the bit line BL may include a doped semiconductor material such as doped silicon or doped germanium, a conductive metal nitride such as titanium nitride or tantalum nitride, a metal such as tungsten, titanium, or tantalum, a metal-semiconductor compound such as tungsten silicide, cobalt silicide, or titanium silicide, or a combination thereof.

As described above, the capacitor 170 may be connected to the other side surface along the first direction DR1 of the semiconductor pattern 130. The capacitor 170 may include a first capacitor electrode 171, a second capacitor electrode 173, a dielectric layer 172 positioned between the first capacitor electrode 171 and the second capacitor electrode 173, and a plate electrode 174 positioned on the second capacitor electrode 173. The first capacitor electrode 171 may be connected to the other side surface along the first direction DR1 of the semiconductor pattern 130. The first capacitor electrode 171 may extend in the first direction DR1. The dielectric layer 172 may cover the surface of the first capacitor electrode 171. The dielectric layer 172 may cover surfaces of the first capacitor electrode 171 except the surface in contact with the semiconductor pattern 130.

A semiconductor device according to embodiments may include a plurality of first capacitor electrodes 171 each connected to the plurality of semiconductor patterns 130. The plurality of first capacitor electrodes 171 may be arranged and spaced apart in the third direction DR3. The plurality of first capacitor electrodes 171 may be arranged and spaced apart in the second direction DR2. The plurality of first capacitor electrodes 171 may be arranged and spaced apart in the first direction DR1. The dielectric layer 172 may cover the plurality of first capacitor electrodes 171 spaced apart and arranged in the third direction DR3 and the second direction DR2. The dielectric layer 172 may cover two first capacitor electrodes 171 adjacent to one another in the first direction DR1. The dielectric layer 172 may cover two first capacitor electrodes 171 positioned facing one another in the first direction DR1 between two bit lines BL adjacent in the first direction DR1.

The second capacitor electrode 173 may cover the surface of the dielectric layer 172. The second capacitor electrode 173 may be separated from the first capacitor electrode 171 by the dielectric layer 172. The plate electrode 174 may cover the surface of the second capacitor electrode 173. The plate electrode 174 may be connected to the second capacitor electrode 173. Between two bit lines BL adjacent to one another in the first direction DR1, The dielectric layer 172, the second capacitor electrode 173, and the plate electrode 174 of the plurality of capacitors 170, which are arranged and spaced apart in the third direction DR3 and the second direction DR2 and face one another in the first direction DR1, may each be formed integrally.

Each of the first capacitor electrode 171, the second capacitor electrode 173, and the plate electrode 174 may include a conductive material. Each of the first capacitor electrode 171, the second capacitor electrode 173, and the plate electrode 174 may include at least one of a metal material such as titanium, tantalum, tungsten, copper, or aluminum, a conductive metal nitride such as titanium nitride or tantalum nitride, or a doped semiconductor material such as doped silicon or doped germanium. The first capacitor electrode 171 and the second capacitor electrode 173 may include the same material. The plate electrode 174 may include a different material from the first capacitor electrode 171 and the second capacitor electrode 173. For example, the first capacitor electrode 171 and the second capacitor electrode 173 may include titanium nitride, and the plate electrode 174 may include doped silicon germanium.

The dielectric layer 172 may include at least one of a dielectric, a ferromagnetic material, or an antiferromagnetic material. The dielectric may include a high-k material. For example, the dielectric may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or combinations thereof.

The word line WL may cross the semiconductor pattern 130 and extend in the second direction DR2. The word line WL may overlap the semiconductor pattern 130 in the third direction DR3. The word line WL may surround a portion of the surface of the semiconductor pattern 130. The word line WL may surround a portion of an outer surface of the semiconductor pattern 130 with respect to a central axis in the first direction DR1. In this case, the word line WL may further overlap the semiconductor pattern 130 in the second direction DR2. The word line WL may surround a portion between both ends along the first direction DR1 of the semiconductor pattern 130. A channel may be formed along the surface of the semiconductor pattern 130 surrounded by the word line WL.

However, it is not limited to the above-described embodiments. For example, the word line WL may overlap the semiconductor pattern 130 only in the third direction DR3 and not in the second direction DR2. For example, the word line WL may be positioned on one side surface of the semiconductor pattern 130 along the third direction DR3. As another example, two word lines WL may be positioned on each side surface of the semiconductor pattern 130 along the third direction DR3.

The word line WL may cross the plurality of semiconductor patterns 130 spaced apart and arranged in the second direction DR2. The word line WL may extend in the second direction DR2 to surround a portion of a surface of the plurality of semiconductor patterns 130 spaced apart in the second direction DR2. The word line WL may be electrically connected to the plurality of semiconductor patterns 130 spaced apart and arranged in the second direction DR2.

A plurality of word lines WLs may be arranged spaced apart in the third direction DR3. Each of the plurality of word lines WL spaced apart and arranged in the third direction DR3 may surround each of the plurality of semiconductor patterns 130 spaced apart and arranged in the third direction DR3. The plurality of word lines WL spaced apart and arranged in the third direction DR3 may be electrically connected to the plurality of semiconductor patterns 130 spaced apart and arranged in the third direction DR3, respectively.

The plurality of word lines WL may be arranged spaced apart in the first direction DR1. Two capacitors 170 connected in the first direction DR1 may be located between two word lines WL adjacent in the first direction DR1. One bit line BL may be located between two word lines WL adjacent in the first direction DR1. Two capacitors 170 and one bit line BL connected in the first direction DR1 may be alternately and repeatedly arranged along the first direction DR1. Two word lines WL adjacent in the first direction DR1 may be spaced apart in the first direction DR1 with two capacitors 170 interposed therebetween that are connected in the first direction DR1. Two word lines WL adjacent in the first direction DR1 may be spaced apart in the first direction DR1 with one bit line BL between them. The distance between two word lines WL located on both sides along the first direction DR1 of two capacitors 170 connected in the first direction DR1 may be longer than the distance between two word lines WL located on both sides along the first direction DR1 of the bit line BL.

A gate insulating layer Gox may be located between the word line WL and the semiconductor pattern 130. The word line WL may be separated from the surface of the semiconductor pattern 130 by the gate insulating layer Gox.

The word line WL may include a conductive material. For example, the word line WL may include a doped semiconductor material such as doped silicon or doped germanium, a conductive metal nitride such as titanium nitride or tantalum nitride, a metal such as tungsten, titanium, or tantalum, a metal-semiconductor compound such as tungsten silicide, cobalt silicide, or titanium silicide, or a combination thereof.

The gate insulating layer Gox may include at least one of a high-k material, silicon oxide, silicon nitride, or silicon oxynitride. The high dielectric constant material may include, for example, at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

An interlayer insulating layer 120 may be positioned between the plurality of word lines WL spaced apart and arranged in the third direction DR3. The interlayer insulating layer 120 may be further positioned between the substrate 100 and the lowermost word line WL. The interlayer insulating layer 120 may also be located between the uppermost word line WL and an upper insulating layer 180 described later.

The interlayer insulating layer 120 may be positioned between the plurality of semiconductor patterns 130 spaced apart and arranged in the third direction DR3. The interlayer insulating layer 120 may also be positioned on the lower surface of the lowermost semiconductor pattern 130 and on the upper surface of the uppermost semiconductor pattern 130.

The interlayer insulating layer 120 may be located between the substrate 100 and the bit line BL. A Then interlayer insulating layer 120 may be located between the upper surface of the substrate 100 and the lower surface of the bit line BL. The bit line BL may be insulated from the substrate 100 by the interlayer insulating layer 120. The interlayer insulating layer 120 may be positioned between the plurality of bit lines BL spaced apart and arranged in the second direction DR2.

An upper insulating layer 180 and an upper wiring layer 182 may be positioned on the plurality of semiconductor patterns 130, the plurality of bit lines BL, the plurality of word lines WL, the plurality of capacitors 170, and the interlayer insulating layer 120. The upper wiring layer 182 may be composed of the plurality of layers. A plurality of layers of the upper wiring layer 182 may be spaced apart in the third direction DR3 by the upper insulating layer 180. Although not shown, the plurality of layers of the upper wiring layer 182 may be connected by vias penetrating the upper insulating layer 180. Each layer of the upper wiring layer 182 may include a plurality of wirings, and the plurality of wirings may be spaced apart in the first direction DR1 or the second direction DR2 by the upper insulating layer 180. The upper insulating layer 180 may be positioned between the plurality of wirings.

The upper wiring layer 182 may be electrically connected to each of the plurality of bit lines BL, the plurality of word lines WL, and the plurality of capacitors 170. The upper wiring layer 182 may include a bit line pad BLP connected to the upper surface of the bit line BL. The upper wiring layer 182 may be connected to the plate electrode 174 of the capacitor 170. The upper wiring layer 182 may be connected to the word line WL through a word line pad 510 and a word line contact 520 to be described later.

A first connection pad 192 and a first pad insulating layer 190 may be positioned on the upper insulating layer 180. The first connection pad 192 may be arranged in a direction parallel to the upper surface of the substrate 100 on the upper insulating layer 180. The first pad insulating layer 190 may surround the side surface of the first connection pad 192.

The plurality of semiconductor patterns 130, the plurality of bit lines BL, the plurality of word lines WL, the plurality of capacitors 170, the interlayer insulating layer 120, the upper insulating layer 180, the upper wiring layer 182, the first pad insulating layer 190, and the first connection pad 192 positioned on the substrate 100 may form a cell structure CS.

A peripheral circuit structure PS may be positioned on the cell structure CS. The peripheral circuit structure PS may include a peripheral circuit substrate 300 and transistors TR positioned on a first surface 300a of the peripheral circuit substrate 300. The transistors TR may form various driving circuits that generate signals that may drive memory cells within the cell structure CS. The driving circuits composed of the transistors TR may include, for example, a sense amplifier, a sub-wordline driver, a row decoder, and a column decoder. A first circuit wiring layer 322, a first wiring via 324, and a first wiring insulating layer 320 may be positioned on the transistors TR. The first circuit wiring layer 322 may include a plurality of layers, and the plurality of layers of the first circuit wiring layer 322 may be spaced apart in the third direction DR3 by the first wiring insulating layer 320. The first wiring via 324 may penetrate the first wiring insulating layer 320 to connect the plurality of layers of the first circuit wiring layer 322 in the third direction DR3. The first circuit wiring layer 322 may be connected to the gate electrode and source/drain regions of the transistors TR by the first wiring via 324. An external connection pad 332 may be positioned on the upper surface of the first wiring insulating layer 320. The external connection pad 332 may be spaced apart from one another in a direction parallel to the first surface 300a of the peripheral circuit substrate 300 on the first wiring insulating layer 320. The semiconductor device may be connected to another device by the external connection pad 332.

A second circuit wiring layer 382 and a second wiring insulating layer 380 may be positioned on a second surface 300b of a peripheral circuit substrate 300 opposite to the first surface 300a. The second wiring insulating layer 380 may be located between the second surface 300b of the peripheral circuit substrate 300 and the second circuit wiring layer 382. The second circuit wiring layer 382 is illustrated as a single layer, but is not limited thereto and may include the plurality of layers. In this case, the plurality of layers of the second circuit wiring layer 382 may be spaced apart in the third direction DR3 by the second wiring insulating layer 380. Additionally, a second wiring via may be further positioned to connect the plurality of layers of the second circuit wiring layer 382 in the third direction DR3.

A through via 328 may be positioned to connect the first circuit wiring layer 322 and the second circuit wiring layer 382. The through via 328 may penetrate the first wiring insulating layer 320, the peripheral circuit substrate 300, and the second wiring insulating layer 380 to connect the first circuit wiring layer 322 and the second circuit wiring layer 382.

A second connection pad 392 and a second pad insulating layer 390 may be positioned on the second wiring insulating layer 380. The second connection pad 392 and the second pad insulating layer 390 may be positioned on the opposite side of the surface of the second wiring insulating layer 380 that is in contact with the second surface 300b of the peripheral circuit substrate 300. The second connection pad 392 may be arranged in a direction parallel to the second surface 300b of the peripheral circuit substrate 300 over the second wiring insulating layer 380. The second pad insulating layer 390 may surround the side surface of the second connection pad 392.

The second connection pad 392 may be bonded to the first connection pad 192, and the second pad insulating layer 390 may be bonded to the first pad insulating layer 190. The first connection pad 192 and the second connection pad 392 may include a metal material, and the first pad insulating layer 190 and the second pad insulating layer 390 may include an insulating material. For example, the first connection pad 192 and the second connection pad 392 may include, but are not limited to, copper Cu. The bonding of the cell structure CS and the peripheral circuit structure PS may be referred to as hybrid bonding since bonding between metal materials and bonding between insulating materials occur simultaneously. For example, when the metal material is copper Cu, the bonding of the cell structure CS and the peripheral circuit structure PS may be referred to as Cu—Cu hybrid bonding.

A semiconductor device according to embodiments may include a word line pad 510 and a word line contact 520. Hereinafter, the word line pad 510 and the word line contact 520 will be specifically described with reference to FIGS. 1, 2, and 4.

As illustrated in FIG. 1, FIG. 2, and FIG. 4, the word line pad 510 and the word line contact 520 may be positioned on the pad region PR of the substrate 100. The word line pad 510 may extend in the first direction DR1 from the word line WL. The word line pad 510 may overlap the capacitor 170 in the second direction DR2. The word line pad 510 may connect two word lines WL spaced apart in the first direction DR1 with two capacitors 170 interposed therebetween. The word line pad 510 may connect two word lines WL located on both sides of two capacitors 170 connected in the first direction DR1 along the first direction DR1.

A plurality of word line pads 510 may be positioned between two word lines WL. The plurality of word line pads 510 may be arranged spaced apart in the second direction DR2 between two word lines WL. Each of the plurality of word line pads 510 may connect between two word lines WL. The lengths of the plurality of word line pads 510 along the first direction DR1 may be the same.

The plurality of word line pads 510 may include word line pads 510 spaced apart and arranged in the third direction DR3. The word line pads 510 spaced apart and arranged in the third direction DR3 may extend in the first direction DR1 from each of the plurality of word lines WL spaced apart and arranged in the third direction DR3. The interlayer insulating layer 120 may be positioned between word line pads 510 spaced apart and arranged in the third direction DR3. The interlayer insulating layer 120 may be positioned between the lowermost word line pad 510 and the substrate 100, and also on the upper surface of the uppermost word line pad 510.

The word line contact 520 may be located on the word line pad 510. A plurality of word line contacts 520 may be arranged spaced apart in the first direction DR1 on the word line pad 510. For example, three word line contacts 520 are illustrated as being spaced apart and arranged in the first direction DR1, but are not limited thereto. The number of word line contacts 520 spaced apart and arranged in the first direction DR1 may vary.

The plurality of word line contacts 520 spaced apart and arranged in the first direction DR1 may be positioned on the plurality of word line pads 510 spaced apart and arranged in the third direction DR3. The plurality of word line contacts 520 spaced apart and arranged in the first direction DR1 may be respectively connected to at least some of a plurality of word line pads 510 spaced apart and arranged in the third direction DR3. Each of the plurality of word line contacts 520 spaced apart and arranged in the first direction DR1 may be connected to one of a plurality of word line pads 510 spaced apart and arranged in the third direction DR3. The plurality of word line contacts 520 spaced apart and arranged in the first direction DR1 may be respectively connected to the word line pad 510s located in a different layer.

The plurality of word line contacts 520 may include word line contacts 520 spaced apart and arranged in the second direction DR2. The word line contacts 520 spaced apart and arranged in the second direction DR2 may be respectively connected to the word line pads 510 located in a different layer. The word line contacts 520 spaced apart and arranged in the second direction DR2 may be respectively connected to the word line pads 510 spaced apart and arranged in the second direction DR2. The word line contacts 520 spaced apart and arranged in the second direction DR2 may be respectively located in a different layer and respectively connected to the word line pads 510 having different positions along the second direction DR2.

Each of the plurality of word line contacts 520 may be electrically connected to one of the plurality of word line pads 510. Each of the plurality of word line contacts 520 may include a conductive layer 521 having a pillar shape extending in the third direction DR3 and an insulating layer 522 surrounding a side surface of the conductive layer 521. The outer surface of the word line contact 520 may be formed of the insulating layer 522, and the upper and lower surfaces of the word line contact 520 may be formed of the conductive layer 521 and the insulating layer 522. For example, when the lower surface of the word line contact 520 is in contact with the upper surface of the word line pad 510, the word line contact 520 may be electrically connected to the word line pad 510. For example, when the word line contact 520 penetrates the word line pad 510 such that the outer surface of the word line contact 520 is in contact with the inner surface of the word line pad 510, the word line contact 520 may not be electrically connected to the word line pad 510.

The lower surface of each of the plurality of word line contacts 520 may be in contact with the upper surface of one word line pad 510. The plurality of word line contacts 520 may include a word line contact 520 that contacts an upper surface of an uppermost word line pad 510, and word line contacts 520 that penetrate at least one word line pad 510 and contact an upper surface of a word line pad 510 positioned below the at least one word line pad 510. A word line contact 520 connected to the uppermost word line pad 510 penetrates the interlayer insulating layer 120 so that a lower surface of the word line contact 520 may come into contact with the upper surface of the uppermost word line pad 510. A word line contact 520 connected to a word line pad 510 other than the uppermost word line pad 510 may penetrate the interlayer insulating layer 120 and at least one word line pad 510 positioned above the word line pad 510.

The number of word line pads 510 through which each of the plurality of word line contacts 520 penetrates may be different. The lengths of the plurality of word line contacts 520 along the third direction DR3 may be different from one another. For example, a word line contact 520 connected to a word line pad 510 located at a relatively low layer may penetrate more word line pads 510. For example, the length of a word line contact 520 connected to the word line pad 510 located at a relatively low layer may be longer along the third direction DR3. The word line pad 510 located at a relatively low layer may mean a word line pad that is relatively closer to the upper surface of the substrate 100.

According to embodiments illustrated in FIG. 4, among the plurality of word line contacts 520, lengths of the word line contacts 520 spaced apart and arranged in the first direction DR1 may gradually increase. The word line contacts 520 spaced apart and arranged in the first direction DR1 may be connected to word line pads 510 located in a consecutive layer.

For example, the plurality of word line pads 510 may include a first layer word line pad 510a, a second layer word line pad 510b, a third layer word line pad 510c, a fourth layer word line pad 510d, a fifth layer word line pad 510e, a sixth layer word line pad 510f, a seventh layer word line pad 510g, an eighth layer word line pad 510h, and a ninth layer word line pad 510i spaced apart from one another in the third direction DR3. The first layer word line pad 510a, the second layer word line pad 510b, the third layer word line pad 510c, the fourth layer word line pad 510d, the fifth layer word line pad 510e, the sixth layer word line pad 510f, the seventh layer word line pad 510g, the eighth layer word line pad 510h, and the ninth layer word line pad 510i may be sequentially adjacent to the upper surface of the substrate 100.

For example, the plurality of word line contacts 520 may include a first word line contact 520a, a second word line contact 520b, a third word line contact 520c, a fourth word line contact 520d, a fifth word line contact 520e, a sixth word line contact 520f, a seventh word line contact 520g, an eighth word line contact 520h, and a ninth word line contact 520i that are spaced apart from one another in the first direction DR1 and the second direction DR2. The first word line contact 520a, the second word line contact 520b, and the third word line contact 520c may be spaced apart from one another in the first direction DR1. The fourth word line contact 520d, the fifth word line contact 520e, and the sixth word line contact 520f may be spaced apart and arranged in the first direction DR1. The seventh word line contact 520g, the eighth word line contact 520h, and the ninth word line contact 520i may be spaced apart and arranged in the first direction DR1. The first word line contact 520a, the fourth word line contact 520d, and the seventh word line contact 520g may be spaced apart and arranged in the second direction DR2. The second word line contact 520b, the fifth word line contact 520e, and the eighth word line contact 520h may be spaced apart and arranged in the second direction DR2. The third word line contact 520c, the sixth word line contact 520f, and the ninth word line contact 520i may be spaced apart and arranged in the second direction DR2.

For example, the first word line contact 520a may be connected to the ninth layer word line pad 510i, which is the uppermost word line pad. The second word line contact 520b may penetrate the ninth layer word line pad 510i and be connected to the eighth layer word line pad 510h. The third word line contact 520c may be connected to the seventh layer word line pad 510g by penetrating the ninth layer word line pad 510i and the eighth layer word line pad 510h. The number of word line pads 510 through which the first word line contact 520a, the second word line contact 520b, and the third word line contact 520c penetrate may gradually increase. The lengths of the first word line contact 520a, the second word line contact 520b, and the third word line contact 520c along the third direction DR3 may gradually increase. The ninth layer word line pad 510i, the eighth layer word line pad 510h, and the seventh layer word line pad 510g, which are respectively connected to the first word line contact 520a, the second word line contact 520b, and the third word line contact 520c, may be located in consecutive layers.

For example, the fourth word line contact 520d may be connected to the sixth layer word line pad 510f by penetrating the ninth layer word line pad 510i, the eighth layer word line pad 510h, and the seventh layer word line pad 510g. The fifth word line contact 520e may be connected to the fifth layer word line pad 510e by penetrating the ninth layer word line pad 510i, the eighth layer word line pad 510h, the seventh layer word line pad 510g, and the sixth layer word line pad 510f. The sixth word line contact 520f may be connected to the fourth layer word line pad 510d by penetrating the ninth layer word line pad 510i, the eighth layer word line pad 510h, the seventh layer word line pad 510g, the sixth layer word line pad 510f, and the fifth layer word line pad 510e. The number of word line pads 510 through which the fourth word line contact 520d, the fifth word line contact 520e, and the sixth word line contact 520f penetrate may gradually increase. The lengths of the fourth word line contact 520d, the fifth word line contact 520e, and the sixth word line contact 520f along the third direction DR3 may gradually increase. The sixth layer word line pad 510f, the fifth layer word line pad 510e, and the fourth layer word line pad 510d, which are respectively connected to the fourth word line contact 520d, the fifth word line contact 520e, and the sixth word line contact 520f, may be located in a consecutive layer.

For example, the seventh word line contact 520g may be connected to the third layer word line pad 510c by penetrating the ninth layer word line pad 510i, the eighth layer word line pad 510h, the seventh layer word line pad 510g, the sixth layer word line pad 510f, the fifth layer word line pad 510e, and the fourth layer word line pad 510d. The eighth word line contact 520h may be connected to the second layer word line pad 510b by penetrating the ninth layer word line pad 510i, the eighth layer word line pad 510h, the seventh layer word line pad 510g, the sixth layer word line pad 510f, the fifth layer word line pad 510e, the fourth layer word line pad 510d, and the third layer word line pad 510c. The ninth word line contact 520i may be connected to the first layer word line pad 510a by penetrating the ninth layer word line pad 510i, the eighth layer word line pad 510h, the seventh layer word line pad 510g, the sixth layer word line pad 510f, the fifth layer word line pad 510e, the fourth layer word line pad 510d, the third layer word line pad 510c, and the second layer word line pad 510b. The number of word line pads 510 through which the seventh word line contact 520g, the eighth word line contact 520h, and the ninth word line contact 520i penetrate may gradually increase. The lengths of the seventh word line contact 520g, the eighth word line contact 520h, and the ninth word line contact 520i along the third direction DR3 may gradually increase. The third layer word line pad 510c, the second layer word line pad 510b, and the first layer word line pad 510a, which are respectively connected to the seventh word line contact 520g, the eighth word line contact 520h, and the ninth word line contact 520i, may be located in consecutive layers.

However, it is not limited to the above-described embodiments. For example, among the plurality of word line contacts 520, lengths of the word line contacts 520 spaced apart and arranged in the first direction DR1 may gradually decrease.

Below, the connection relationship between the bit line BL and the global bit line GBL is specifically described with reference to FIGS. 5 to 8.

As illustrated in FIGS. 5 to 8, a semiconductor device according to embodiments may include a plurality of global bit lines GBL that are connected to the plurality of bit lines BL spaced apart in the first direction DR1 and extend in the first direction DR1. A global bit line GBL may connect the plurality of bit lines BL spaced apart in the first direction DR1 and sense amplifiers within the peripheral circuit structure PS.

The plurality of global bit lines GBLs may include a first global bit line GBL1 and a second global bit line GBL2. The plurality of global bit lines GBLs may include a plurality of first global bit lines GBL1 and a plurality of second global bit lines GBL2. The plurality of first global bit lines GBL1 may be arranged spaced apart in the second direction DR2. The plurality of second global bit lines GBL2 may be arranged spaced apart in the second direction DR2. The plurality of first global bit lines GBL1 may be respectively connected to the bit lines BL spaced apart and arranged in the second direction DR2. The plurality of second global bit lines GBL2 may be respectively connected to the bit lines BL spaced apart and arranged in the second direction DR2.

The second global bit line GBL2 may be different from the first global bit line GBL1. In a plan view, the first global bit line GBL and the second global bit line GBL2 may be arranged spaced apart from one another in the second direction DR2. Two bit lines BL adjacent in the first direction DR1 may be connected to different global bit lines GBL. The plurality of bit lines BL spaced apart and arranged in the first direction DR1 may be alternately connected to the first global bit line GBL1 and the second global bit line GBL2.

A semiconductor device according to embodiments may include a plurality of bit line pads BLPs each positioned on an upper surface of a plurality of bit lines BLs. The plurality of bit line pads BLPs may be arranged and spaced apart in the first direction DR1. Each of the plurality of bit line pads BLPs overlaps the bit line BL in the third direction DR3 and may extend in a second direction DR2. Two bit line pads BLPs adjacent in the first direction DR1 may extend in opposite directions in the second direction DR2. For example, referring to FIG. 5, one of two bit line pads BLPs adjacent in the first direction DR1 may extend upward and the other may extend downward.

Two bit line pads BLPs adjacent in the first direction DR1 may include a first sub-bit line pad BLP1 connected to the first global bit line GBL1 and a second sub-bit line pad BLP2 connected to the second global bit line GBL2. A semiconductor device according to embodiments may include a first sub-bit line contact CT1 connecting between the first sub-bit line pad BLP1 and the first global bit line GBL1, and a second sub-bit line contact CT2 connecting between the second sub-bit line pad BLP2 and the second global bit line GBL2. The first sub-bit line contact CT1 and the second sub-bit line contact CT2 may be positioned on one side and the other side along the second direction DR2 with respect to the plurality of bit lines BL that are spaced apart and arranged in the first direction DR1. The first sub-bit line contact CT1 and the second sub-bit line contact CT2 may not overlap in the first direction DR1.

The first sub-bit line pad BLP1 and the second sub-bit line pad BLP2 may be located on the same layer. The first global bit line GBL1 and the second global bit line GBL2 may be located in different layers. The lengths of the first sub-bit line contact CT1 and the second sub-bit line contact CT2 may be different. As illustrated in FIGS. 7 and 8, for example, when the second global bit line GBL2 is located at a relatively higher layer than the first global bit line GBL1, the length of the second sub-bit line contact CT2 may be longer than the length of the first sub-bit line contact CT1. The length of the first sub-bit line contact CT1 and the second sub-bit line contact CT2 may mean the length along the third direction DR3. Since the first global bit line GBL1 and the second global bit line GBL2 are located in different layers, signal interference between them may be reduced.

According to the above-described embodiment, two word lines WL located on both sides along the first direction DR1 of two capacitors 170 connected to each of two semiconductor patterns 130 adjacent in the first direction DR1 may be connected by the word line pad 510. The Two word lines WL connected by the word line pad 510 may be turned on/off simultaneously. For example, when two memory cells, each connected to two word lines WL connected by word line pads 510, are connected to the same global bit line GBL, it may not be possible to know which of the two memory cells the value sensed by the sense amplifier through the global bit line GBL is the value of. In embodiments, two bit lines BL adjacent in the first direction DR1 are connected to different global bit lines GBL, so that two memory cells, each connected to two word lines WL connected by word line pads 510, may be connected to different global bit lines GBL. Accordingly, the values stored in the two memory cells each connected to two word lines WL connected by the word line pad 510 may be read separately through different global bit lines GBL.

The semiconductor device according to embodiments described above with reference to FIGS. 1 to 8 includes the plurality of word line pads 510 extending in the first direction DR1 intersecting the second direction DR2 in which the word lines WL extend from the plurality of word lines WL, overlapping the capacitor 170 in the second direction DR2, and the plurality of word line contacts 520 extending in a direction perpendicular to the upper surface of the substrate 100 and spaced apart from one another in the first direction DR1, at least some of the plurality of word line pads 510 are respectively connected to the plurality of word line contacts 520, and lengths of the plurality of word line contacts 520 along the third direction DR3 may be different. Each of the plurality of word line pads 510 may connect two word lines WL located on both sides along the first direction DR1 of two capacitors 170 respectively connected to two semiconductor patterns 130 adjacent to one another in the first direction DR1. The lengths of the plurality of word line pads 510 along the first direction DR1 may be the same. The plurality of word line contacts 520 may include a word line contact 520 connected to the uppermost word line pad 510, and a word line contact 520 connected to a word line pad 510 positioned below at least one word line pad 510 by penetrating the at least one word line pad 510.

According to a comparative example, a semiconductor device may include a plurality of word line pads extending in the second direction DR2 in which the word line WL extends from each word line WL and having a stepped shape and extending with different lengths, and a plurality of word line contacts respectively connected to upper surfaces of the plurality of word line pads without penetrating other word line pads and spaced apart from one another in the second direction DR2. In the comparative example, since the plurality of word line pads extend from the word line WL in the second direction DR2 and the capacitor is positioned on one side along the first direction DR1 intersecting the second direction DR2 with respect to the word line WL, the plurality of word line pads and the capacitor may not overlap.

Capacitors may occupy relatively large areas in the comparative example. According to embodiments, by utilizing the remaining space between two word lines WL located on both sides of two capacitors 170 connected in the first direction DR1, it is possible to reduce an area of the pad region PR in which the plurality of word line pads 510 are positioned.

In addition, in the semiconductor device according to the comparative example, an area occupied by the plurality of word line pads in a plan view increases as the number of layers in which the plurality of memory cells are stacked increases, whereas in the semiconductor device according to embodiments, the area occupied by the plurality of word line pads 510 in a plan view may be the same even if the number of layers in which the plurality of memory cells are stacked increases.

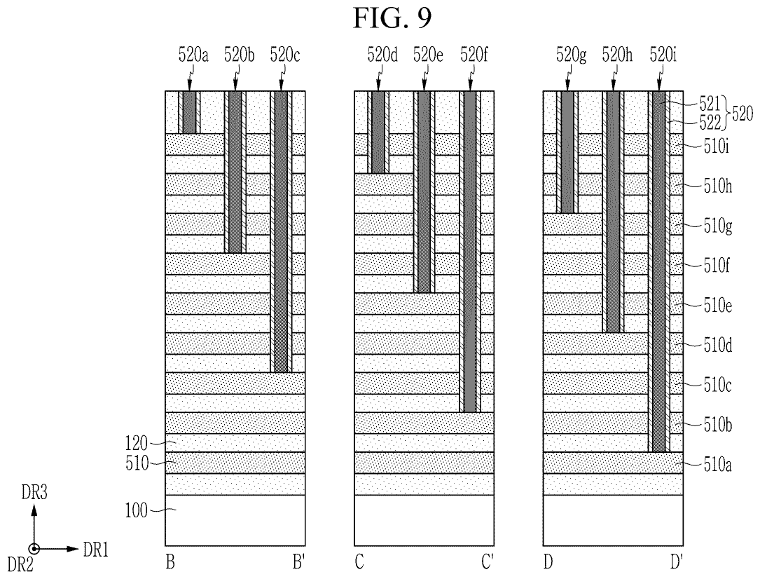

Hereinafter, modifications of the semiconductor device according to the embodiments illustrated in FIGS. 1 to 8 will be described with reference to FIGS. 9 to 11.

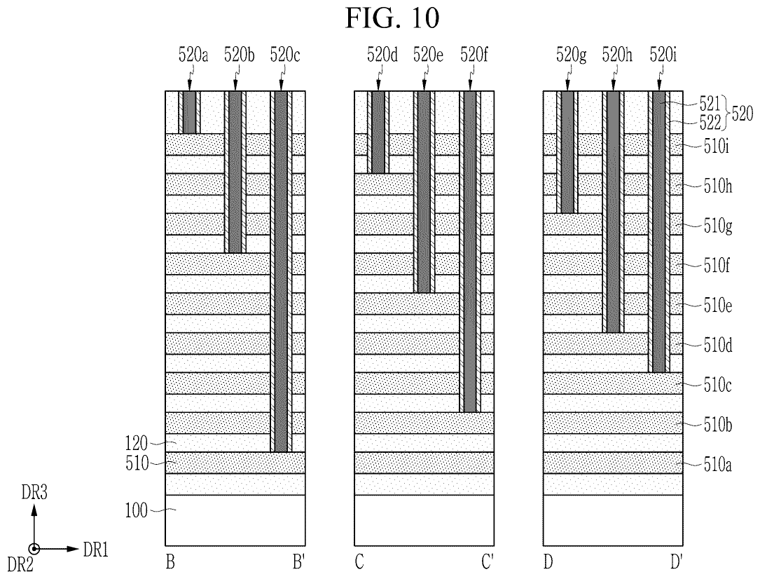

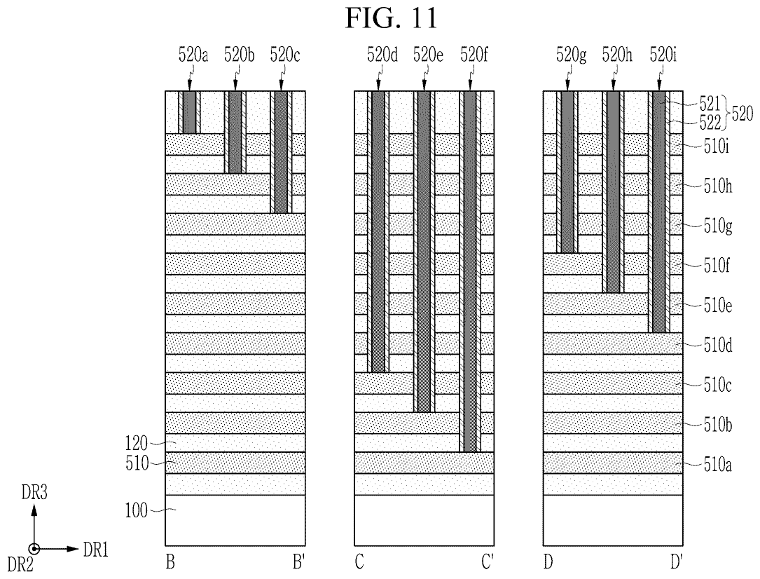

FIG. 9 is a cross-sectional view taken along lines B-B′, C-C′, and D-D′ of FIG. 1. FIG. 10 is a cross-sectional view taken along lines B-B′, C-C′, and D-D′ of FIG. 1. FIG. 11 is a cross-sectional view taken along lines B-B′, C-C′, and D-D′ of FIG. 1. In the embodiments illustrated in FIGS. 9 to 11, components identical or corresponding to those illustrated in FIGS. 1 to 8 may be referenced by the same symbols. The embodiments illustrated in FIGS. 9 to 11 may differ in some respects from the embodiments illustrated in FIGS. 1 to 8 in the connection relationship between the plurality of word line contacts 520 and the plurality of word line pads 510. Below, the differences from the previous example are mainly explained, and any duplicate explanations are omitted or simplified.

According to embodiments illustrated in FIG. 9, among the plurality of word line contacts 520, lengths of the word line contacts 520 spaced apart and arranged in the second direction DR2 may gradually increase. The word line contacts 520 spaced apart and arranged in the second direction DR2 may be connected to the word line pads 510 located in a consecutive layer.

For example, the first word line contact 520a may be connected to the ninth layer word line pad 510i, which is the uppermost word line pad. The fourth word line contact 520d may penetrate the ninth layer word line pad 510i and be connected to the eighth layer word line pad 510h. The seventh word line contact 520g may be connected to the seventh layer word line pad 510g by penetrating the ninth layer word line pad 510i and the eighth layer word line pad 510h. The number of word line pads 510 through which the first word line contact 520a, the fourth word line contact 520d, and the seventh word line contact 520g penetrate may gradually increase. The lengths of the first word line contact 520a, the fourth word line contact 520d, and the seventh word line contact 520g along the third direction DR3 may gradually increase. The ninth layer word line pad 510i, the eighth layer word line pad 510h, and the seventh layer word line pad 510g, which are respectively connected to the first word line contact 520a, the fourth word line contact 520d, and the seventh word line contact 520g, may be located in consecutive layers.

For example, the second word line contact 520b may be connected to the sixth layer word line pad 510f by penetrating the ninth layer word line pad 510i, the eighth layer word line pad 510h, and the seventh layer word line pad 510g. The fifth word line contact 520e may be connected to the fifth layer word line pad 510e by penetrating the ninth layer word line pad 510i, the eighth layer word line pad 510h, the seventh layer word line pad 510g, and the sixth layer word line pad 510f. The eighth word line contact 520h may be connected to the fourth layer word line pad 510d by penetrating the ninth layer word line pad 510i, the eighth layer word line pad 510h, the seventh layer word line pad 510g, the sixth layer word line pad 510f, and the fifth layer word line pad 510e. The number of word line pads 510 through which the second word line contact 520b, the fifth word line contact 520e, and the eighth word line contact 520h penetrate may gradually increase. The lengths of the second word line contact 520b, the fifth word line contact 520e, and the eighth word line contact 520h along the third direction DR3 may gradually increase. The sixth layer word line pad 510f, the fifth layer word line pad 510e, and the fourth layer word line pad 510d, which are respectively connected to the second word line contact 520b, the fifth word line contact 520e, and the eighth word line contact 520h, may be located in a consecutive layer.

For example, the third word line contact 520c may be connected to the third layer word line pad 510c by penetrating the ninth layer word line pad 510i, the eighth layer word line pad 510h, the seventh layer word line pad 510g, the sixth layer word line pad 510f, the fifth layer word line pad 510e, and the fourth layer word line pad 510d. The sixth word line contact 520f may be connected to the second layer word line pad 510b by penetrating the ninth layer word line pad 510i, the eighth layer word line pad 510h, the seventh layer word line pad 510g, the sixth layer word line pad 510f, the fifth layer word line pad 510e, the fourth layer word line pad 510d, and the third layer word line pad 510c. The ninth word line contact 520i may be connected to the first layer word line pad 510a by penetrating the ninth layer word line pad 510i, the eighth layer word line pad 510h, the seventh layer word line pad 510g, the sixth layer word line pad 510f, the fifth layer word line pad 510e, the fourth layer word line pad 510d, the third layer word line pad 510c, and the second layer word line pad 510b. The number of word line pads 510 through which the third word line contact 520c, the sixth word line contact 520f, and the ninth word line contact 520i penetrate may gradually increase. The lengths of the third word line contact 520c, the sixth word line contact 520f, and the ninth word line contact 520i along the third direction DR3 may gradually increase. The third layer word line pad 510c, the second layer word line pad 510b, and the first layer word line pad 510a, which are respectively connected to the third word line contact 520c, the sixth word line contact 520f, and the ninth word line contact 520i, may be located in a consecutive layer.

However, it is not limited to the above-described embodiments. For example, among the plurality of word line contacts 520, lengths of the word line contacts 520 spaced apart and arranged in the second direction DR2 may gradually decrease.

According to embodiments illustrated in FIG. 10, among the plurality of word line contacts 520, the shortest word line contact 520 and the longest word line contact 520 may be arranged along the first direction DR1.

For example, the diameter of the word line contact 520 may increase as the length extending along the third direction DR3 becomes longer. The longer the length of the word line contact 520 along the third direction DR3, the greater the number of word line pads 510 through which the word line contact 520 penetrates. As the length of the word line contact 520 in the third direction DR3 increases, the word line pad 510 connected to the word line contact 520 may be located at a lower layer. The diameter of a word line contact 520 connected to a relatively low word line pad 510 may be larger than the diameter of a word line contact 520 connected to a relatively high word line pad 510. Accordingly, the diameter of the word line contact 520 connected to the uppermost word line pad 510 may be the smallest, and the diameter of the word line contact 520 connected to the lowermost word line pad 510 may be the largest. For example, the diameter of the word line contact 520 may gradually become smaller as it approaches the upper surface of the substrate 100. In embodiments, the diameter of the word line contact 520 may mean the diameter of the top of the word line contact 520 or maximum diameter.

For example, among the plurality of word line contacts 520, the word line contacts 520 arranged along the first direction DR1 may include the first word line contact 520a having the shortest length along the third direction DR3 and the third word line contact 520c having the longest length along the third direction DR3. The first word line contact 520a having the shortest length along the third direction DR3 and the third word line contact 520c having the longest length along the third direction DR3 may be arranged along the first direction DR1. The first word line contact 520a connected to the ninth layer word line pad 510i, which is the uppermost word line pad, and the third word line contact 520c connected to the first layer word line pad 510a, which is the lowermost word line pad, may be arranged along the first direction DR1. The first word line contact 520a having the smallest diameter and the third word line contact 520c having the largest diameter may be arranged along the first direction DR1.

For example, among the plurality of word line contacts 520, an n-th (n≥1) shortest word line contact 520 and an n-th longest word line contact 520 may be arranged along the first direction DR1. A word line contact 520 connected to an n-th (n≥1) uppermost word line pad 510 and a word line contact 520 connected to an n-th (n≥1) lowermost word line pad 510 among the plurality of word line pads 510 may be arranged along the first direction DR1.

For example, the second shortest fourth word line contact 520d and the second longest sixth word line contact 520f among the plurality of word line contacts 520 may be arranged along the first direction DR1. The fourth word line contact 520d connected to the eighth layer word line pad 510h located at the second highest layer among the plurality of word line pads 510, and the sixth word line contact 520f connected to the second layer word line pad 510b located at the second lowest layer among the plurality of word line pads 510 may be arranged along the first direction DR1.

For example, the third shortest seventh word line contact 520g and the third longest ninth word line contact 520i among the plurality of word line contacts 39 520 may be arranged along the first direction DR1. The seventh word line contact 520g connected to the seventh layer word line pad 510g located at the third highest layer among the plurality of word line pads 510, and the ninth word line contact 520i connected to the third layer word line pad 510c located at the third lowest layer among the plurality of word line pads 510 may be arranged along the first direction DR1.

The fact that an n-th (n≥1) longest word line contact 520 and n-th (n≥1) shortest word line contact 520 length among the plurality of word line contacts 520 are arranged along the first direction DR1 may indicates an n-th largest-diameter word line contact 520 and an n- [symbol] smallest-diameter word line contact 520 among the plurality of word line contacts 520 are arranged along the first direction DR1. By arranging an n-th (n≥1) largest-diameter word line contact 520 and the n-th smallest-diameter word line contact 520 along the first direction DR1, it is possible to reduce or prevent short circuits between the word line contacts 520 arranged along the first direction DR1.

According to embodiments illustrated in FIG. 11, the lengths of the word line contacts 520 spaced apart from one another in the first direction DR1 among the plurality of word line contacts 520 as in embodiments illustrated in FIG. 4 may gradually increase. The word line contacts 520 spaced apart and arranged in the first direction DR1 may be connected to the word line pads 510 located in a consecutive layer.

According to embodiments illustrated in FIG. 11, unlike embodiments illustrated in FIG. 4, among the plurality of word line contacts 520, the word line contacts 520 spaced apart in the second direction DR2 may have a longer length as they are located farther from the cell region CR. Among the plurality of word line contacts 520, the word line contacts 520 spaced apart in the second direction DR2 may be connected to word line pads 510 that are located in lower layers as they are positioned farther from the cell region CR. Referring to FIG. 1 together, the cell region CR may be a region where the plurality of semiconductor patterns 130, the bit line BL, the plurality of capacitors 170, and the plurality of word lines WL are positioned, and the pad region PR may be a region where the plurality of word line pads 510 are positioned. The pad region PR may be located on one side of the cell region CR along the second direction DR2. For example, the plurality of cell regions CR may be arranged and spaced apart in the second direction DR2, and the pad region PR may be positioned between the plurality of cell regions CR spaced apart in the second direction DR2. Among the word line contacts 520 spaced apart and arranged in the second direction DR2, the word line contact 520 that is furthest from the cell region CR may have the longest length. Among the word line contacts 520 spaced apart and arranged in the second direction DR2, a word line pad 510 connected to a word line contact 520 that is furthest from the cell region CR may be located at the lowest layer.

For example, the first word line contact 520a may be connected to the ninth layer word line pad 510i, the fourth word line contact 520d may be connected to the third layer word line pad 510c, and the seventh word line contact 520g may be connected to the sixth layer word line pad 510f. Among the first word line contact 520a, the fourth word line contact 520d, and the seventh word line contact 520g that are spaced apart and arranged in the second direction DR2, the fourth word line contact 520d, which is furthest from the cell region CR, may have the longest length along the third direction DR3. The third layer word line pad 510c connected to the fourth word line contact 520d, which is the furthest from the cell region CR among the first word line contact 520a, the fourth word line contact 520d, and the seventh word line contact 520g, may be located at the lowest layer.

For example, the second word line contact 520b may be connected to the eighth layer word line pad 510h, the fifth word line contact 520e may be connected to the second layer word line pad 510b, and the eighth word line contact 520h may be connected to the fifth layer word line pad 510e. Among the second word line contact 520b, the fifth word line contact 520e, and the eighth word line contact 520h that are spaced apart in the second direction DR2, the fifth word line contact 520e, which is furthest from the cell region CR, may have the longest length along the third direction DR3. The second layer word line pad 510b connected to the fifth word line contact 520e, which is the furthest from the cell region CR among the second word line contact 520b, the fifth word line contact 520e, and the eighth word line contact 520h, may be located at the lowest layer.

For example, the third word line contact 520c may be connected to the seventh layer word line pad 510g, the sixth word line contact 520f may be connected to the first layer word line pad 510a, and the ninth word line contact 520i may be connected to the fourth layer word line pad 510d. Among the third word line contact 520c, the sixth word line contact 520f, and the ninth word line contact 520i that are spaced apart from the cell region CR and arranged in the second direction DR2, the sixth word line contact 520f may have the longest length along the third direction DR3.

The first layer word line pad 510a connected to the sixth word line contact 520f that is farthest from the cell region CR among the third word line contact 520c, the sixth word line contact 520f, and the ninth word line contact 520i may be located at the lowest layer.

In the above-described embodiment, when the cell region CR is positioned on both sides of the pad region PR along the second direction DR2, the word line contact 520 in the middle among the word line contacts 520 spaced apart and arranged in the second direction DR2 may be the farthest from the cell region CR. However, the examples are not limited to this. For example, when the cell region CR is positioned only on one side of the pad region PR along the second direction DR2, the length of the word line contacts 520 spaced apart and arranged in the second direction DR2 may become longer as they are located farther from the cell region CR along the second direction DR2.

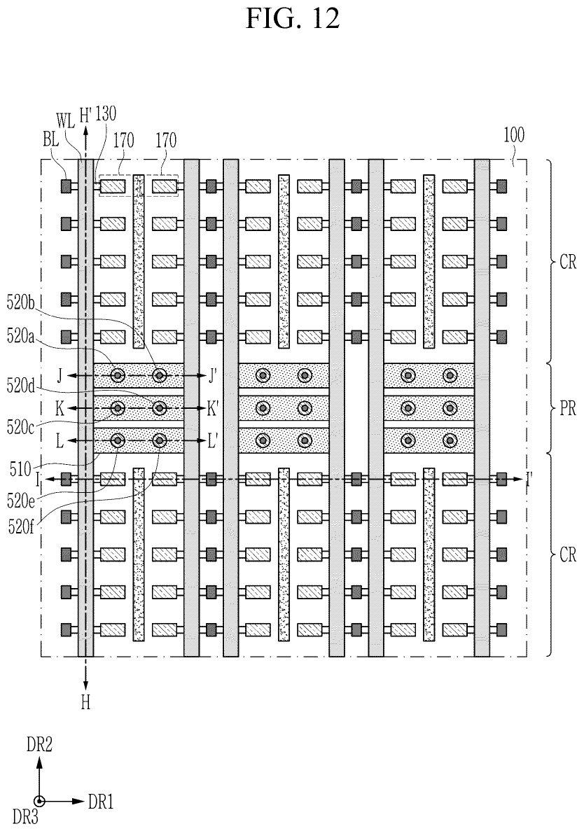

Hereinafter, modifications of the semiconductor device according to the embodiments illustrated in FIGS. 1 to 8 will be described with reference to FIGS. 12 to 15.

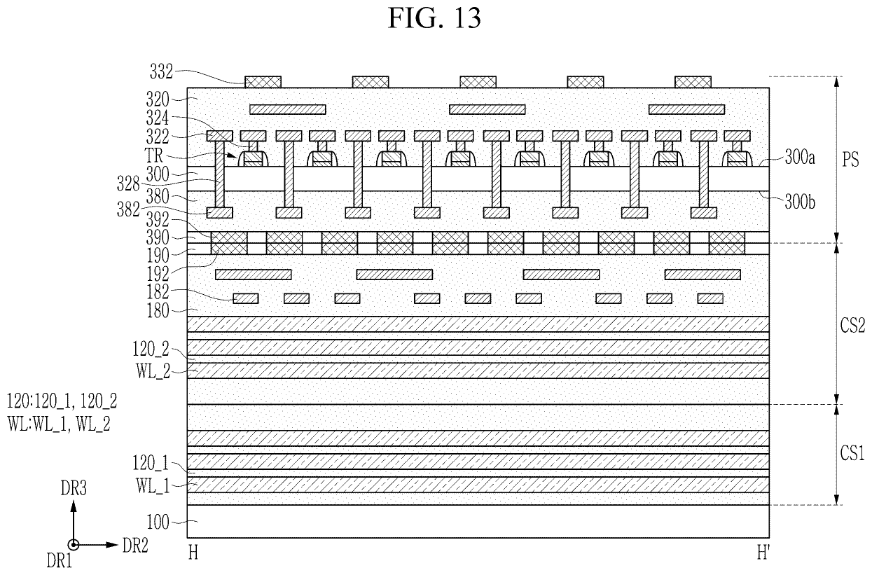

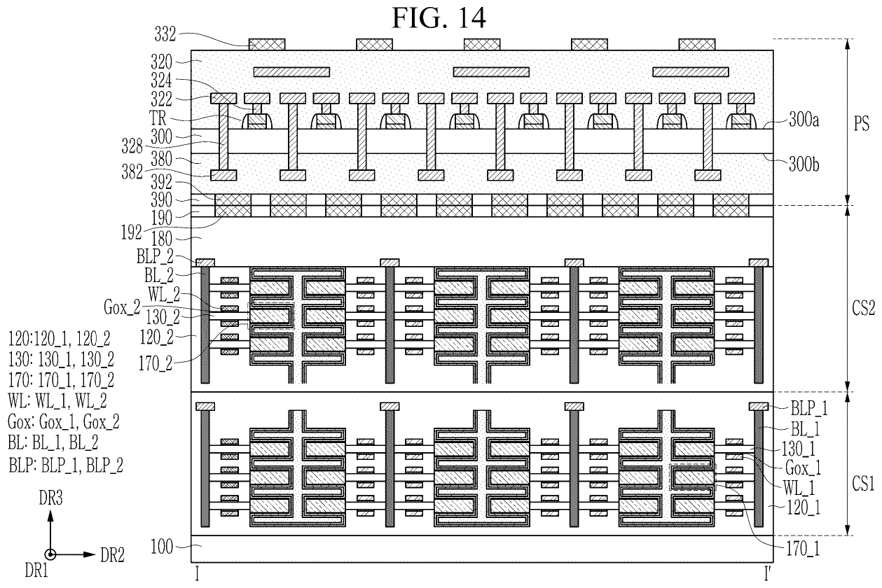

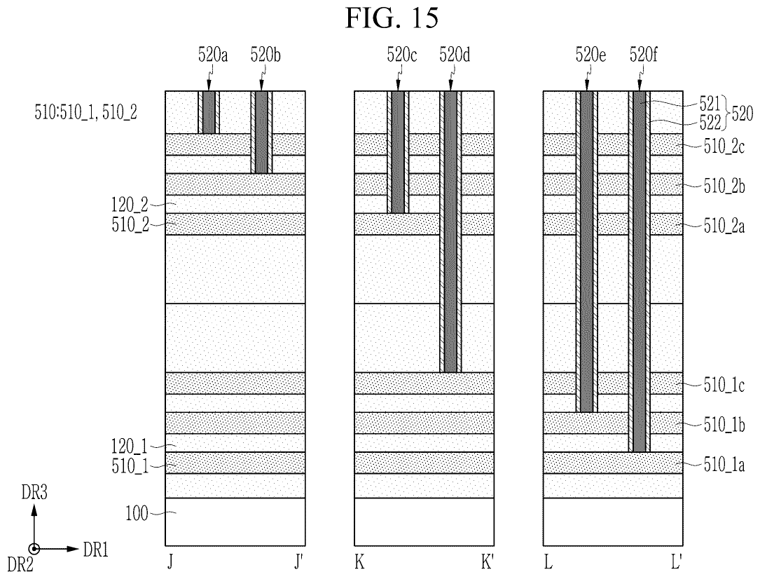

FIG. 12 is a plan view showing a semiconductor device according to embodiments. FIG. 13 is a cross-sectional view taken along line H-H′ of FIG. 12. FIG. 14 is a cross-sectional view taken along line I-l′ of FIG. 12. FIG. 15 is a cross-sectional view taken along lines J-J′, K-K′, and L-L′ of FIG. 12. In the embodiments illustrated in FIGS. 12 to 15, components identical or corresponding to those illustrated in FIGS. 1 to 8 may be referenced by the same symbols. The embodiments illustrated in FIGS. 12 to 15 may differ in some respects from the embodiments illustrated in FIGS. 1 to 8 in that a plurality of cell structures CS1, CS2 are stacked. Below, the differences from the previous example are mainly explained, and any duplicate explanations are omitted or simplified.

As shown in FIGS. 12 to 15, the plurality of cell structures CS1, CS2 may be positioned on the substrate 100. For example, the plurality of cell structures CS1, CS2 may include, but are not limited to, a first cell structure CS1 and a second cell structure CS2. For example, the plurality of cell structures CS1, CS2 may include three or more cell structures. The first cell structure CS1 and the second cell structure CS2 may be sequentially stacked on the substrate 100. Each of the plurality of cell structures CS1, CS2 may include the plurality of semiconductor patterns 130, the bit line BL, the plurality of capacitors 170, the plurality of word lines WL, and the plurality of word line pads 510.

The first cell structure CS1 may include a plurality of first semiconductor patterns 130_1, a first bit line BL_1, a plurality of first capacitors 170_1, a plurality of first word lines WL_1, and a plurality of first word line pads 510_1. The first cell structure CS1 may include a plurality of first bit lines BL_1. The first cell structure CS1 may include a plurality of first bit line pads BLP_1. The first cell structure CS1 may include a plurality of first gate insulating layers Gox_1. The first cell structure CS1 may include a first interlayer insulating layer 120_1.

The second cell structure CS2 may include a plurality of second semiconductor patterns 130_2, a second bit line BL_2, a plurality of second capacitors 170_2, a plurality of second word lines WL_2, and a plurality of second word line pads 510_2. The second cell structure CS2 may include a plurality of second bit lines BL_2. The second cell structure CS2 may include a plurality of second bit line pads BLP_2. The second cell structure CS2 may include a plurality of second gate insulating layers Gox_2. The second cell structure CS2 may include a second interlayer insulating layer 120_2.

The first semiconductor pattern 130_1 and the second semiconductor pattern 130_2 may be collectively referred to as the semiconductor pattern 130. The first bit line BL_1 and the second bit line BL_2 may be collectively referred to as the bit line BL. The first bit line pad BLP_1 and the second bit line pad BLP_2 may be collectively referred to as the bit line pad BLPs. The first capacitor 170_1 and the second capacitor 170_2 may be collectively referred to as the capacitor 170. The first word line WL_1 and the second word line WL_2 may be collectively referred to as the word line WL. The first gate insulating layer Gox_1 and the second gate insulating layer Gox_2 may be collectively referred to as the gate insulating layer Gox. The first word line pad 510_1 and the second word line pad 510_2 may be collectively referred to as the word line pad 510. The first interlayer insulating layer 120_1 and the second interlayer insulating layer 120_2 illustrated in FIGS. 12 to 15 may be collectively referred to as the interlayer insulating layer 120. With respect to the semiconductor pattern 130, bit line BL, bit line pad BLP, capacitor 170, word line WL, gate insulating layer Gox, word line pad 510, and interlayer insulating layer 120, the contents described with reference to the same drawing symbols in the embodiments illustrated in FIGS. 1 to 8 may be applied identically or similarly.

The second cell structure CS2 may include the upper insulating layer 180 and the upper wiring layer 182. The second cell structure CS2 may include the first pad insulating layer 190 and the first connection pad 192. With respect to the upper insulating layer 180, the upper wiring layer 182, the first pad insulating layer 190, and the first connection pad 192, the same or similar contents described with reference to the same drawing reference numerals in the embodiments illustrated in FIGS. 1 to 8 may be applied.

The peripheral circuit structure PS may be positioned on top of the plurality of cell structures CS1, CS2. The peripheral circuit structure PS may be positioned on the second cell structure CS2. The peripheral circuit structure PS may include the peripheral circuit substrate 300 and the transistors TR positioned on the first surface 300a of the peripheral circuit substrate 300. The first circuit wiring layer 322, the first wiring via 324, and the first wiring insulating layer 320 may be positioned on the transistors TR. The external connection pad 332 may be positioned on the upper surface of the first wiring insulating layer 320. The second circuit wiring layer 382 and the second wiring insulating layer 380 may be positioned on the second surface 300b of the peripheral circuit substrate 300 opposite to the first surface 300a. The through via 328 may be positioned to connect the first circuit wiring layer 322 and the second circuit wiring layer 382. The second pad insulating layer 390 and the second connection pad 392 may be positioned on the second wiring insulating layer 380. With respect to the peripheral circuit structure PS and each component thereof, the contents described with reference to the same drawing reference numerals in the embodiments illustrated in FIGS. 1 to 8 may be applied identically or similarly.

The peripheral circuit structure PS may be joined to the second cell structure CS2. The first connection pad 192 and the second connection pad 392 may be bonded, and the first pad insulating layer 190 and the second pad insulating layer 390 may be bonded. The first connection pad 192 and the second connection pad 392 may include a metal material, and the first pad insulating layer 190 and the second pad insulating layer 390 may include an insulating material. The bonding between the peripheral circuit structure PS and the second cell structure CS2 may be referred to as hybrid bonding since bonding between metal materials and bonding between insulating materials occur simultaneously. For example, when the metal material is copper Cu, the bonding between the peripheral circuit structure PS and the second cell structure CS2 may be referred to as Cu-Cu hybrid bonding.

The substrate 100 may include the cell region CR and the pad region PR. The substrate 100 may include the plurality of cell regions CR spaced apart in the second direction DR2, and the pad region PR may be positioned between the plurality of cell regions CR spaced apart in the second direction DR2. The plurality of semiconductor patterns 130, the plurality of bit lines BL, the plurality of capacitors 170, and the plurality of word lines WL may be positioned on the cell region CR of the substrate 100. The plurality of word line pads 510 may be positioned on the pad region PR of the substrate 100. The plurality of word line contacts 520 may be positioned on the pad region PR of the substrate 100.

The description of the word line pad 510 described below may be equally applied to each of the first word line pad 510_1 and the second word line pad 510_2.

The plurality of word lines WL may be further extended into the pad region PR. Each of the plurality of word line pads 510 may extend in the first direction DR1 from portions of the plurality of word lines WL located in the pad region PR. Each word line pad 510 may overlap with the capacitor 170 in the second direction DR2. Each word line pad 510 may connect two word lines WL located on both sides of two capacitors 170 respectively connected to two semiconductor patterns 130 adjacent to one another in the first direction DR1. The plurality of word line pads 510 may be arranged spaced apart in the second direction DR2 between two word lines WL.

The plurality of word line contacts 520 may be arranged spaced apart in the first direction DR1 on the word line pad 510 connecting two word lines WL. For example, as shown in FIG. 12 and FIG. 15, the two word line contacts 520 may be arranged spaced apart in the first direction DR1 on the word line pad 510, but are not limited thereto. The number of word line contacts 520 spaced apart in the first direction DR1 and arranged on the word line pad 510 may be varied.

The plurality of word line contacts 520 spaced apart in the second direction DR2 may be respectively positioned on the plurality of word line pads 510 spaced apart in the second direction DR2 between two word lines WL.

Each of the plurality of word line contacts 520 may be electrically connected to one of the plurality of first word line pads 510_1 and the plurality of second word line pads 510_2. The word line contact 520 may be connected to the first word line pad 510_1 or the second word line pad 510_2.

Each of the plurality of word line contacts 520 may include the conductive layer 521 extending in the third direction DR3 and the insulating layer 522 surrounding the side surface of the conductive layer 521. The outer surface of the word line contact 520 may be formed of the insulating layer 522, and the upper and lower surfaces of the word line contact 520 may be formed of the conductive layer 521 and the insulating layer 522. For example, when the lower surface of the word line contact 520 is in contact with the upper surface of the first word line pad 510 1 or the second word line pad 510_2, the word line contact 520 may be electrically connected to the first word line pad 510_1 or the second word line pad 510_2. For example, when the word line contact 520 penetrates the first word line pad 510_1 or the second word line pad 510_2 and the outer surface of the word line contact 520 is in contact with the inner surface of the first word line pad 510_1 or the second word line pad 510_2, the word line contact 520 may not be electrically connected to the first word line pad 510_1 or the second word line pad 510 2.

The lower surface of each of the plurality of word line contacts 520 may be in contact with the upper surface of the first word line pad 510_1 or the upper surface of the second word line pad 510_2. The plurality of word line contacts 520 may include a word line contact 520 that contacts an upper surface of an uppermost second word line pad 510_2, word line contacts 520 that penetrate at least one second word line pad 510_2 and contact an upper surface of a second word line pad 510_2 or a first word line pad 510_1 positioned below the at least one second word line pad 510_2, and word line contacts 520 that penetrate all of the second word line pads 510_2 and at least one first word line pad 510_1 and contact an upper surface of a first word line pad 510_1 positioned below the at least one first word line pad 510_1. The word line contact 520 connected to the uppermost second word line pad 510_2 penetrates the second interlayer insulating layer 120_2 so that the lower surface of the word line contact 520 may come into contact with the upper surface of the uppermost second word line pad 510_2. A word line contact 520 connected to a second word line pad 510_2 other than the uppermost second word line pad 510_2 may penetrate the second interlayer insulating layer 120_2 and at least one second word line pad 510_2 positioned above the second word line pad 510_2. A word line contact 520 connected to the uppermost first word line pad 510_1 penetrates the second interlayer insulating layer 120_2, all of the second word line pads 510_2, and the first interlayer insulating layer 120_1, so that a lower surface of the word line contact 520 may be in contact with an upper surface of the uppermost first word line pad 510_1. A word line contact 520 connected to a first word line pad 510_1 other than the uppermost first word line pad 510_1 may penetrate the second interlayer insulating layer 120_2, the first interlayer insulating layer 120_1, and all of the second word line pads 510_2 and at least one first word line pad 510_1 positioned above the first word line pad 510_1.

The number of first word line pads 510_1 and second word line pads 510_2 through which each of the plurality of word line contacts 520 penetrates may be different. The lengths of the plurality of word line contacts 520 along the third direction DR3 may be different. For example, a word line contact 520 connected to a first word line pad 510_1 or a second word line pad 510_2 located at a relatively low layer may penetrate more first word line pads 510_1 and/or second word line pads 510_2. For example, the length of the word line contact 520 connected to the first word line pad 510_1 or the second word line pad 510_2 located at a relatively low layer may be longer along the third direction DR3. The first word line pad 510_1 or the second word line pad 510_2 located at a relatively low layer may mean a word line pad that is relatively closer to the upper surface of the substrate 100.

According to embodiments illustrated in FIG. 15, among the plurality of word line contacts 520, lengths of the word line contacts 520 spaced apart and arranged in the first direction DR1 may gradually increase. The word line contacts 520 spaced apart and arranged in the first direction DR1 may be connected to the word line pads 510 located in a consecutive layer.

For example, the plurality of word line pads 510 may include a first layer word line pad 510_1a, a second layer word line pad 510_1b, a third layer word line pad 510_1c, a fourth layer word line pad 510_2a, a fifth layer word line pad 510_2b, and a sixth layer word line pad 510_2c spaced apart from one another in the third direction DR3. The first layer word line pad 510_1a, the second layer word line pad 510_1b, the third layer word line pad 510_1c, the fourth layer word line pad 510_2a, the fifth layer word line pad 510_2b, and the sixth layer word line pad 510_2c may be adjacent to the upper surface of the substrate 100 in that order. The first layer word line pad 510_1a, the second layer word line pad 510_1b, and the third layer word line pad 510_1c may be included in the first cell structure CS1, and the fourth layer word line pad 510_2a, the fifth layer word line pad 510_2b, and the sixth layer word line pad 510_2c may be included in the second cell structure CS2.

For example, the plurality of word line contacts 520 may include a first word line contact 520a, a second word line contact 520b, a third word line contact 520c, a fourth word line contact 520d, a fifth word line contact 520e, and a sixth word line contact 520f spaced apart from one another in the first direction DR1 and the second direction DR2. The first word line contact 520a and the second word line contact 520b may be arranged spaced apart from one another in the first direction DR1. The third word line contact 520c and the fourth word line contact 520d may be arranged spaced apart from one another in the first direction DR1. The fifth word line contact 520e and the sixth word line contact 520f may be arranged spaced apart from one another in the first direction DR1. The first word line contact 520a, the third word line contact 520c, and the fifth word line contact 520e may be spaced apart and arranged in the second direction DR2. The second word line contact 520b, the fourth word line contact 520d, and the sixth word line contact 520f may be spaced apart and arranged in the second direction DR2.

For example, the first word line contact 520a may be connected to the sixth layer word line pad 510_2c, which is the uppermost word line pad. The second word line contact 520b may be connected to the fifth layer word line pad 510_2b by penetrating the sixth layer word line pad 510_2c. The number of word line pads 510 through which the first word line contact 520a and the second word line contact 520b penetrate may gradually increase. The lengths of the first word line contact 520a and the second word line contact 520b along the third direction DR3 may gradually increase. The sixth layer word line pad 510_2c and the fifth layer word line pad 510_2b, which are respectively connected to the first word line contact 520a and the second word line contact 520b, may be located in a consecutive layer.

For example, the third word line contact 520c may be connected to the fourth layer word line pad 510_2a by penetrating the sixth layer word line pad 510_2c and the fifth layer word line pad 510_2b. The fourth word line contact 520d may be connected to the third layer word line pad 510_1c by penetrating the sixth layer word line pad 510_2c, the fifth layer word line pad 510_2b, and the fourth layer word line pad 510_2a. The number of word line pads 510 through which the third word line contact 520c and the fourth word line contact 520d penetrate may gradually increase. The lengths of the third word line contact 520c and the fourth word line contact 520d along the third direction DR3 may gradually increase. The fourth layer word line pad 510_2a and the third layer word line pad 510_1c, which are respectively connected to the third word line contact 520c and the fourth word line contact 520d, may be located in a consecutive layer.

For example, the fifth word line contact 520e may be connected to the second layer word line pad 510_1b by penetrating the sixth layer word line pad 510_2c, the fifth layer word line pad 510_2b, the fourth layer word line pad 510_2a, and the third layer word line pad 510_1c. The sixth word line contact 520f may be connected to the first layer word line pad 510_1a by penetrating the sixth layer word line pad 510_2c, the fifth layer word line pad 510_2b, the fourth layer word line pad 510_2a, the third layer word line pad 510_1c, and the second layer word line pad 510_1b. The number of word line pads 510 through which the fifth word line contact 520e and the sixth word line contact 520f penetrate may gradually increase. The lengths of the fifth word line contact 520e and the sixth word line contact 520f along the third direction DR3 may gradually increase. The second layer word line pad 510_1b and the first layer word line pad 510_1a, which are respectively connected to the fifth word line contact 520e and the sixth word line contact 520f, may be located in a consecutive layer.

However, it is not limited to the above-described embodiments. For example, among the plurality of word line contacts 520, lengths of the word line contacts 520 spaced apart and arranged in the first direction DR1 may gradually decrease.

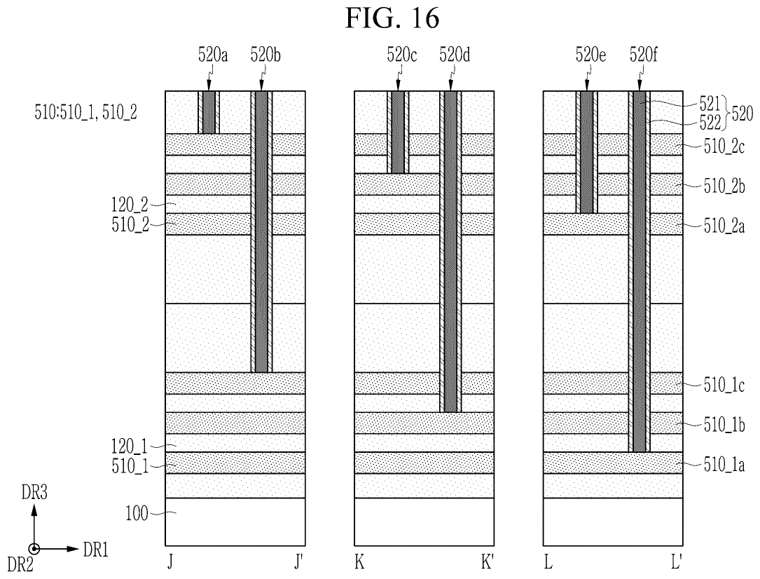

Hereinafter, modification examples of semiconductor devices according to the embodiments illustrated in FIGS. 12 to 15 will be described with reference to FIGS. 16 to 19.

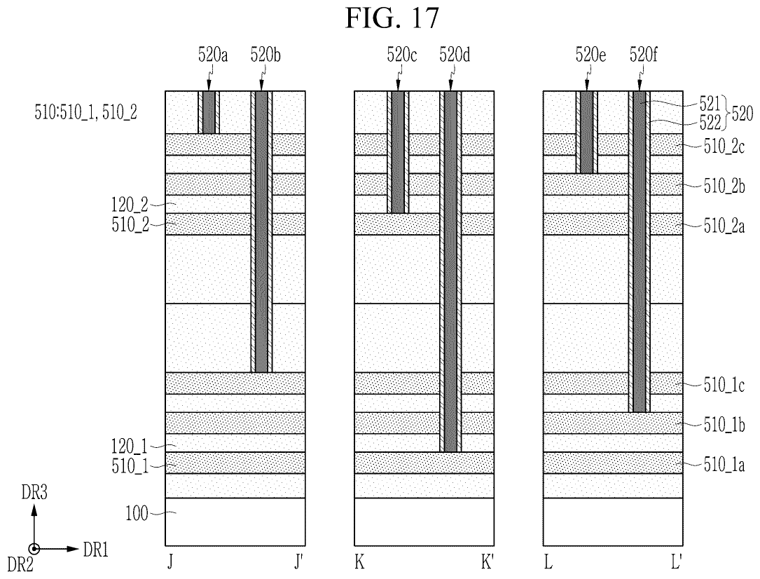

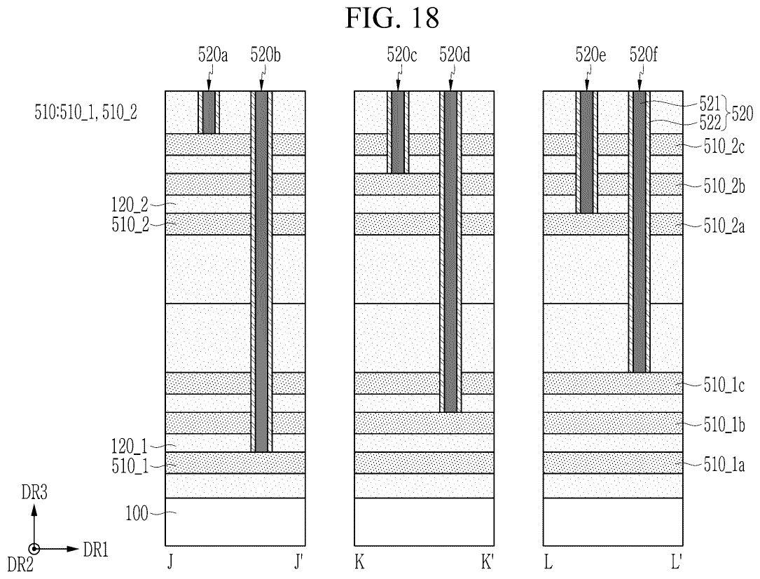

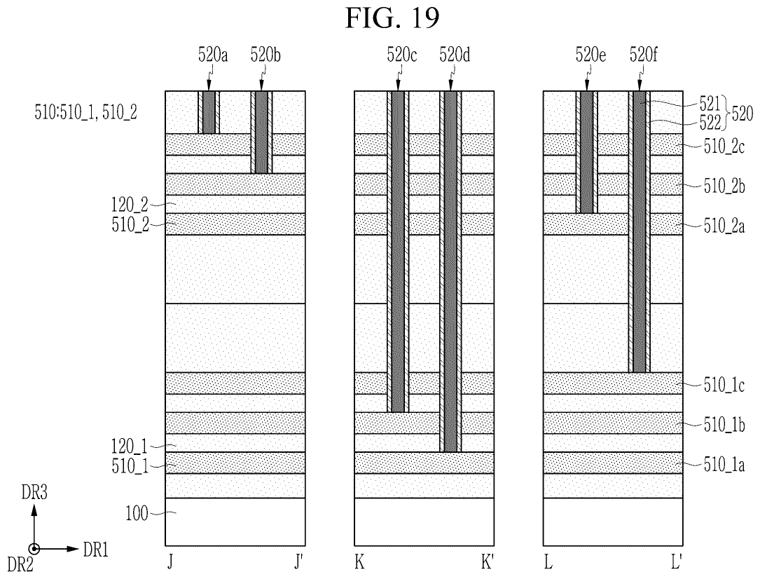

FIG. 16 is a cross-sectional view taken along lines J-J′, K-K′, and L-L′ of FIG. 12. FIG. 17 is a cross-sectional view taken along lines J-J′, K-K′, and L-L′ of FIG. 12. FIG. 18 is a cross-sectional view taken along lines J-J′, K-K′, and L-L′ of FIG. 12. FIG. 19 is a cross-sectional view taken along lines J-J′, K-K′, and L-L′ of FIG. 12. In the embodiments illustrated in FIGS. 16 to 19, components identical or corresponding to those illustrated in FIGS. 12 to 15 may be referenced by the same symbols. The embodiments illustrated in FIGS. 16 to 19 may differ in some respects from the embodiments illustrated in FIGS. 12 to 15 in the connection relationship between the plurality of word line contacts 520 and the plurality of word line pads 510. Below, the differences from the previous example are mainly explained, and any duplicate explanations are omitted or simplified.

According to embodiments illustrated in FIG. 16, the word line pads 510 respectively connected to the word line contacts 520 spaced apart and arranged in the first direction DR1 may be included in different cell structures.

The first word line contact 520a and the second word line contact 520b, which are spaced apart and arranged in the first direction DR1, may be connected to the second word line pad 510_2 included in the second cell structure CS2 and the first word line pad 510_1 included in the first cell structure CS1, respectively. For example, the first word line contact 520a may be connected to the sixth layer word line pad 510_2c included in the second cell structure CS2, and the second word line contact 520b may be connected to the third layer word line pad 510_1c included in the first cell structure CS1.

The third word line contact 520c and the fourth word line contact 520d, which are spaced apart and arranged in the first direction DR1, may be connected to the second word line pad 510_2 included in the second cell structure CS2 and the first word line pad 510_1 included in the first cell structure CS1, respectively. For example, the third word line contact 520c may be connected to the fifth layer word line pad 510_2b included in the second cell structure CS2, and the fourth word line contact 520d may be connected to the second layer word line pad 510_1b included in the first cell structure CS1.

The fifth word line contact 520e and the sixth word line contact 520f, which are spaced apart and arranged in the first direction DR1, may be connected to the second word line pad 510_2 included in the second cell structure CS2 and the first word line pad 510_1 included in the first cell structure CS1, respectively. For example, the fifth word line contact 520e may be connected to the fourth layer word line pad 510_2a included in the second cell structure CS2, and the sixth word line contact 520f may be connected to the first layer word line pad 510_1a included in the first cell structure CS1.

According to embodiments, the word line pads 510 respectively connected to the word line contacts 520 spaced apart and arranged in the second direction DR2 may be included in the same cell structure.

The first word line contact 520a, the third word line contact 520c, and the fifth word line contact 520e, which are spaced apart and arranged in the second direction DR2, may be connected to the second word line pads 510_2 included in the second cell structure CS2, respectively. For example, the first word line contact 520a may be connected to the sixth layer word line pad 510_2c included in the second cell structure CS2, the third word line contact 520c may be connected to the fifth layer word line pad 510_2b included in the second cell structure CS2, and the fifth word line contact 520e may be connected to the fourth layer word line pad 510_2a included in the second cell structure CS2.

The second word line contact 520b, the fourth word line contact 520d, and the sixth word line contact 520f, which are spaced apart and arranged in the second direction DR2, may be connected to the first word line pads 510_1 included in the first cell structure CS1, respectively. For example, the second word line contact 520b may be connected to the third layer word line pad 510_1c included in the first cell structure CS1, the fourth word line contact 520d may be connected to the second layer word line pad 510_1b included in the first cell structure CS1, and 56 the sixth word line contact 520f may be connected to the first layer word line pad 510_1a included in the first cell structure CS1.

According to embodiments, the plurality of word line contacts 520 spaced apart and arranged in the second direction DR2 may have their lengths gradually increased along the second direction DR2. The word line contacts 520 spaced apart and arranged in the second direction DR2 may be connected to the word line pads 510 located in a consecutive layer.

For example, the first word line contact 520a may be connected to the sixth layer word line pad 510_2c, which is the uppermost word line pad of the second cell structure CS2. The third word line contact 520c may be connected to the fifth layer word line pad 510_2b by penetrating the sixth layer word line pad 510 2c. The fifth word line contact 520e may be connected to the fourth layer word line pad 510_2a by penetrating the sixth layer word line pad 510_2c and the fifth layer word line pad 510_2b. The number of word line pads 510 through which the first word line contact 520a, the third word line contact 520c, and the fifth word line contact 520e penetrate may gradually increase. The lengths of the first word line contact 520a, the third word line contact 520c, and the fifth word line contact 520e along the third direction DR3 may gradually increase. The sixth layer word line pad 510_2c, the fifth layer word line pad 510_2b, and the fourth layer word line pad 510_2a, which are respectively connected to the first word line contact 520a, the third word line contact 520c, and the fifth word line contact 520e, may be located in a consecutive layer.

For example, the second word line contact 520b may be connected to the third layer word line pad 510_1c, which is the uppermost word line pad of the first cell structure CS1, by penetrating the sixth layer word line pad 510_2c, the fifth layer word line pad 510_2b, and the fourth layer word line pad 510_2a. The fourth word line contact 520d may be connected to the second layer word line pad 510_1b by penetrating the sixth layer word line pad 510_2c, the fifth layer word line pad 510_2b, the fourth layer word line pad 510_2a, and the third layer word line pad 510 1c. The sixth word line contact 520f may be connected to the first layer word line pad 510_1a by penetrating the sixth layer word line pad 510_2c, the fifth layer word line pad 510_2b, the fourth layer word line pad 510_2a, the third layer word line pad 510_1c, and the second layer word line pad 510_1b. The number of word line pads 510 through which the second word line contact 520b, the fourth word line contact 520d, and the sixth word line contact 520f penetrate may gradually increase. The lengths of the second word line contact 520b, the fourth word line contact 520d, and the sixth word line contact 520f along the third direction DR3 may gradually increase. The third layer word line pad 510_1c, the second layer word line pad 510_1b, and the first layer word line pad 510_1a, which are respectively connected to the second word line contact 520b, the fourth word line contact 520d, and the sixth word line contact 520f, may be located in a consecutive layer.

However, it is not limited to the above-described embodiments. For example, among the plurality of word line contacts 520, lengths of the word line contacts 520 spaced apart and arranged in the second direction DR2 may gradually decrease.

According to embodiments illustrated in FIG. 17, the word line pads 510 respectively connected to the word line contacts 520 spaced apart and arranged in the first direction DR1, as in embodiments illustrated in FIG. 16, may be included in different cell structures.

The first word line contact 520a and the second word line contact 520b, which are spaced apart and arranged in the first direction DR1, may be connected to the second word line pad 510_2 included in the second cell structure CS2 and the first word line pad 510_1 included in the first cell structure CS1, respectively. For example, the first word line contact 520a may be connected to the sixth layer word line pad 510_2c included in the second cell structure CS2, and the second word line contact 520b may be connected to the third layer word line pad 510_1c included in the first cell structure CS1.

The third word line contact 520c and the fourth word line contact 520d, which are spaced apart and arranged in the first direction DR1, may be connected to the second word line pad 510_2 included in the second cell structure CS2 and the first word line pad 510_1 included in the first cell structure CS1, respectively. For example, the third word line contact 520c may be connected to the fourth layer word line pad 510_2a included in the second cell structure CS2, and the fourth word line contact 520d may be connected to the first layer word line pad 510_1a included in the first cell structure CS1.

The fifth word line contact 520e and the sixth word line contact 520f, which are spaced apart and arranged in the first direction DR1, may be connected to the second word line pad 510_2 included in the second cell structure CS2 and the first word line pad 510_1 included in the first cell structure CS1, respectively. For example, the fifth word line contact 520e may be connected to the fifth layer word line pad 510_2b included in the second cell structure CS2, and the sixth word line contact 520f may be connected to the second layer word line pad 510_1b included in the first cell structure CS1.

According to embodiments, the word line pads 510 respectively connected to the word line contacts 520 spaced apart and arranged in the second direction DR2, as in embodiments illustrated in FIG. 16, may be included in the same cell structure.

The first word line contact 520a, the third word line contact 520c, and the fifth word line contact 520e, which are spaced apart and arranged in the second direction DR2, may be connected to the second word line pads 510_2 included in the second cell structure CS2, respectively. For example, the first word line contact 520a may be connected to the sixth layer word line pad 510_2c included in the second cell structure CS2, the third word line contact 520c may be connected to the fourth layer word line pad 510_2a included in the second cell structure CS2, and the fifth word line contact 520e may be connected to the fifth layer word line pad 510_2b included in the second cell structure CS2.

The second word line contact 520b, the fourth word line contact 520d, and the sixth word line contact 520f, which are spaced apart and arranged in the second direction DR2, may be connected to the first word line pads 510_1 included in the first cell structure CS1, respectively. For example, the second word line contact 520b may be connected to the third layer word line pad 510_1c included in the first cell structure CS1, the fourth word line contact 520d may be connected to the first layer word line pad 510_1a included in the first cell structure CS1, and the sixth word line contact 520f may be connected to the second layer word line pad 510_1b included in the first cell structure CS1.

According to embodiments, unlike embodiments illustrated in FIG. 16, the word line contacts 520 spaced apart and arranged in the second direction DR2 among the plurality of word line contacts 520 may have a longer length as they are located farther from the cell region CR. Among the plurality of word line contacts 520, the word line contacts 520 spaced apart in the second direction DR2 may have word line pads 510 connected to the word line contacts 520 positioned at a lower layer as they get farther away from the cell region CR. Referring to FIG. 12 together, the cell region CR may be a region where the plurality of semiconductor patterns 130, the bit line BL, the plurality of capacitors 170, and the plurality of word lines WL are positioned, and the pad region PR may be a region where the plurality of word line pads 510 are positioned. The pad region PR may be located on one side of the cell region CR along the second direction DR2. For example, the plurality of cell regions CR may be arranged and spaced apart in the second direction DR2, and the pad region PR may be positioned between the plurality of cell regions CR spaced apart in the second direction DR2. Among the word line contacts 520 spaced apart and arranged in the second direction DR2, the word line contact 520 that is furthest from the cell region CR may have the longest length. Among the word line contacts 520 spaced apart and arranged in the second direction DR2, a word line pad 510 connected to a word line contact 520 that is furthest from the cell region CR may be located at the lowest layer.

For example, the first word line contact 520a may be connected to the sixth layer word line pad 510_2c, the third word line contact 520c may be connected to the fourth layer word line pad 510_2a, and the fifth word line contact 520e may be connected to the fifth layer word line pad 510_2b. The fourth layer word line pad 510_2a may be the second word line pad 510_2 located at the lowest layer within the second cell structure CS2. Among the first word line contact 520a, the third word line contact 520c, and the fifth word line contact 520e that are spaced apart and arranged in the second direction DR2, the length of the third word line contact 520c that is furthest from the cell region CR may be the longest along the third direction DR3. The fourth layer word line pad 510_2a connected to the third word line contact 520c, which is the farthest from the cell region CR among the first word line contact 520a, the third word line contact 520c, and the fifth word line contact 520e, may be located at the lowest layer.

For example, the second word line contact 520b may be connected to the third layer word line pad 510_1c, the fourth word line contact 520d may be connected to the first layer word line pad 510_1a, and the sixth word line contact 520f may be connected to the second layer word line pad 510_1b. The first layer word line pad 510_1a may be the first word line pad 510_1 located at the lowest layer within the first cell structure CS1. Among the second word line contact 520b, the fourth word line contact 520d, and the sixth word line contact 520f that are spaced apart and arranged in the second direction DR2, the fourth word line contact 520d, which is furthest from the cell region CR, may have the longest length along the third direction DR3. The first layer word line pad 510_1a connected to the fourth word line contact 520d, which is the furthest from the cell region CR among the second word line contact 520b, the fourth word line contact 520d, and the sixth word line contact 520f, may be located at the lowest layer.

In the above-described embodiment, when the cell region CR is positioned on both sides of the pad region PR along the second direction DR2, the word line contact 520 in the middle among the word line contacts 520 spaced apart and arranged in the second direction DR2 may be the farthest from the cell region CR. However, the examples are not limited to this. For example, when the cell region CR is positioned only on one side of the pad region PR along the second direction DR2, the length of the word line contacts 520 spaced apart and arranged in the second direction DR2 may become longer as they are positioned farther from the cell region CR along the second direction DR2.

According to embodiments illustrated in FIG. 18, the word line pads 510 respectively connected to the word line contacts 520 spaced apart and arranged in the first direction DR1, as in embodiments illustrated in FIG. 16, may be included in different cell structures.

The first word line contact 520a and the second word line contact 520b, which are spaced apart and arranged in the first direction DR1, may be connected to the second word line pad 510_2 included in the second cell structure CS2 and the first word line pad 510_1 included in the first cell structure CS1, respectively. For example, the first word line contact 520a may be connected to the sixth layer word line pad 510_2c included in the second cell structure CS2, and the second word line contact 520b may be connected to the first layer word line pad 510_1a included in the first cell structure CS1.

The third word line contact 520c and the fourth word line contact 520d, which are spaced apart and arranged in the first direction DR1, may be connected to the second word line pad 510_2 included in the second cell structure CS2 and the first word line pad 510_1 included in the first cell structure CS1, respectively. For example, the third word line contact 520c may be connected to the fifth layer word line pad 510_2b included in the second cell structure CS2, and the fourth word line contact 520d may be connected to the second layer word line pad 510_1b included in the first cell structure CS1.

The fifth word line contact 520e and the sixth word line contact 520f, which are spaced apart and arranged in the first direction DR1, may be connected to the second word line pad 510_2 included in the second cell structure CS2 and the first word line pad 510_1 included in the first cell structure CS1, respectively. For example, the fifth word line contact 520e may be connected to the fourth layer word line pad 510_2a included in the second cell structure CS2, and the sixth word line contact 520f may be connected to the third layer word line pad 510_1c included in the first cell structure CS1.

According to embodiments, the word line pads 510 respectively connected to the word line contacts 520 spaced apart and arranged in the second direction DR2, as in embodiments illustrated in FIG. 16, may be included in the same cell structure.

The first word line contact 520a, the third word line contact 520c, and the fifth word line contact 520e, which are spaced apart and arranged in the second direction DR2, may be connected to the second word line pads 510_2 included in the second cell structure CS2, respectively. For example, the first word line contact 520a may be connected to the sixth layer word line pad 510_2c included in the second cell structure CS2, the third word line contact 520c may be connected to the fifth layer word line pad 510_2b included in the second cell structure CS2, and the fifth word line contact 520e may be connected to the fourth layer word line pad 510_2a included in the second cell structure CS2.

The second word line contact 520b, the fourth word line contact 520d, and the sixth word line contact 520f, which are spaced apart and arranged in the second direction DR2, may be connected to the first word line pads 510_1 included in the first cell structure CS1, respectively. For example, the second word line contact 520b may be connected to the first layer word line pad 510_1a included in the first cell structure CS1, the fourth word line contact 520d may be connected to the second layer word line pad 510_1b included in the first cell structure CS1, and the sixth word line contact 520f may be connected to the third layer word line pad 510 1c included in the first cell structure CS1.

According to embodiments, unlike embodiments illustrated in FIG. 16, the shortest word line contact 520 and the longest word line contact 520 among the plurality of word line contacts 520 may be arranged along the first direction DR1.

For example, the diameter of the word line contact 520 may increase as the length extending along the third direction DR3 becomes longer. The longer the length of the word line contact 520 along the third direction DR3, the greater the number of word line pads 510 through which the word line contact 520 penetrates. As the length of the word line contact 520 in the third direction DR3 increases, the word line pad 510 connected to the word line contact 520 may be located at a lower layer. The diameter of a word line contact 520 connected to a relatively low word line pad 510 may be larger than the diameter of a word line contact 520 connected to a relatively high word line pad 510. Accordingly, the diameter of the word line contact 520 connected to the uppermost word line pad 510 may be the smallest, and the diameter of the word line contact 520 connected to the lowermost word line pad 510 may be the largest. For example, the diameter of the word line contact 520 may gradually become smaller as it approaches the upper surface of the substrate 100. In embodiments, the diameter of the word line contact 520 may mean the diameter of the top of the word line contact 520 or maximum diameter.

For example, among the plurality of word line contacts 520, the word line contacts 520 arranged along the first direction DR1 may include the first word line contact 520a having the shortest length along the third direction DR3 and the second word line contact 520b having the longest length along the third direction DR3. The first word line contact 520a having the shortest length along the third direction DR3 and the second word line contact 520b having the longest length along the third direction DR3 may be arranged along the first direction DR1. The first word line contact 520a connected to the sixth layer word line pad 510_2c, which is the uppermost word line pad, and the second word line contact 520b connected to the first layer word line pad 510_1a, which is the lowermost word line pad, may be arranged along the first direction DR1. The first word line contact 520a having the smallest diameter and the second word line contact 520b having the largest diameter may be arranged along the first direction DR1.

For example, among the plurality of word line contacts 520, an n-th (n≥1) shortest word line contact 520 and an n-th longest word line contact 520 may be arranged along the first direction DR1. A word line contact 520 connected to an n-th (n≥1) highest-layer word line pad 510, and a word line contact 520 connected to an n-th lowest-layer word line pad 510, among the plurality of word line pads 510, may be arranged along the first direction DR1.

For example, the second shortest third word line contact 520c and the second longest fourth word line contact 520d among the plurality of word line contacts 520 may be arranged along the first direction DR1. The third word line contact 520c connected to the fifth layer word line pad 510_2b located at the second highest layer among the plurality of word line pads 510, and the fourth word line contact 520d connected to the second layer word line pad 510_1b located at the second lowest layer among the plurality of word line pads 510 may be arranged along the first direction DR1.

For example, the third shortest fifth word line contact 520e and the third longest sixth word line contact 520f among the plurality of word line contacts 520 may be arranged along the first direction DR1. The fifth word line contact 520e connected to the fourth layer word line pad 510_2a located at the third highest layer among the plurality of word line pads 510, and the sixth word line contact 520f connected to the third layer word line pad 510_1c located at the third lowest layer among the plurality of word line pads 510 may be arranged along the first direction DR1.

The fact that an n-th (n≥1) longest word line contact 520 and an n-th shortest word line contact 520, among the plurality of word line contacts 520, are arranged along the first direction DR1 may indicate that an n-th (n≥1) largest-diameter word line contact 520 and an n-th smallest-diameter word line contact 520 among the plurality of word line contacts 520 are arranged along the first direction DR1. By arranging an n-th (n≥1) largest-diameter word line contact 520 and an n-th smallest-diameter word line contact 520 along the first direction DR1, it is possible to reduce or prevent short circuits between the word line contacts 520 arranged along the first direction DR1.

According to embodiments illustrated in FIG. 19, lengths of the word line contacts 520 spaced apart from one another in the first direction DR1 among the plurality of word line contacts 520 and arranged like embodiments illustrated in FIG. 15 may gradually increase. The word line contacts 520 spaced apart and arranged in the first direction DR1 may be connected to the word line pads 510 located in a consecutive layer.

For example, the first word line contact 520a may be connected to the sixth layer word line pad 510_2c, which is the uppermost word line pad. The second word line contact 520b may be connected to the fifth layer word line pad 510_2b by penetrating the sixth layer word line pad 510_2c. The number of word line pads 510 through which the first word line contact 520a and the second word line contact 520b penetrate may gradually increase. The lengths of the first word line contact 520a and the second word line contact 520b along the third direction DR3 may gradually increase. The sixth layer word line pad 510_2c and the fifth layer word line pad 510_2b, which are respectively connected to the first word line contact 520a and the second word line contact 520b, may be located in a consecutive layer.

For example, the third word line contact 520c may be connected to the second layer word line pad 510_1b by penetrating the sixth layer word line pad 510_2c, the fifth layer word line pad 510_2b, the fourth layer word line pad 510_2a, and the third layer word line pad 510_1c. The fourth word line contact 520d may be connected to the first layer word line pad 510_1a by penetrating the sixth layer word line pad 510_2c, the fifth layer word line pad 510_2b, the fourth layer word line pad 510_2a, the third layer word line pad 510_1c, and the second layer word line pad 510 1b. The number of word line pads 510 through which the third word line contact 520c and the fourth word line contact 520d penetrate may gradually increase. The lengths of the third word line contact 520c and the fourth word line contact 520d along the third direction DR3 may gradually increase. The second layer word line pad 510_1b and the first layer word line pad 510_1a, which are respectively connected to the third word line contact 520c and the fourth word line contact 520d, may be located in a consecutive layer.

For example, the fifth word line contact 520e may be connected to the fourth layer word line pad 510_2a by penetrating the sixth layer word line pad 510_2c and the fifth layer word line pad 510_2b. The sixth word line contact 520f may be connected to the third layer word line pad 510_1c by penetrating the sixth layer word line pad 510_2c, the fifth layer word line pad 510_2b, and the fourth layer word line pad 510_2a. The number of word line pads 510 through which the fifth word line contact 520e and the sixth word line contact 520f penetrate may gradually increase. The lengths of the fifth word line contact 520e and the sixth word line contact 520f along the third direction DR3 may gradually increase. The fourth layer word line pad 510_2a and the third layer word line pad 510_1c, which are respectively connected to the fifth word line contact 520e and the sixth word line contact 520f, may be located in a consecutive layer.

However, it is not limited to the above-described embodiments. For example, among the plurality of word line contacts 520, lengths of the word line contacts 520 spaced apart and arranged in the first direction DR1 may gradually decrease.

According to embodiments illustrated in FIG. 19, unlike embodiments illustrated in FIG. 15, among the plurality of word line contacts 520, the word line contacts 520 spaced apart in the second direction DR2 may have a longer length as they are located farther from the cell region CR. Among the plurality of word line contacts 520, the word line contacts 520 spaced apart in the second direction DR2 may have word line pads 510 connected to the word line contacts 520 positioned at a lower layer as they get farther away from the cell region CR.

Referring to FIG. 12 together, the cell region CR may be a region where the plurality of semiconductor patterns 130, the bit line BL, the plurality of capacitors 170, and the plurality of word lines WL are positioned, and the pad region PR may be a region where the plurality of word line pads 510 are positioned. The pad region PR may be located on one side of the cell region CR along the second direction DR2. For example, the plurality of cell regions CR may be arranged and spaced apart in the second direction DR2, and the pad region PR may be positioned between the plurality of cell regions CR spaced apart in the second direction DR2. Among the word line contacts 520 spaced apart and arranged in the second direction DR2, the word line contact 520 that is furthest from the cell region CR may have the longest length. Among the word line contacts 520 spaced apart and arranged in the second direction DR2, a word line pad 510 connected to a word line contact 520 that is furthest from the cell region CR may be located at the lowest layer.

For example, the first word line contact 520a may be connected to the sixth layer word line pad 510_2c, the third word line contact 520c may be connected to the second layer word line pad 510_1b, and the fifth word line contact 520e may be connected to the fourth layer word line pad 510_2a. The second layer word line pad 510_1b may be located at the lowest layer among the sixth layer word line pad 510_2c, the second layer word line pad 510_1b, and the fourth layer word line pad 510_2a. Among the first word line contact 520a, the third word line contact 520c, and the fifth word line contact 520e that are spaced apart and arranged in the second direction DR2, the third word line contact 520c that is furthest from the cell region CR may have the longest length along the third direction DR3. The second layer word line pad 510_1b connected to the third word line contact 520c that is furthest from the cell region CR among the first word line contact 520a, the third word line contact 520c, and the fifth word line contact 520e may be located at the lowest layer.

For example, the second word line contact 520b may be connected to the fifth layer word line pad 510_2b, the fourth word line contact 520d may be connected to the first layer word line pad 510_1a, and the sixth word line contact 520f may be connected to the third layer word line pad 510_1c. The first layer word line pad 510_1a may be located at the lowest layer among the fifth layer word line pad 510_2b, the first layer word line pad 510_1a, and the third layer word line pad 510_1c. Among the second word line contact 520b, the fourth word line contact 520d, and the sixth word line contact 520f that are spaced apart and arranged in the second direction DR2, the fourth word line contact 520d, which is furthest from the cell region CR, may have the longest length along the third direction DR3. The first layer word line pad 510_1a connected to the fourth word line contact 520d, which is the furthest from the cell region CR among the second word line contact 520b, the fourth word line contact 520d, and the sixth word line contact 520f, may be located at the lowest layer.

In the above-described embodiment, when the cell region CR is positioned on both sides of the pad region PR along the second direction DR2, the word line contact 520 in the middle among the word line contacts 520 spaced apart and arranged in the second direction DR2 may be the farthest from the cell region CR. However, the examples are not limited to this. For example, when the cell region CR is positioned only on one side of the pad region PR along the second direction DR2, the length of the word line contacts 520 spaced apart and arranged in the second direction DR2 may become longer as they are located farther from the cell region CR along the second direction DR2.

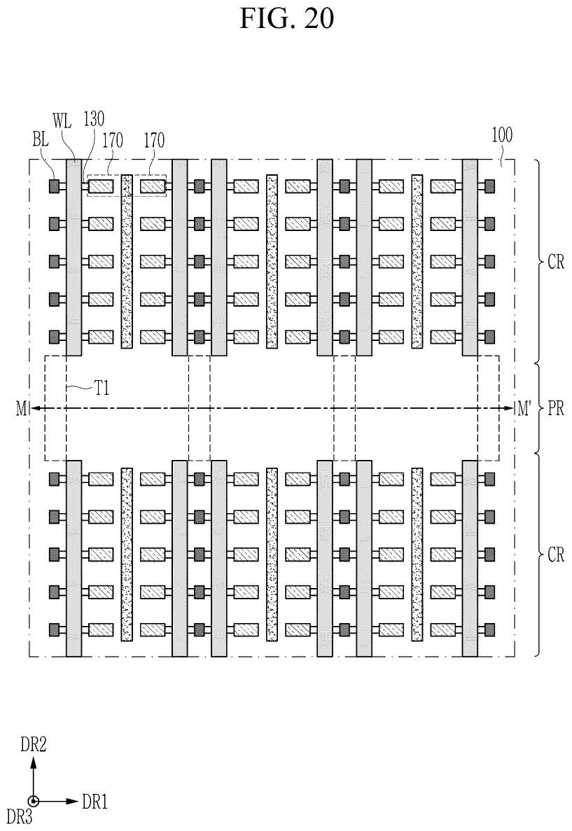

Hereinafter, a portion of a method for manufacturing a semiconductor device according to the embodiments shown in FIGS. 1 to 8 will be described with reference to FIGS. 20 to 39.

FIGS. 20, 23, 25, 28, 31, 33, and 36 are plan views illustrating a portion of a method for manufacturing a semiconductor device according to embodiments.

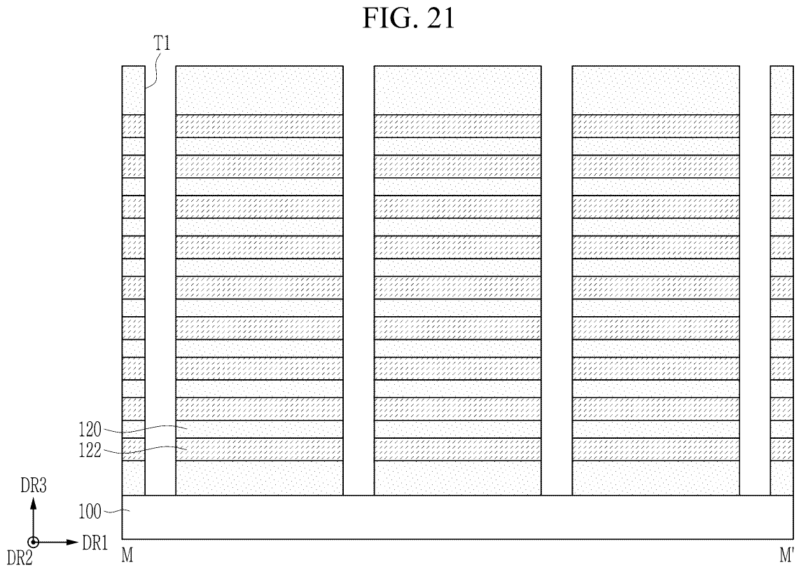

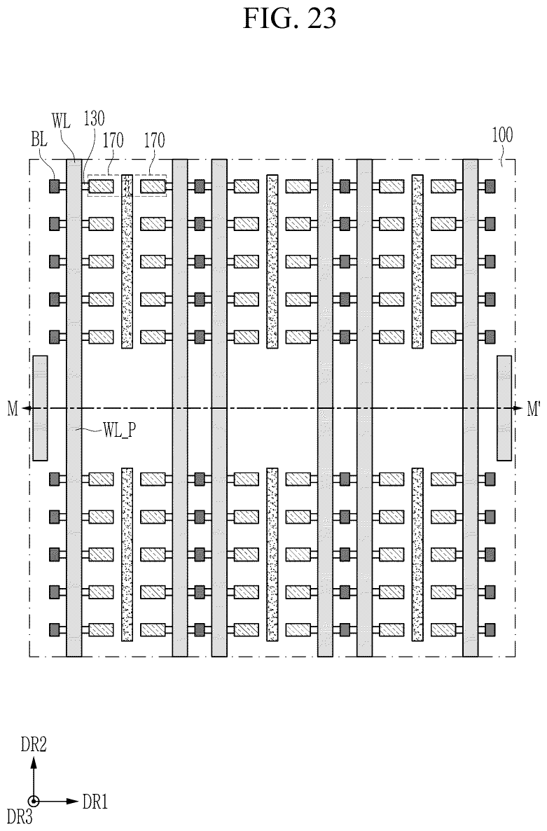

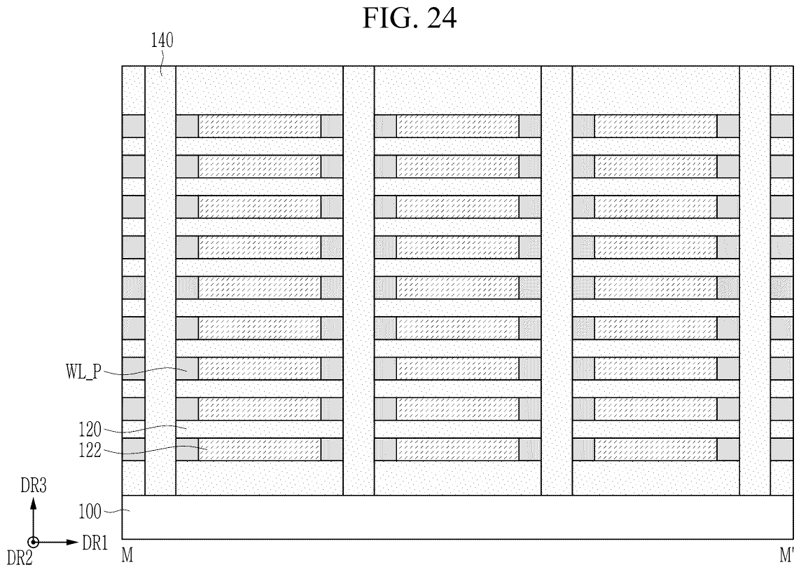

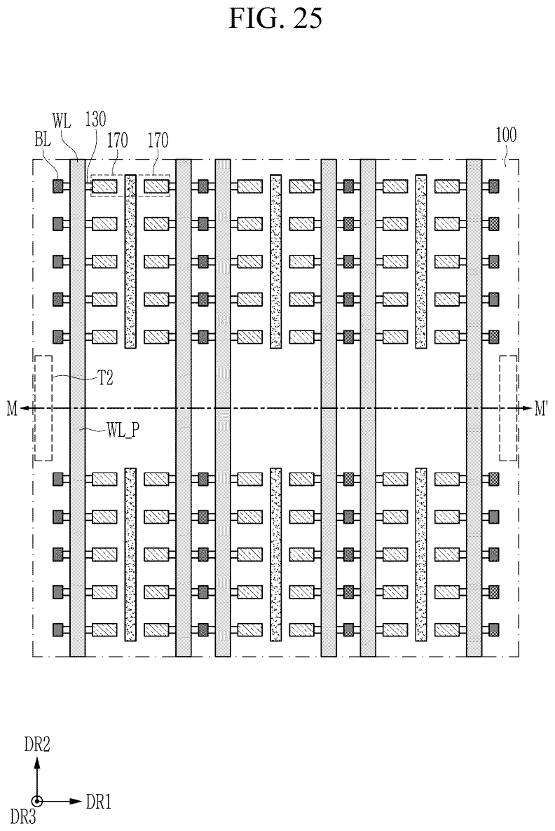

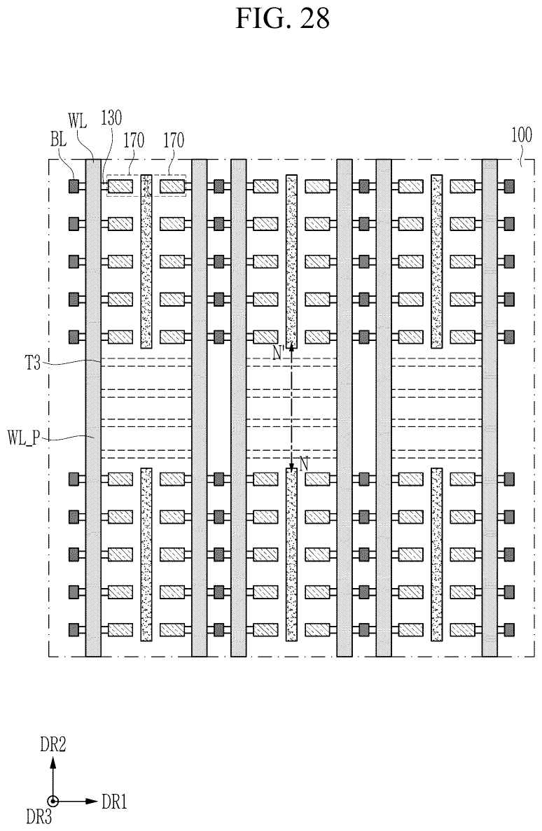

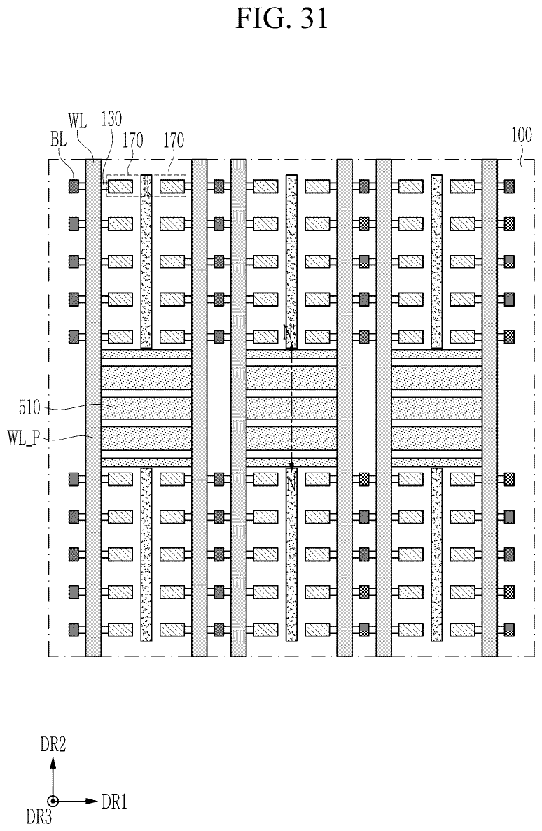

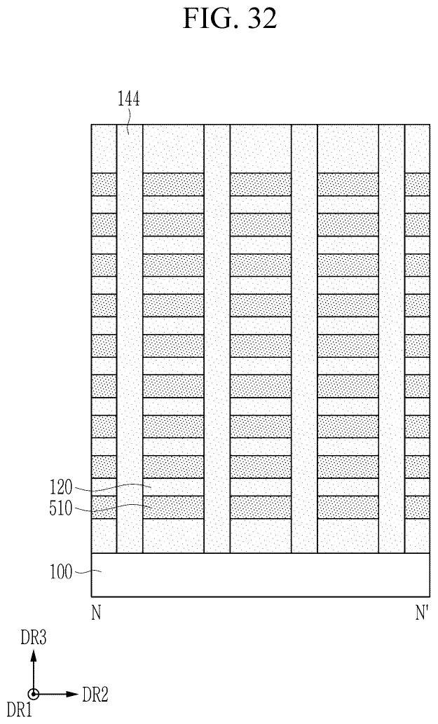

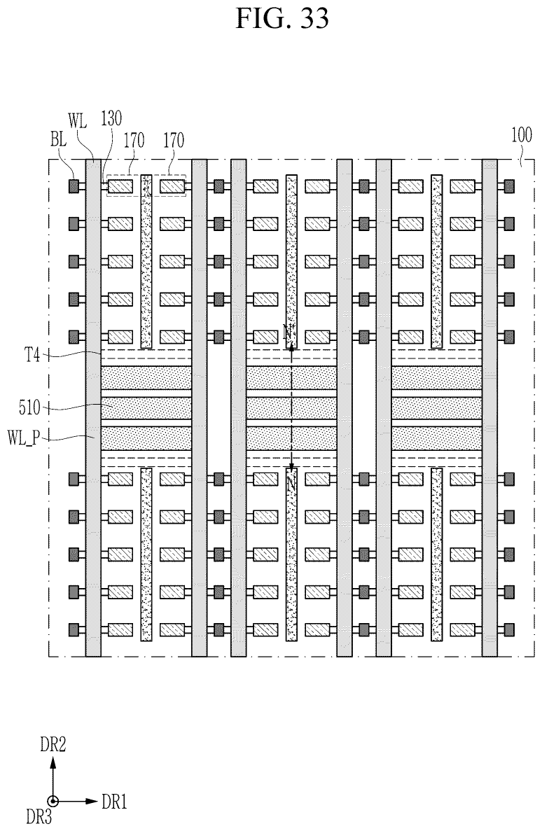

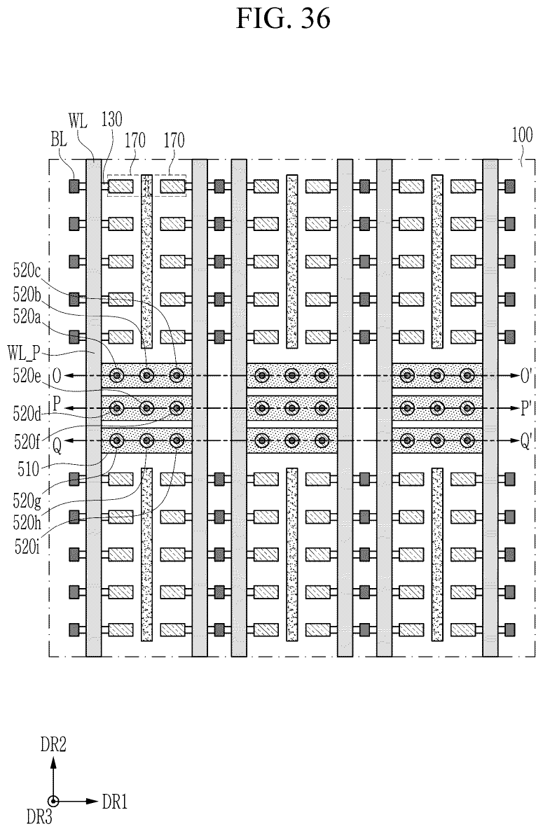

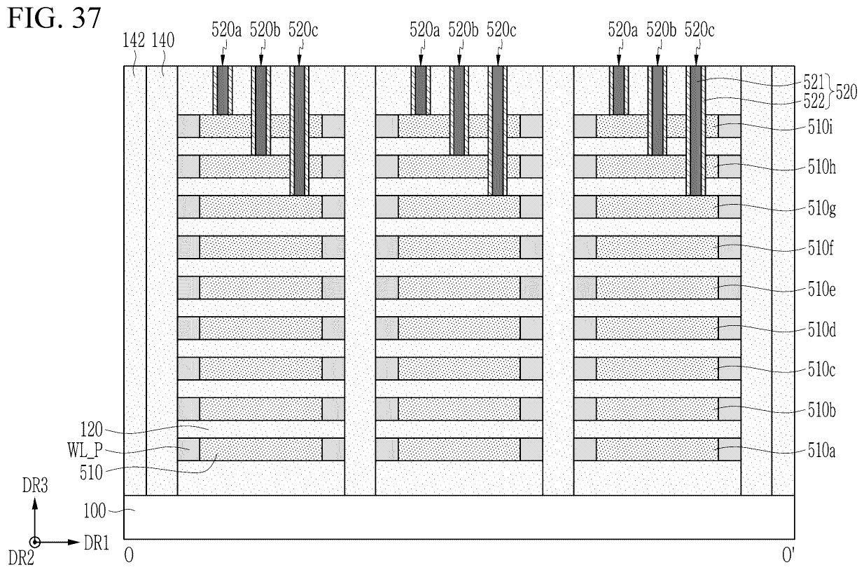

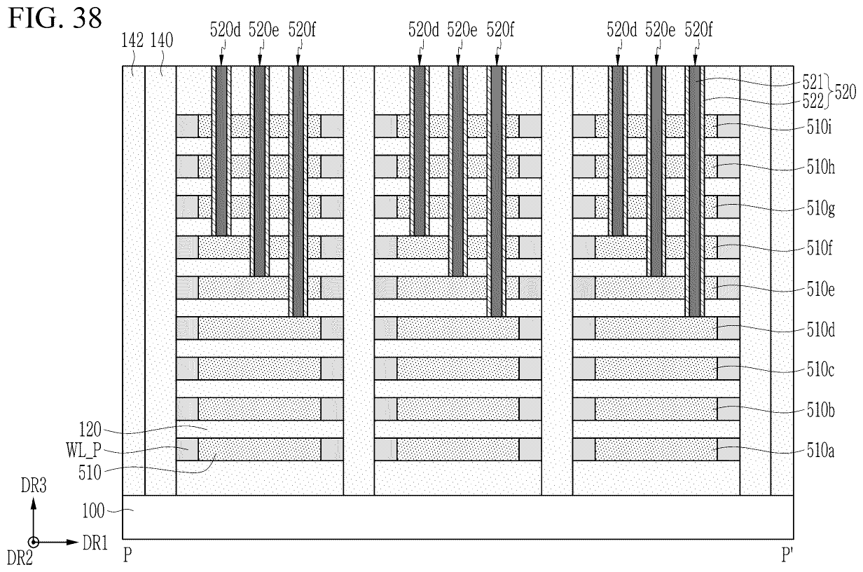

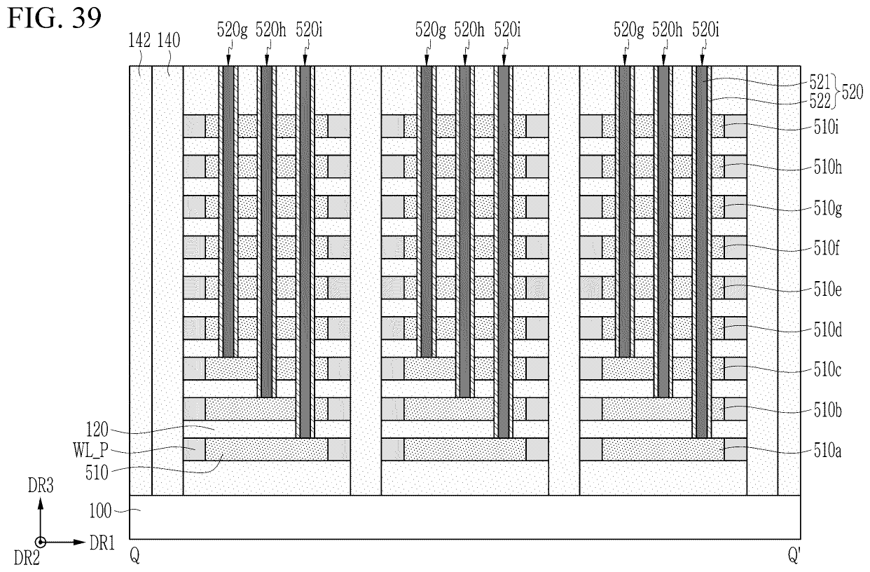

FIGS. 21, 22, 24, 26, 27, 29, 30, 32, 34, 35, 37, 38, and 39 are cross-sectional views illustrating a portion of a method for manufacturing a semiconductor device according to embodiments. FIG. s 21 and 22 are cross-sectional views taken along line M-M′ of FIG. 20. FIG. 24 is a cross-sectional view taken along line M-M′ of FIG. 23. FIG. s 26 and 27 are cross-sectional views taken along line M-M′ of FIG. 25. FIG. s 29 and 30 are cross-sectional views taken along line N-N′ of FIG. 28. FIG. 32 is a cross-sectional view taken along the line N-N′ of FIG. 31. FIG. s 34 and 35 are cross-sectional views taken along line N-N′ of FIG. 33. FIG. 37 is a cross-sectional view taken along line O-O′ of FIG. 36. FIG. 38 is a cross-sectional view taken along line P-P′ of FIG. 36. FIG. 39 is a cross-sectional view taken along line Q-Q′ of FIG. 36. Section lines referenced by the same drawing symbol may indicate the same location.

A plurality of memory cells may be formed on a cell region CR of a substrate 100. Each of the plurality of memory cells may include a semiconductor pattern 130 extending in a first direction DR1 parallel to an upper surface of the substrate 100, a bit line BL connected to one side surface of the semiconductor pattern 130 along the first direction DR1 and extending in a third direction DR3 perpendicular to the upper surface of the substrate 100, a capacitor 170 connected to the other side surface of the semiconductor pattern 130 along the first direction DR1, a word line WL crossing the semiconductor pattern 130 and extending in a second direction DR2, and a gate insulating layer Gox positioned between the semiconductor pattern 130 and the word line WL. The second direction DR2 may be a direction parallel to the upper surface of the substrate 100 and intersecting the first direction DR1. For example, the second direction DR2 may be a direction orthogonal to the first direction DR1.

The plurality of memory cells may be arranged and spaced apart in the first direction DR1 and the second direction DR2, and may be arranged and spaced apart in the third direction DR3. That is, a plurality of semiconductor patterns 130 may be arranged to be spaced apart in the first direction DR1 and the second direction DR2, and may be arranged to be spaced apart in the third direction DR3. A plurality of word lines WLs may be arranged spaced apart in the first direction DR1 and the third direction DR3. A plurality of bit lines BL may be arranged spaced apart in the first direction DR1 and the second direction DR2. A plurality of capacitors 170 may be arranged and spaced apart in the first direction DR1, the second direction DR2, and the third direction DR3. One word line WL may cross the plurality of semiconductor patterns 130 spaced apart and arranged in the second direction DR2. Between two semiconductor patterns 130 spaced apart and arranged in the first direction DR1, one bit line BL may be connected to the two semiconductor patterns 130. Between two semiconductor patterns 130 spaced apart and arranged in the first direction DR1, two capacitors 170 may be connected to each of the two semiconductor patterns 130. One bit line BL and two capacitors 170 may be alternately arranged along the first direction DR1. The plurality of semiconductor patterns 130 spaced apart and arranged in the third direction DR3 may be connected to one bit line BL. The capacitors 170 connected to the plurality of semiconductor patterns 130 spaced apart and arranged in the third direction DR3 may be connected one another in the third direction DR3. The capacitors 170 connected to the plurality of semiconductor patterns 130 spaced apart and arranged in the second direction DR2 may be connected one another in the second direction DR2. Two capacitors 170 positioned between two semiconductor patterns 130 adjacent in the first direction DR1 and each connected to the two semiconductor patterns 130 may be connected one another in the first direction DR1.

As illustrated in FIGS. 20 and 21, a plurality of first trenches T1 may be formed by etching a portion of an interlayer insulating layer 120 and a plurality of semiconductor layers 122 alternately stacked on a pad region PR of the substrate 100 located on one side along the second direction DR2 of the cell region CR. The plurality of first trenches T1 may be arranged and spaced apart in the first direction DR1. Each of the plurality of first trenches T1 is located on one side of the pad region PR along the first direction DR1 that overlaps the word line WL in the second direction DR2 and may have a depth along the third direction DR3. Some of the plurality of first trenches T1 may be located in the pad region PR that overlaps a region between two word lines WL adjacent in the first direction DR1 with the bit line BL therebetween.

The substrate 100 may include a plurality of cell regions CR spaced apart in the second direction DR2, and the pad region PR may be positioned between the plurality of cell regions CR spaced apart in the second direction DR2. The plurality of first trenches T1 may be positioned between the plurality of cell regions CR spaced apart in the second direction DR2.

As the plurality of first trenches T1 are formed, the upper surface of the substrate 100, side surfaces of the interlayer insulating layer 120, and side surfaces of the plurality of semiconductor layers 122 may be exposed.

The interlayer insulating layer 120 may include, for example, silicon oxide, but is not limited thereto. The semiconductor layer 122 may include the same semiconductor material as the semiconductor pattern 130. For example, the semiconductor layer 122 may include, but is not limited to, silicon.

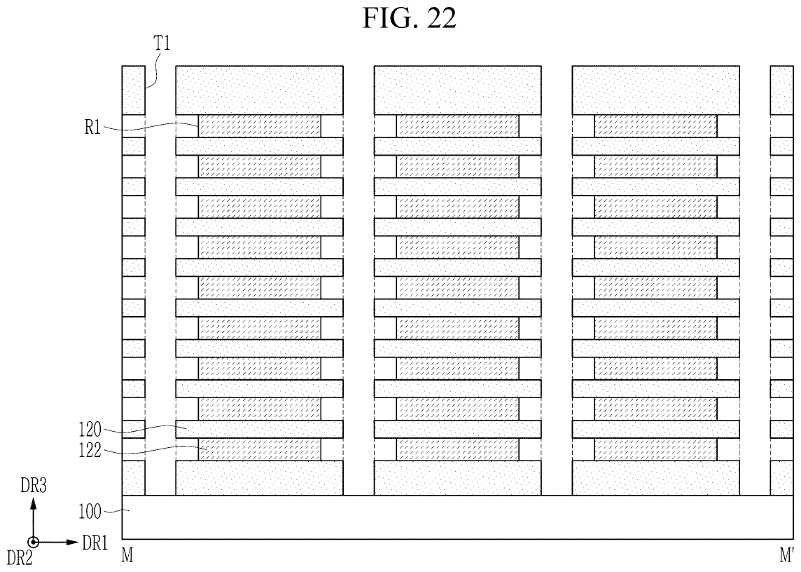

As illustrated in FIG. 22, a plurality of first recesses R1 may be formed by etching portions of the plurality of semiconductor layers 122 through the plurality of first trenches T1. Each of the plurality of first recesses R1 may have a depth along the first direction DR1 that is substantially the same as a length along the first direction DR1 of the word line WL.

As illustrated in FIG. 23 and FIG. 24, a plurality of word line extensions WL_P may be formed within the plurality of first recesses R1 by depositing a conductive material. The word line extension WL_P may include, but is not limited to, the same material as the word line WL.

The plurality of word line extensions WL_P may be arranged spaced apart in the third direction DR3. The plurality of word line extensions WL_P may be arranged spaced apart in the first direction DR1. The word line extension WL_P may extend in the second direction DR2. The word line extension WL_P may be connected to an end of the word line WL located in the cell region CR along the second direction DR2. The word line extension WL_P may connect word lines WL located in each of the plurality of cell regions CR spaced apart in the second direction DR2. The word line extension WL_P may be a part of the word line WL.

Among the plurality of word line extensions WL_P, the word line extensions WL_P located at both edges along the first direction DR1 may not be connected to the word line WL located in the cell region CR.

Next, an insulating material may be deposited to form a first insulating pattern 140 within the plurality of first trenches T1. The first insulating pattern 140 may include the same material as the interlayer insulating layer 120, but is not limited thereto. When the first insulating pattern 140 and the interlayer insulating layer 120 include the same material, the boundary between the first insulating pattern 140 and the interlayer insulating layer 120 may not be visible.

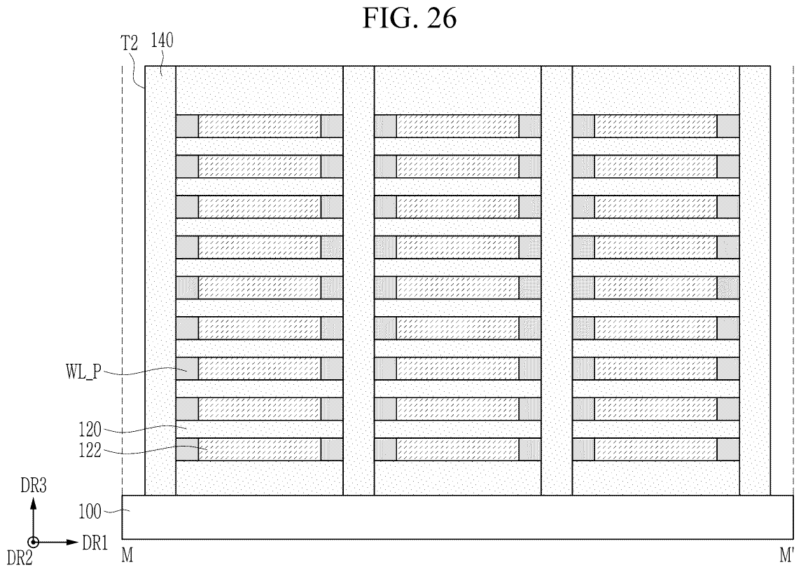

As illustrated in FIG. 25 and FIG. 26, the word line extensions WL_P located at both edges along the first direction DR1 among the plurality of word line extensions WL_P and a portion of the interlayer insulating layer 120 overlapping with the word line extensions WL_P in the third direction DR3 may be etched to form two second trenches T2. The two second trenches T2 may be formed in a region where the word line extensions WL_P located at both edges along the first direction DR1 among the plurality of word line extensions WL_P are located. The second trench T2 may have a depth along the third direction DR3.

As the two second trenches T2 are formed, the word line extensions WL_P located at both edges along the first direction DR1 among the plurality of word line extensions WL_P and not connected to the word line WL located in the cell region CR may be removed.

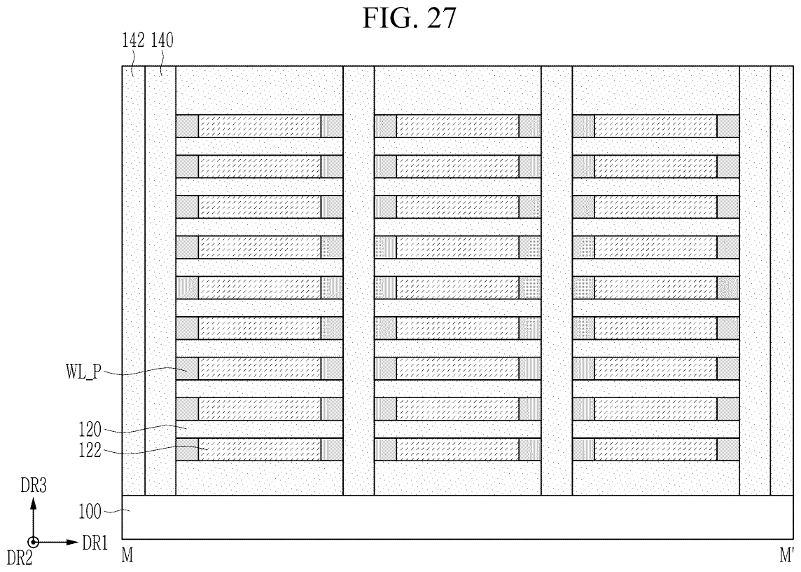

Next, as illustrated in FIG. 27, an insulating material may be deposited to form a second insulating pattern 142 within the two second trenches T2. The second insulating pattern 142 may include the same material as the first insulating pattern 140 and the interlayer insulating layer 120, but is not limited thereto. When the second insulating pattern 142, the first insulating pattern 140, and the interlayer insulating layer 120 include the same material, the boundary between the second insulating pattern 142 and the first insulating pattern 140 and the boundary between the second insulating pattern 142 and the interlayer insulating layer 120 may not be visible.

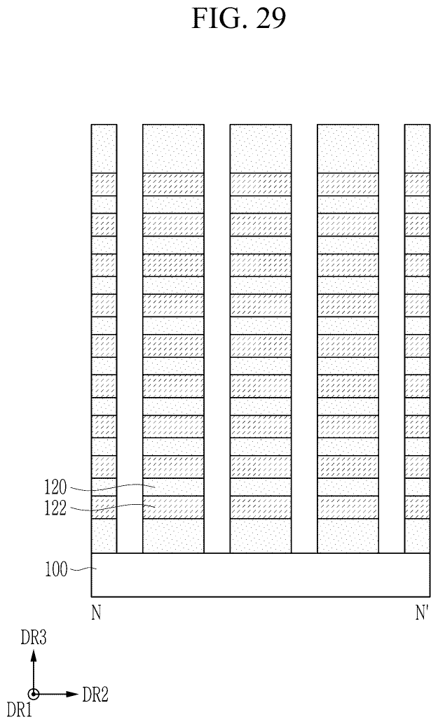

As illustrated in FIGS. 28 and 29, a plurality of third trenches T3 may be formed by etching a portion of the interlayer insulating layer 120 and the plurality of semiconductor layers 122 alternately stacked on the pad region PR overlapping the capacitor 170 of the cell region CR in the second direction DR2. The plurality of third trenches T3 may be located between two word line extensions WL_P spaced apart in the first direction DR1. Each of the two word line extensions WL_P may be respectively connected to two word lines WL located on both sides of two capacitors 170, the two capacitors 170 being positioned between two semiconductor patterns 130 adjacent in the first direction DR1. The plurality of third trenches T3 may be arranged spaced apart in the second direction DR2 between two word line extensions WL_P. The plurality of third trenches T3 may be further arranged and spaced apart in the first direction DR1.

Each of the plurality of third trenches T3 may have a depth along the third direction DR3. As the plurality of third trenches T3 are formed, the upper surface of the substrate 100, side surfaces of the interlayer insulating layer 120, and side surfaces of the plurality of semiconductor layers 122 may be exposed.

The interlayer insulating layer 120 may include, for example, silicon oxide, but is not limited thereto. The semiconductor layer 122 may include the same semiconductor material as the semiconductor pattern 130. For example, the semiconductor layer 122 may include, but is not limited to, silicon.

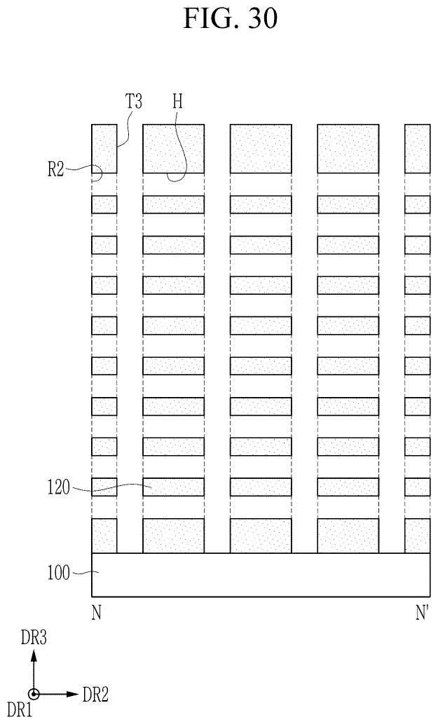

As illustrated in FIG. 30, a plurality of second recesses R2 and a plurality of holes H may be formed by etching a portion of the plurality of semiconductor layers 122 through the plurality of third trenches T3.

The plurality of holes H may be formed as portions of the plurality of semiconductor layers 122 positioned between the plurality of third trenches T3 spaced apart and arranged in the second direction DR2 are etched. The plurality of second recesses R2 may be formed as portions of the plurality of semiconductor layers 122 located on one side adjacent to the cell region CR of the third trenches T3 located at both edges along the second direction DR2 among the plurality of third trenches T3 are etched.

Each of the plurality of holes H may have a depth along the second direction DR2 that is substantially the same as a length along the second direction DR2 between the plurality of third trenches T3 that are spaced apart in the second direction DR2. Each of the plurality of second recesses R2 may have a depth along the second direction DR2 that is substantially equal to half the depth along the second direction DR2 of each of the plurality of holes H.

As illustrated in FIG. 31 and FIG. 32, a plurality of word line pads 510 may be formed within the plurality of second recesses R2 and the plurality of holes H by depositing a conductive material.

Each of the plurality of word line pads 510 may connect between two word line extensions WL_P spaced apart in the first direction DR1. Each of the two word line extensions WL_P may be a part of two word lines WL positioned on both sides of two capacitors 170 positioned between two semiconductor patterns 130 adjacent in the first direction DR1. The plurality of word line pads 510 may overlap the capacitor 170 in the second direction DR2. The plurality of word line pads 510 may be arranged spaced apart in the second direction DR2 between two word lines WL. The plurality of word line pads 510 may be arranged spaced apart in the third direction DR3. The lengths of the plurality of word line pads 510 spaced apart and arranged in the third direction DR3 along the first direction DR1 may be the same. The lengths of the plurality of word line pads 510 spaced apart and arranged in the third direction DR3 along the second direction DR2 may be the same. The plurality of word line pads 510 may be further arranged and spaced apart in the first direction DR1.

Next, an insulating material may be deposited to form a third insulating pattern 144 within the plurality of third trenches T3. The third insulating pattern 144 may include the same material as the interlayer insulating layer 120, but is not limited thereto. When the third insulating pattern 144 and the interlayer insulating layer 120 include the same material, the boundary between the third insulating pattern 144 and the interlayer insulating layer 120 may not be visible.

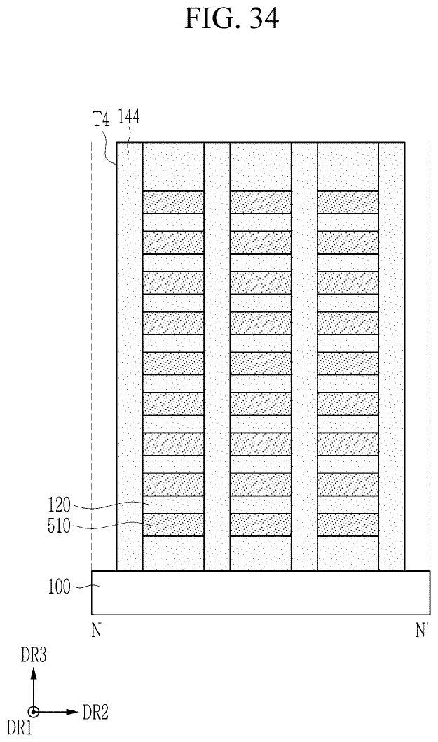

As illustrated in FIG. 33 and FIG. 34, word line pads 510 positioned at both edges along the second direction DR2 among the plurality of word line pads 510 and a portion of the interlayer insulating layer 120 overlapping with the word line pads in the third direction DR3 may be etched to form two fourth trenches T4. The two fourth trenches T4 may be formed in a region where the word line pads 510 located at both edges along the second direction DR2 among the plurality of word line pads 510 are located. The fourth trench T4 may have a depth along the third direction DR3.

As the two fourth trenches T4 are formed, the word line pads 510 located at both edges along the second direction DR2 among the plurality of word line pads 510 and having a length that is half of that of the word line pads 510 along the second direction DR2 may be removed.

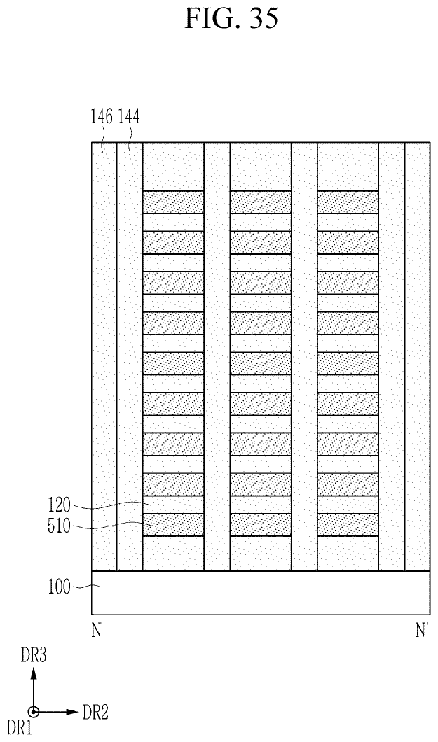

Next, as illustrated in FIG. 35, an insulating material may be deposited to form a fourth insulating pattern 146 within the two fourth trenches T4. The fourth insulating pattern 146 may include the same material as the third insulating pattern 144 and the interlayer insulating layer 120, but is not limited thereto. When the fourth insulating pattern 146, the third insulating pattern 144, and the interlayer insulating layer 120 include the same material, the boundary between the fourth insulating pattern 146 and the third insulating pattern 144 and the boundary between the fourth insulating pattern 146 and the interlayer insulating layer 120 may not be visible.

As illustrated in FIGS. 36, 37, 38, and 39, a plurality of word line contacts 520 spaced apart in the first direction DR1 may be formed on the plurality of word line pads 510 spaced apart in the third direction DR3.

For example, a plurality of contact holes penetrating the plurality of word line pads 510 and a portion of the interlayer insulating layer 120 may be formed. The plurality of contact holes may include contact holes extending in the third direction DR3 through the interlayer insulating layer 120 positioned on the uppermost word line pad 510 to an upper surface of the uppermost word line pad 510, and contact holes extending in the third direction DR3 through the interlayer insulating layer 120 and at least one word line pad 510 to an upper surface of a word line pad 510 positioned below the at least one word line pad 510. The lengths of the third direction DR3 of the plurality of contact holes may be different. The number of word line pads 510 through which the plurality of contact holes pass may vary. A portion of the upper surface of each of the plurality of word line pads 510 spaced apart in the third direction DR3 by each contact hole may be exposed.

An insulating material layer may be formed by depositing an insulating material to cover the inner surfaces of the plurality of contact holes and the upper surfaces of the plurality of word line pads 510 exposed by the plurality of contact holes. A portion of the insulating material layer covering the upper surface of the plurality of word line pads 510 may be etched through an anisotropic etching process. Next, a conductive material layer may be formed by depositing a conductive material to fill the remaining space of each of the plurality of contact holes. Next, a planarization process may be performed so that the insulating material layer and the conductive material layer have upper surfaces at the same level as the upper surface of the interlayer insulating layer 120. In the planarization process, a portion of the insulating material layer and the conductive material layer may be etched, and the plurality of word line contacts 520 may be formed within the plurality of contact holes. Each of the plurality of word line contacts 520 may include a conductive layer 521 having a pillar shape extending in the third direction DR3 and an insulating layer 522 surrounding a side surface of the conductive layer 521. The side of the word line contact 520 may be formed of the insulating layer 522, and the upper and lower surfaces of the word line contact 520 may be formed of the conductive layer 521 and the insulating layer 522. As the lower surface of the word line contact 520 comes into contact with the word line pad 510, the word line contact 520 and the word line pad 510 may be electrically connected.

Each of the plurality of word line pads 510 may connect two word lines WL spaced apart in the first direction DR1. The plurality of word line pads 510 may be further arranged between two word lines WL spaced apart in the first direction DR1 and spaced apart in the second direction DR2. For example, the plurality of word line contacts 520 positioned on the plurality of word line pads 510 may include a first word line contact 520a, a second word line contact 520b, a third word line contact 520c, a fourth word line contact 520d, a fifth word line contact 520e, a sixth word line contact 520f, a seventh word line contact 520g, an eighth word line contact 520h, and a ninth word line contact 520i.

For example, the first word line contact 520a, the second word line contact 520b, and the third word line contact 520c may be spaced apart from one another in the first direction DR1 and arranged on the plurality of word line pads 510 that are spaced apart from one another in the third direction DR3. The fourth word line contact 520d, the fifth word line contact 520e, and the sixth word line contact 520f may be spaced apart in the first direction DR1 and arranged on the plurality of word line pads 510 spaced apart in the third direction DR3. The seventh word line contact 520g, the eighth word line contact 520h, and the ninth word line contact 520i may be spaced apart in the first direction DR1 and arranged on the plurality of word line pads 510 spaced apart in the third direction DR3.

For example, the first word line contact 520a, the fourth word line contact 520d, and the seventh word line contact 520g may be respectively arranged on the plurality of word line pads 510 spaced apart from one another in the second direction DR2. The first word line contact 520a, the fourth word line contact 520d, and the seventh word line contact 520g may be spaced apart and arranged in the second direction DR2. The second word line contact 520b, the fifth word line contact 520e, and the eighth word line contact 520h may be respectively arranged on the plurality of word line pads 510 spaced apart from one another in the second direction DR2. The second word line contact 520b, the fifth word line contact 520e, and the eighth word line contact 520h may be spaced apart and arranged in the second direction DR2. The third word line contact 520c, the sixth word line contact 520f, and the ninth word line contact 520i may be respectively arranged on the plurality of word line pads 510 spaced apart from one another in the second direction DR2. The third word line contact 520c, the sixth word line contact 520f, and the ninth word line contact 520i may be spaced apart and arranged in the second direction DR2.

As illustrated, the number of word line contacts 520 spaced apart in the first direction DR1 and arranged on the plurality of word line pads 510 spaced apart in the third direction DR3 may be three, but is not limited thereto. For example, the number of the plurality of word line contacts 520 spaced apart in the first direction DR1 and arranged on the plurality of word line pads 510 spaced apart in the third direction DR3 may be 1 or 2, or may be 4 or more. As the number of word line contacts 520 spaced apart in the first direction DR1 and arranged on the plurality of word line pads 510 spaced apart in the third direction DR3 increases, the length of the pad region PR in the second direction DR2 may decrease.

For example, the plurality of word line pads 510 spaced apart and arranged in the third direction DR3 may include a first layer word line pad 510a, a second layer word line pad 510b, a third layer word line pad 510c, a fourth layer word line pad 510d, a fifth layer word line pad 510e, a sixth layer word line pad 510f, a seventh layer word line pad 510g, an eighth layer word line pad 510h, and a ninth layer word line pad 510i. The first layer word line pad 510a, the second layer word line pad 510b, the third layer word line pad 510c, the fourth layer word line pad 510d, the fifth layer word line pad 510e, the sixth layer word line pad 510f, the seventh layer word line pad 510g, the eighth layer word line pad 510h, and the ninth layer word line pad 510i may be sequentially adjacent to the upper surface of the substrate 100.

According to embodiments, the word line pads 510 each connected to the plurality of word line contacts 520 spaced apart and arranged in the first direction DR1 may be located in a consecutive layer. The number of word line pads 510 penetrated by a word line contact 520 connected to a word line pad 510 located at a relatively lower layer passes may be greater than the number of word line pads 510 penetrated by a word line contact 520 connected to a word line pad 510 located at a relatively higher layer. The length along the third direction DR3 of a word line contact 520 connected to a word line pad 510 located at a relatively lower layer may be longer than the length along the third direction DR3 of a word line contact 520 connected to a word line pad 510 located at a relatively higher layer.

According to embodiments, the layer in which the word line pads 510 respectively connected to the plurality of word line contacts 520 spaced apart and arranged in the first direction DR1 are positioned may be gradually lowered. The number of word line pads 510 penetrated by each of the plurality of word line contacts 520 spaced apart and arranged in the first direction DR1 penetrates may gradually increase. The length in the third direction DR3 of each of the plurality of word line contacts 520 spaced apart and arranged in the first direction DR1 may gradually increase.

For example, the first word line contact 520a may be connected to the ninth layer word line pad 510i, which is the uppermost word line pad among the plurality of word line pads 510, by penetrating the interlayer insulating layer 120. The second word line contact 520b may be connected to the eighth layer word line pad 510h located below the ninth layer word line pad 510i by penetrating the interlayer insulating layer 120 and the ninth layer word line pad 510i. The third word line contact 520c may be connected to the seventh layer word line pad 510g by penetrating the interlayer insulating layer 120, the ninth layer word line pad 510i, and the eighth layer word line pad 510h. The first word line contact 520a may penetrate zero word line pads 510, the second word line contact 520b may penetrate one word line pad 510, and the third word line contact 520c may penetrate two word line pads 510. The number of word line pads 510 through which the first word line contact 520a, the second word line contact 520b, and the third word line contact 520c are spaced apart and arranged in the first direction DR1 may gradually increase. The ninth layer word line pad 510i, the eighth layer word line pad 510h, and the seventh layer word line pad 510g, which are respectively connected to the first word line contact 520a, the second word line contact 520b, and the third word line contact 520c spaced apart and arranged in the first direction DR1, may be located in a consecutive layer. As the layers in which the ninth layer word line pad 510i, the eighth layer word line pad 510h, and the seventh layer word line pad 510g, which are respectively connected to the first word line contact 520a, the second word line contact 520b, and the third word line contact 520c, which are spaced apart and arranged in the first direction DR1, are positioned gradually become lower, the lengths of the first word line contact 520a, the second word line contact 520b, and the third word line contact 520c along the third direction DR3 may gradually increase.

For example, the fourth word line contact 520d may be connected to the sixth layer word line pad 510f by penetrating the interlayer insulating layer 120, the ninth layer word line pad 510i, the eighth layer word line pad 510h, and the seventh layer word line pad 510g. The fifth word line contact 520e may be connected to the fifth layer word line pad 510e by penetrating the interlayer insulating layer 120, the ninth layer word line pad 510i, the eighth layer word line pad 510h, the seventh layer word line pad 510g, and the sixth layer word line pad 510f. The sixth word line contact 520f may be connected to the fourth layer word line pad 510d by penetrating the interlayer insulating layer 120, the ninth layer word line pad 510i, the eighth layer word line pad 510h, the seventh layer word line pad 510g, the sixth layer word line pad 510f, and the fifth layer word line pad 510e. The fourth word line contact 520d may penetrate three word line pads 510, the fifth word line contact 520e may penetrate four word line pads 510, and the sixth word line contact 520f may penetrate five word line pads 510. The number of word line pads 510 through which the fourth word line contact 520d, the fifth word line contact 520e, and the sixth word line contact 520f are spaced apart and arranged in the first direction DR1 may gradually increase. The sixth layer word line pad 510f, the fifth layer word line pad 510e, and the fourth layer word line pad 510d, which are respectively connected to the fourth word line contact 520d, the fifth word line contact 520e, and the sixth word line contact 520f spaced apart from one another in the first direction DR1, may be positioned in a consecutive layer. As the layers in which the sixth layer word line pad 510f, the fifth layer word line pad 510e, and the fourth layer word line pad 510d are positioned, which are respectively connected to the fourth word line contact 520d, the fifth word line contact 520e, and the sixth word line contact 520f, which are spaced apart and arranged in the first direction DR1, gradually become lower, the lengths of the fourth word line contact 520d, the fifth word line contact 520e, and the sixth word line contact 520f in the third direction DR3 may gradually increase.

For example, the seventh word line contact 520g may be connected to the third layer word line pad 510c by penetrating the interlayer insulating layer 120, the ninth layer word line pad 510i, the eighth layer word line pad 510h, the seventh layer word line pad 510g, the sixth layer word line pad 510f, the fifth layer word line pad 510e, and the fourth layer word line pad 510d. The eighth word line contact 520h may be connected to the second layer word line pad 510b by penetrating the interlayer insulating layer 120, the ninth layer word line pad 510i, the eighth layer word line pad 510h, the seventh layer word line pad 510g, the sixth layer word line pad 510f, the fifth layer word line pad 510e, the fourth layer word line pad 510d, and the third layer word line pad 510c. The ninth word line contact 520i may be connected to the first layer word line pad 510a by penetrating the interlayer insulating layer 120, the ninth layer word line pad 510i, the eighth layer word line pad 510h, the seventh layer word line pad 510g, the sixth layer word line pad 510f, the fifth layer word line pad 510e, the fourth layer word line pad 510d, the third layer word line pad 510c, and the second layer word line pad 510b. The seventh word line contact 520g may penetrate six word line pads 510, the eighth word line contact 520h may penetrate seven word line pads 510, and the ninth word line contact 520i may penetrate eight word line pads 510. The number of word line pads 510 through which the seventh word line contact 520g, the eighth word line contact 520h, and the ninth word line contact 520i are spaced apart and arranged in the first direction DR1 may gradually increase. The third layer word line pad 510c, the second layer word line pad 510b, and the first layer word line pad 510a, which are respectively connected to the seventh word line contact 520g, the eighth word line contact 520h, and the ninth word line contact 520i spaced apart and arranged in the first direction DR1, may be positioned in a consecutive layer. As the layers in which the third layer word line pad 510c, the second layer word line pad 510b, and the first layer word line pad 510a, which are respectively connected to the seventh word line contact 520g, the eighth word line contact 520h, and the ninth word line contact 520i, which are spaced apart and arranged in the first direction DR1, are positioned gradually become lower, the lengths of the seventh word line contact 520g, the eighth word line contact 520h, and the ninth word line contact 520i in the third direction DR3 may gradually increase.

However, the examples are not limited thereto. For example, the lengths of the plurality of word line contacts 520 spaced apart and arranged in the first direction DR1 along the third direction DR3 may gradually decrease. As another example, as illustrated in FIG. 9, the lengths of the plurality of word line contacts 520 spaced apart in the second direction DR2 among the plurality of word line contacts 520 along the third direction DR3 may gradually increase or decrease. Additionally, as illustrated in FIG. 10, among the plurality of word line contacts 520, the shortest word line contact 520 and the longest word line contact 520 may be arranged along the first direction DR1. In addition, as illustrated in FIG. 11, among the plurality of word line contacts 520, the word line contacts 520 spaced apart and arranged in the second direction DR2 may have a longer length as they are located farther from the cell region CR.

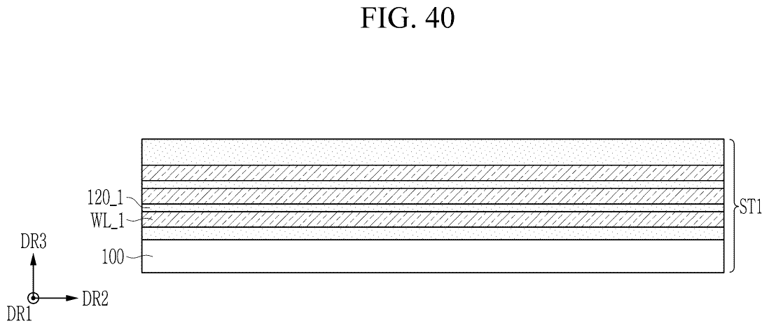

Hereinafter, a portion of a method for manufacturing a semiconductor device according to the embodiments shown in FIGS. 12 to 15 will be described with reference to FIGS. 40 to 48.

FIGS. 40 to 48 are cross-sectional views illustrating a portion of a method for manufacturing a semiconductor device according to embodiments.

As illustrated in FIG. 40, a first stacked structure ST1 may be formed. The first stacked structure ST1 may include a first cell substrate 100 and a plurality of memory cells positioned on the first cell substrate 100. The plurality of memory cells may be arranged and spaced apart in a first direction DR1 and a second direction DR2 that are parallel to the upper surface of the first cell substrate 100, and may be arranged and spaced apart in a third direction DR3 that is perpendicular to the upper surface of the first cell substrate 100. The second direction DR2 may be a direction intersecting the first direction DR1. For example, the second direction DR2 may be a direction orthogonal to the first direction DR1. Each of the plurality of memory cells may include a first semiconductor pattern, a first bit line connected to one side surface of the first semiconductor pattern along a first direction DR1, a first capacitor connected to the other side surface of the first semiconductor pattern along the first direction DR1, and a first word line WL_1 extending in a second direction DR2 while crossing the first semiconductor pattern. The first stacked structure ST1 may include a first interlayer insulating layer 120_1 positioned between a plurality of first word lines WL_1, between the lowermost first word line WL_1 and the first cell substrate 100, and on an upper surface of the uppermost first word line WL_1. The first stacked structure ST1 may include a plurality of first word line pads extending from the plurality of first word lines WL_1 in the first direction DR1 and overlapping a plurality of first capacitors in the second direction DR2. Each of the plurality of first word line pads may connect between two first word lines WL_1 spaced apart in the first direction DR1. Two first word lines WL_1 connected by the first word line pad may be spaced apart in the first direction DR1 with two first capacitors interposed therebetween, the two first capacitors being positioned between two first semiconductor patterns adjacent in the first direction DR1. Although only the first word line WL_1 and the first interlayer insulating layer 120_1 are illustrated in FIG. 40, the first stacked structure ST1 may include other components described above.

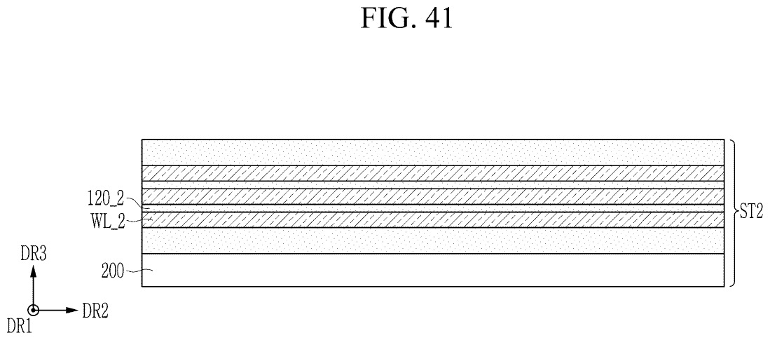

As illustrated in FIG. 41, a second stacked structure ST2 may be formed. The second stacked structure ST2 may include a second cell substrate 200 and a plurality of memory cells positioned on the second cell substrate 200. The plurality of memory cells may be arranged and spaced apart in the first direction DR1 and the second direction DR2 that are parallel to the upper surface of the second cell substrate 200, and may be arranged and spaced apart in a third direction DR3 that is perpendicular to the upper surface of the second cell substrate 200. The second direction DR2 may be a direction intersecting the first direction DR1. For example, the second direction DR2 may be a direction orthogonal to the first direction DR1. Each of the plurality of memory cells may include a second semiconductor pattern, a second bit line connected to one side surface of the second semiconductor pattern along the first direction DR1, a second capacitor connected to the other side surface of the second semiconductor pattern along the first direction DR1, and a second word line WL_2 extending in the second direction DR2 while crossing the second semiconductor pattern. The second stacked structure ST2 may include a second interlayer insulating layer 120_2 positioned between a plurality of second word lines WL_2, between the lowermost second word line WL_2 and the second cell substrate 200, and on an upper surface of the uppermost second word line WL_2. The second stacked structure ST2 may include a plurality of first word lines WL_1 extending from a plurality of first word lines WL_1 in a first direction DR1 and overlapping a plurality of second capacitors in a second direction DR2. Each of the plurality of second word line pads may connect between two second word lines WL_2 spaced apart in the first direction DR1. Two second word lines WL 2 connected by the second word line pads may be spaced apart in the first direction DR1 with two second capacitors interposed therebetween, the two second capacitors being positioned between two second semiconductor patterns adjacent in the first direction DR1. Although only the second word line WL_2 and the second interlayer insulating layer 120_2 are illustrated in FIG. 40, the second stacked structure ST2 may include other components described above.

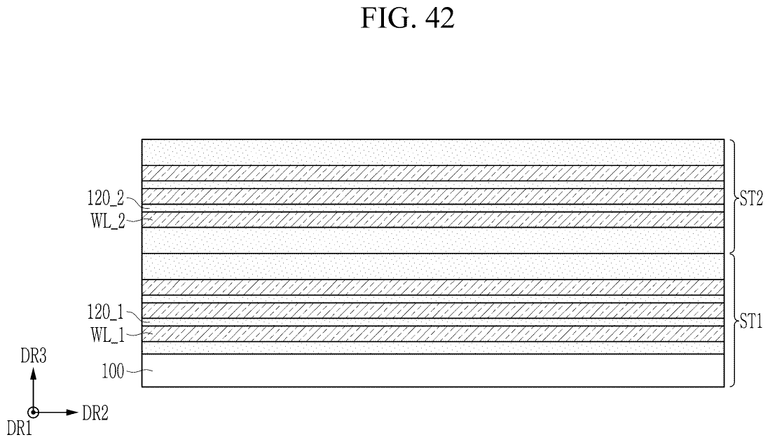

As illustrated in FIG. 42, the second stacked structure ST2 may be flipped to bond the second stacked structure ST2 on top of the first stacked structure ST1. By bringing the second interlayer insulating layer 120_2 of the second stacked structure ST2 into contact with the first interlayer insulating layer 120 1 of the first stacked structure ST1 and performing heat treatment, the first interlayer insulating layer 120_1 and the second interlayer insulating layer 120_2 may be bonded. Next, the second cell substrate 200 may be removed.

Although not shown, a plurality of first bit line contacts may be formed to connect the plurality of first bit lines and a global bit line of the first stacked structure ST1. A plurality of second bit line contacts may be formed to connect the plurality of second bit lines and a global bit line of a second stacked structure ST2.

Although not shown, the plurality of word line contacts may be formed. Hereinafter, the first word line pad included in the first stacked structure ST1 and the second word line pad included in the second stacked structure ST2 may be collectively referred to as word line pads. The plurality of word line contacts may be formed on the plurality of word line pads spaced apart and arranged in the third direction DR3. The plurality of word line contacts may be arranged and spaced apart in the first direction DR1 on the plurality of word line pads that are arranged and spaced apart in the third direction DR3. The plurality of word line contacts spaced apart in the first direction DR1 and arranged on the plurality of word line pads spaced apart in the third direction DR3 may be electrically connected to word line pads located in different layers. The word line contact may extend in the third direction DR3 through the interlayer insulating layer and some of the plurality of word line pads. The word line contact and the word line pad may be electrically connected as the lower surface of the word line contact is in contact with the upper surface of the word line pad. The lengths of the plurality of word line contacts spaced apart in the first direction DR1 and arranged on the plurality of word line pads spaced apart in the third direction DR3 may be different along the third direction DR3.

The plurality of word line pads may be arranged between two word lines WL spaced apart in the first direction DR1 and spaced apart in the second direction DR2. The plurality of word line contacts may be spaced apart in the second direction DR2 and arranged respectively on the plurality of word line pads. The plurality of word line contacts may be spaced apart and arranged in the second direction DR2. The plurality of word line contacts are respectively arranged on the plurality of word line pads spaced apart in the second direction DR2, and the plurality of word line contacts spaced apart in the second direction DR2 may be electrically connected to word line pads located in different layers. The plurality of word line contacts are arranged on the plurality of word line pads spaced apart in the second direction DR2, and the lengths of the plurality of word line contacts spaced apart in the second direction DR2 along the third direction DR3 may be different.

Length relationships among the plurality of word line contacts spaced apart from one another in the first direction DR1 and the second direction DR2, and relationships between the plurality of word line pads connected to the plurality of word line contacts may be implemented according to various embodiments illustrated in FIGS. 15 to 19.

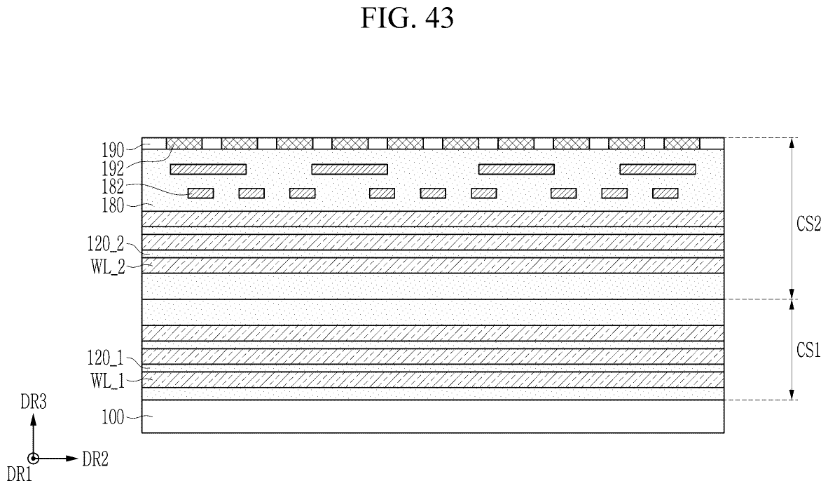

As illustrated in FIG. 43, an upper insulating layer 180 and an upper wiring layer 182 may be formed on the upper surface of the second interlayer insulating layer 120_2. Although not shown, a global bit line may be formed on the upper surface of the second interlayer insulating layer 120_2. For example, the global bit line may be, but is not limited to, part of the upper wiring layer 182. As another example, the upper wiring layer 182 may be formed separately from the global bit line. The upper wiring layer 182 may include a plurality of wiring layers spaced apart in the third direction DR3. Although not shown, additional wiring vias may be formed to connect the plurality of wiring layers spaced apart in the third direction DR3 by penetrating the upper insulating layer 180.

Next, a first pad insulating layer 190 and a first connection pad 192 may be formed on the upper wiring layer 182 and the upper insulating layer 180. The first pad insulating layer 190 may include an insulating material, and the first connection pad 192 may include a metal material. For example, the first connection pad 192 may include copper Cu. Although not shown, the first connection pad 192 may be electrically connected to the upper wiring layer 182. For example, the first connection pad 192 may be connected to the upper wiring layer 182 by a wiring via.

The order of forming the first bit line contact, the second bit line contact, and the word line contact may be varied.

The first cell substrate 100 may be referred to as substrate 100 hereinafter. A first cell structure CS1 and a second cell structure CS2 may be stacked on the substrate 100. The first cell structure CS1 may include components of the first stacked structure ST1 positioned on the substrate 100. The second cell structure CS2 may include the upper insulating layer 180, the upper wiring layer 182, the first pad insulating layer 190, and the first connection pad 192 additionally formed on the second stacked structure ST2.

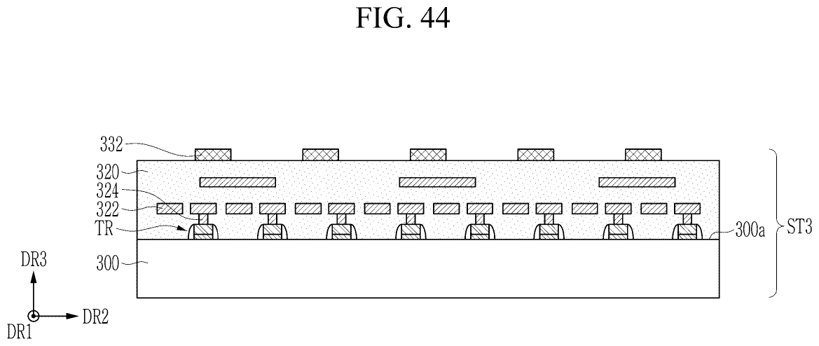

As illustrated in FIG. 44, a third stacked structure ST3 may be formed in which transistors TR are positioned on a first surface 300a of a peripheral circuit substrate 300, a first wiring insulating layer 320, a first circuit wiring layer 322, and a first wiring via 324 are positioned on the transistors TR, and an external connection pad 332 is positioned on an upper surface of the first wiring insulating layer 320. The first circuit wiring layer 322 may include a plurality of wiring layers spaced apart in the third direction DR3. The first circuit wiring layer 322 may include a plurality of wirings spaced apart in the second direction DR2. The first wiring insulating layer 320 may be positioned between the plurality of wiring layers spaced apart in the third direction DR3 and between the plurality of wirings spaced apart in the second direction DR2. The first wiring via 324 may penetrate the first wiring insulating layer 320 to connect the first circuit wiring layer 322 and the transistors TR. Although not shown, the first wiring via 324 may penetrate the first wiring insulating layer 320 to connect the plurality of wiring layers spaced apart in the third direction DR3. Although not shown, the first wiring via 324 may penetrate the first wiring insulating layer 320 to connect the first circuit wiring layer 322 and the external connection pad 332.

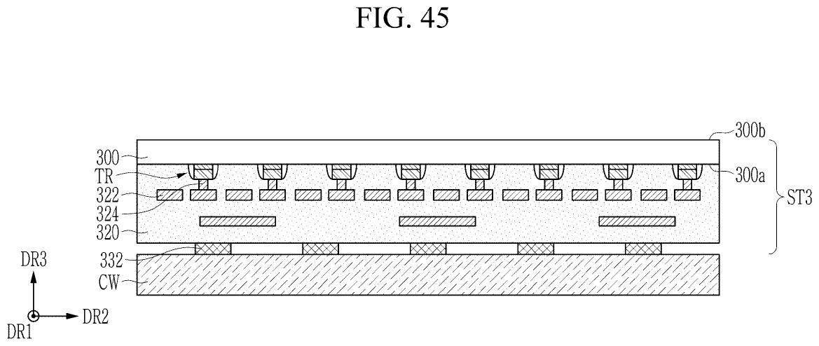

As illustrated in FIG. 45, the third stacked structure ST3 may be flipped so that the upper portion of the third stacked structure ST3 faces the carrier substrate CW and bonded onto the carrier substrate CW. Although not shown, a bonding material or adhesive layer may be positioned between the third stacked structure ST3 and the carrier substrate CW.

Next, a wafer thinning process may be performed on the second surface 300b of the peripheral circuit substrate 300, which is the opposite side of the first surface 300a, to reduce the thickness of the peripheral circuit substrate 300 in the third direction DR3.

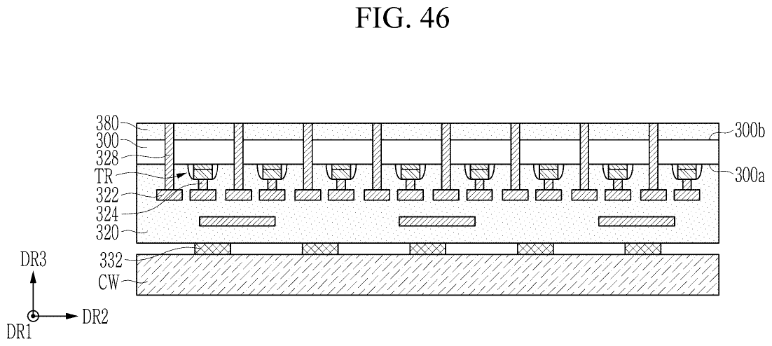

As illustrated in FIG. 46, a second wiring insulating layer 380 may be formed on the second surface 300b of the peripheral circuit substrate 300, and a through via 328 may be formed that penetrates the second wiring insulating layer 380, the peripheral circuit substrate 300, and the first wiring insulating layer 320 in the third direction DR3 to be connected to the first circuit wiring layer 322.

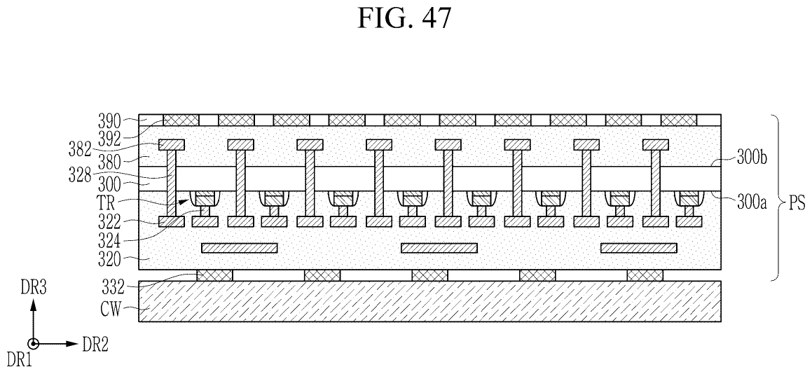

As illustrated in FIG. 47, a second circuit wiring layer 382 may be formed on the through via 328. The through via 328 may connect the first circuit wiring layer 322 and the second circuit wiring layer 382 in the third direction DR3. A second wiring insulating layer 380 may be additionally formed on the second circuit wiring layer 382.

Although not shown, the second circuit wiring layer 382 may include a plurality of wiring layers spaced apart in the third direction DR3. The second circuit wiring layer 382 may include a plurality of wirings spaced apart in the second direction DR2. The second wiring insulating layer 380 may be positioned between the plurality of wiring layers spaced apart in the third direction DR3 and between the plurality of wirins spaced apart in the second direction DR2. Although not shown, a second wiring via may be located to connect the plurality of wiring layers spaced apart in the third direction DR3 by penetrating the second wiring insulating layer 380.

Next, a second pad insulating layer 390 and a second connection pad 392 may be formed on the second wiring insulating layer 380 and the second circuit wiring layer 382. The second pad insulating layer 390 may include an insulating material, and the second connection pad 392 may include a metal material. For example, the second connection pad 392 may include copper Cu. Although not shown, the second connection pad 392 may be electrically connected to the second circuit wiring layer 382. For example, the second connection pad 392 may be connected to the second circuit wiring layer 382 by the second wiring via.

Accordingly, a peripheral circuit structure PS may be formed. The peripheral circuit structure PS may include the peripheral circuit substrate 300, the transistors TR, the first wiring insulating layer 320, the first circuit wiring layer 322, and the first wiring via 324 on the first surface 300a of the peripheral circuit substrate 300, the second wiring insulating layer 380, the second circuit wiring layer 382, the second pad insulating layer 390, and the second connection pad 392 on the second surface 300b of the peripheral circuit substrate 300, and may include the through via 328 that penetrates the first wiring insulating layer 320, the peripheral circuit substrate 300, and the second wiring insulating layer 380 to connect the first circuit wiring layer 322 and the second circuit wiring layer 382 in the third direction DR3.

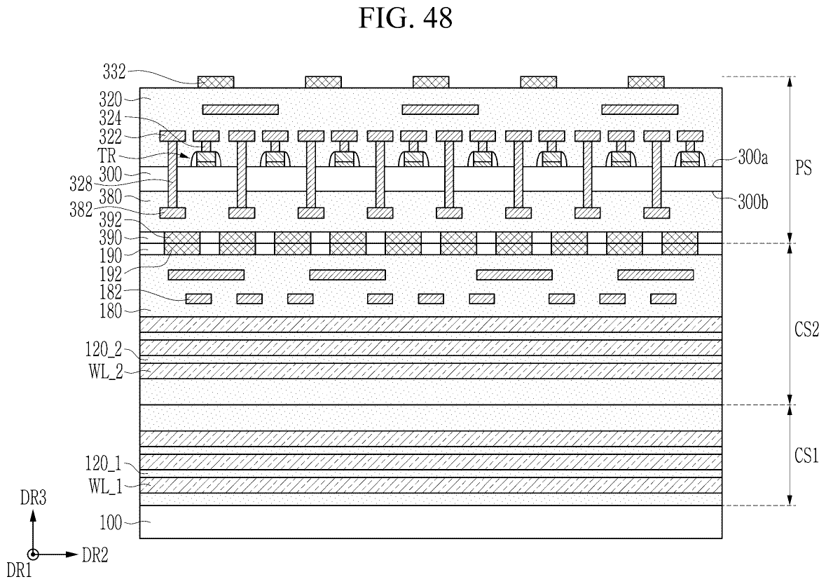

As illustrated in FIG. 48, the peripheral circuit structure PS on the carrier substrate CW may be flipped and bonded on the second cell structure CS2. The second connection pad 392 and the second pad insulating layer 390 of the peripheral circuit structure PS may be aligned and brought into contact with the first connection pad 192 and the first pad insulating layer 190 of the second cell structure CS2, respectively, and then heat treated. Accordingly, the first connection pad 192 may be bonded to the second connection pad 392, and the first pad insulating layer 190 may be bonded to the second pad insulating layer 390. Such bonding may be referred to as hybrid bonding. For example, when the first connection pad 192 and the second connection pad 392 include copper Cu, the bonding of the peripheral circuit structure PS and the second cell structure CS2 may be referred to as Cu—Cu hybrid bonding.

A method for manufacturing a semiconductor device according to embodiments may include forming a plurality of memory cells on a cell region of a substrate, the memory cells being spaced apart from one another in a first direction and a second direction substantially parallel to an upper surface of the substrate, and in a third direction substantially perpendicular to the upper surface of the substrate, each of the plurality of memory cells including a semiconductor pattern, a bit line connected to one side surface of the semiconductor pattern along the first direction and extending in the third direction, a capacitor connected to the other side surface of the semiconductor pattern along the first direction, and a word line crossing the semiconductor pattern and extending in the second direction, forming a word line extension connected to the word line and extending in the second direction on a pad region of the substrate located on one side of the cell region along the second direction, forming a word line pad extending from the word line extension in the first direction on the pad region and overlapping the capacitor in the second direction, and forming a plurality of word line contacts spaced apart from one another in the first direction on the word line pad and having different lengths along the third direction.

The step of forming the word line extension may include etching portions of an interlayer insulating layer and a plurality of semiconductor layers alternately stacked on the pad region to form a plurality of first trenches spaced apart in the first direction, each of the plurality of first trenches being located on one side, in the first direction, of a region of the pad region overlapping the word line in the second direction, etching portions of the plurality of semiconductor layers through the plurality of first trenches to form a plurality of first recesses, forming a plurality of word line extensions in the plurality of first recesses respectively by depositing a conductive material, the plurality of word line extensions being spaced apart in the third direction and the first direction, and forming a first insulating pattern in the plurality of first trenches by depositing an insulating material.

The step of forming the word line pad may include etching portions of an interlayer insulating layer and a plurality of semiconductor layers alternately stacked on the pad region to form a plurality of second trenches spaced apart in the second direction, the plurality of second trenches being located between two word line extensions spaced apart in the first direction, and the two word line extensions being respectively connected to two word lines located on both sides of two capacitors, the two capacitors being located between two semiconductor patterns adjacent in the first direction, etching portions of the plurality of semiconductor layers through the plurality of second trenches to form a plurality of holes, each of the plurality of holes being located between the plurality of second trenches spaced apart in the second direction, forming a plurality of word line pads in each of the plurality of holes by depositing a conductive material, the plurality of word line pads being spaced apart in the third direction and the second direction, and each of the plurality of word line pads connecting between the two word line extensions spaced apart in the first direction, and forming a second insulating pattern in the plurality of second trenches by depositing an insulating material.

The step of forming the plurality of word line contacts may include forming a plurality of contact holes penetrating the plurality of word line pads spaced apart from one another in the third direction, and a portion of the interlayer insulating layer, wherein the the plurality of contact holes have different lengths along the third direction, forming an insulating material layer by depositing an insulating material to cover inner surfaces of the plurality of contact holes and upper surfaces of the plurality of word line pads exposed by the plurality of contact holes, etching a portion of the insulating material layer covering the upper surfaces of the plurality of word line pads through an anisotropic etching process, forming a material layer filling remaining spaces of the plurality of contact holes by depositing a conductive material, etching portions of the insulating material layer and the conductive material layer through a planarization process to form the plurality of word line contacts in the plurality of contact holes, each of the plurality of word line contacts including an insulating layer and a conductive layer. A side surface of each of the plurality of word line contacts may be formed of the insulating layer. An upper surface and a lower surface of each of the plurality of word line contacts may be formed of the insulating layer and the conductive layer. A lower surface of each of the plurality of word line contacts may contact the word line pad.

The length, in the third direction, of the plurality of word line pads spaced apart in the first direction on the plurality of word line pads spaced apart in the third direction may gradually increase or decrease.

Although the embodiments of the present disclosure have been described in detail above, the scope of the present disclosure is not limited thereto, and various modifications and improvements made by those skilled in the art using the basic concept of the present disclosure defined in the following claims also fall within the scope of the present disclosure.

What is claimed is:

1. A semiconductor device comprising:
a substrate,
a plurality of semiconductor patterns on the substrate, spaced apart in a direction substantially perpendicular to an upper surface of the substrate,
a bit line connected to one side surfaces of the plurality of semiconductor patterns along a first direction and extending in a direction substantially perpendicular to the upper surface of the substrate,
a plurality of capacitors respectively connected to other side surfaces of the plurality of semiconductor patterns along the first direction,
a plurality of word lines respectively crossing the plurality of semiconductor patterns and extending in a second direction intersecting the first direction,
a plurality of word line pads overlapping the plurality of capacitors in the second direction, and
a plurality of word line contacts extending in a direction substantially perpendicular to the upper surface of the substrate;
wherein at least some of the plurality of word line pads are respectively connected to the plurality of word line contacts,
wherein the plurality of word line contacts are spaced apart in the first direction, and
wherein the plurality of word line contacts have different lengths along the direction substantially perpendicular to the upper surface of the substrate.

2. The semiconductor device of claim 1,
wherein the plurality of word line pads include word line pads spaced apart in the second direction,
wherein the plurality of word line contacts include word line contacts spaced apart in the second direction, and
wherein the word line contacts spaced apart in the second direction are respectively connected to the word line pads spaced apart in the second direction.

3. The semiconductor device of claim 2, wherein each of the plurality of word line contacts is electrically connected to one of the plurality of word line pads.

4. The semiconductor device of claim 3,
wherein each of the plurality of word line contacts includes a conductive layer having a pillar shape extending in a direction substantially perpendicular to the upper surface of the substrate, and an insulating layer surrounding a side surface of the conductive layer,
wherein a lower surface of each of the plurality of word line contacts is in contact with an upper surface of one word line pad, and
wherein the word line contacts, except for the word line contact in contact with the upper surface of the uppermost word line pad among the plurality of word line contacts, penetrate a word line pad located above the one word line pad.

5. The semiconductor device of claim 2,
wherein the word line contacts, which are spaced apart in the first direction among the plurality of word line contacts, have lengths that gradually increase or decrease.

6. The semiconductor device of claim 2,
wherein the word line contacts, which are spaced apart in the second direction among the plurality of word line contacts, have lengths that gradually increase or decrease.

7. The semiconductor device of claim 2,
wherein the shortest word line contact and the longest word line contact among the plurality of word line contacts are arranged along the first direction.

8. The semiconductor device of claim 2,
wherein the plurality of semiconductor patterns, the bit line, the plurality of capacitors, and the plurality of word lines are located on a cell region of the substrate, the plurality of word line pads are located on a pad region of the substrate, and the pad region is located on one side of the cell region along the second direction, and
wherein the word line contacts, which are spaced apart in the second direction among the plurality of word line contacts, have longer lengths the farther they are from the cell region.

9. The semiconductor device of claim 2,
wherein a plurality of cell structures are stacked on the substrate,
each of the plurality of cell structures including the plurality of semiconductor patterns, the bit line, the plurality of capacitors, the plurality of word lines, and the plurality of word line pads,
wherein the word line pads respectively connected to the word line contacts spaced apart in the first direction are included in different cell structures,
and the word line pads respectively connected to the word line contacts spaced apart in the second direction are included in the same cell structure.

10. The semiconductor device of claim 9,
wherein the word line contacts spaced apart in the first direction are respectively connected to word line pads having the same stacking order among the plurality of word line pads of each of the different cell structures.

11. The semiconductor device of claim 10,
wherein the plurality of semiconductor patterns, the bit line, the plurality of capacitors, and the plurality of word lines of each of the plurality of cell structures are located on a cell region of the substrate, the plurality of word line pads of each of the plurality of cell structures are located on a pad region of the substrate, and the pad region is located on one side of the cell region along the second direction, and
wherein the word line contacts, which are spaced apart in the second direction among the plurality of word line contacts, are connected to word line pads having a lower stacking order among the plurality of word line pads of each of the same cell structures as they get farther from the cell region.

12. The semiconductor device of claim 1,
wherein the plurality of semiconductor patterns include semiconductor patterns spaced apart in the first direction,
wherein, between two semiconductor patterns adjacent in the first direction, two capacitors respectively connected to the two semiconductor patterns or one bit line connected to the two semiconductor patterns is arranged, and
wherein the word line pad connects two word lines located on both sides of the two capacitors along the first direction.

13. The semiconductor device of claim 12,
further comprising a plurality of bit lines respectively connected to the semiconductor patterns spaced apart in the first direction, and a plurality of global bit lines connected to the plurality of bit lines and extending in the first direction,
wherein the plurality of bit lines are spaced apart in the first direction,
wherein two bit lines adjacent in the first direction are connected to different global bit lines.

14. The semiconductor device of claim 13,
further comprising a plurality of bit line pads respectively positioned on upper surfaces of the plurality of bit lines,
wherein the plurality of bit line pads are spaced apart in the first direction, and
wherein two bit line pads adjacent in the first direction extend in opposite directions along the second direction.

15. The semiconductor device of claim 14,
wherein the plurality of global bit lines include a first global bit line and a second global bit line,
wherein, in a plan view, the first global bit line and the second global bit line are spaced apart in the second direction,
wherein two bit line pads adjacent in the first direction include a first sub-bit line pad connected to the first global bit line and a second sub-bit line pad connected to the second global bit line.

16. The semiconductor device of claim 15,
further comprising a first sub-bit line contact connecting between the first sub-bit line pad and the first global bit line, and a second sub-bit line contact connecting between the second sub-bit line pad and the second global bit line,
wherein the first global bit line and the second global bit line are located in different layers, and
wherein the first sub-bit line contact and the second sub-bit line contact have different lengths along a direction substantially perpendicular to the upper surface of the substrate.

17. A semiconductor device comprising:
a substrate,
a plurality of semiconductor patterns on the substrate, spaced apart in a direction substantially perpendicular to an upper surface of the substrate,
a bit line connected to one side surfaces of the plurality of semiconductor patterns in the first direction and extending in a direction substantially perpendicular to the upper surface of the substrate,
a plurality of capacitors respectively connected to the other side surfaces of the plurality of semiconductor patterns along the first direction,
a plurality of word lines respectively crossing the plurality of semiconductor patterns and extending in a second direction intersecting the first direction,
a plurality of word line pads overlapping the plurality of capacitors in the second direction, and
a plurality of word line contacts extending in a direction substantially perpendicular to the upper surface of the substrate;
wherein at least some of the plurality of word line pads are respectively connected to the plurality of word line contacts,
wherein the plurality of word line contacts are spaced apart in the first direction, and
wherein the plurality of word line contacts are connected to upper surfaces of word line pads located in different layers.

18. The semiconductor device of claim 17,
wherein the plurality of semiconductor patterns are spaced apart in the first direction,
wherein, between two semiconductor patterns adjacent in the first direction, two capacitors respectively connected to the two semiconductor patterns or one bit line connected to the two semiconductor patterns is arranged, and
wherein each of the plurality of word line pads connects between two word lines located on both sides of the two capacitors, and
wherein the plurality of word line pads have the same length in the first direction.

19. The semiconductor device of claim 18,
wherein the plurality of word line pads include word line pads spaced apart in the second direction between the two word lines,
wherein the plurality of word line contacts include word line contacts spaced apart in the second direction,
wherein the word line contacts spaced apart in the second direction are respectively connected to upper surfaces of word line pads spaced apart in the second direction.

20. A semiconductor device comprising:
a substrate,
a plurality of semiconductor patterns on the substrate, spaced apart in a direction substantially parallel to an upper surface of the substrate and in a direction substantially perpendicular to the upper surface of the substrate,
a plurality of bit lines spaced apart in the direction substantially parallel to the upper surface of the substrate, each of the plurality of bit lines being connected to one side surfaces of the plurality of semiconductor patterns spaced apart in the direction substantially perpendicular to the upper surface of the substrate along a first direction, and extending in the direction substantially perpendicular to the upper surface of the substrate,
a plurality of capacitors respectively connected to other side surfaces of the plurality of semiconductor patterns along the first direction,
a plurality of word lines spaced apart in the direction substantially perpendicular to the upper surface of the substrate and in the first direction, each of the plurality of word lines crossing the plurality of semiconductor patterns spaced apart in a second direction intersecting the first direction, and extending in the second direction,
a plurality of word line pads overlapping the plurality of capacitors in the second direction, each of the plurality of word line pads connecting two word lines among the plurality of word lines that are adjacent in the first direction with the capacitor interposed therebetween, and
a plurality of word line contacts extending in the direction substantially perpendicular to the upper surface of the substrate and spaced apart in the first direction on each of the plurality of word line pads,
wherein the plurality of word line contacts are connected to upper surfaces of word line pads located in different layers.
